(19) United States
(12) Patent Application Publication
(10) Pub. No.: US 2024/0369928 A1
(43) Pub. Date: Nov. 7, 2024

(54) RADIATION-SENSITIVE RESIN COMPOSITION AND METHOD FOR FORMING PATTERN

(71) Applicant: JSR CORPORATION, Tokyo (JP)

(72) Inventor: Ken MARUYAMA, Tokyo (JP)

(73) Assignee: JSR CORPORATION, Tokyo (JP)

(21) Appl. No.: 18/685,539

(22) PCT Filed: Aug. 30, 2022
(86) PCT No.: PCT/JP2022/032570

§ 371 Date: Feb. 22, 2024

(30) Foreign Application Priority Data
Sep. 6, 2021 (JP) 2021-144675

(51) Int. Cl. G03F 7/039; G03F 7/20

(52) U.S. Cl. CPC G03F 7/0392; G03F 7/2004; G03F 7/2059

(57) ABSTRACT

A radiation-sensitive resin composition includes a resin, an acid diffusion controlling agent represented by formula (a), and a solvent. The resin includes: at least one structural unit selected from the group consisting of a structural unit represented by formula (1) and a structural unit represented by formula (2); and a structural unit including a phenolic hydroxy group. R^{w} is a monovalent organic group having 1 to 20 carbon atoms, a hydroxy group, or an amino group; L^{q} is a divalent linking group; Z⁺ is a monovalent radiation-sensitive onium cation; q₁ is an integer of 1 to 4; q₂ is an integer of 0 to 3; q₃ is an integer of 1 to 3; and an upper limit of q₁+q₂+q₃ is 6.

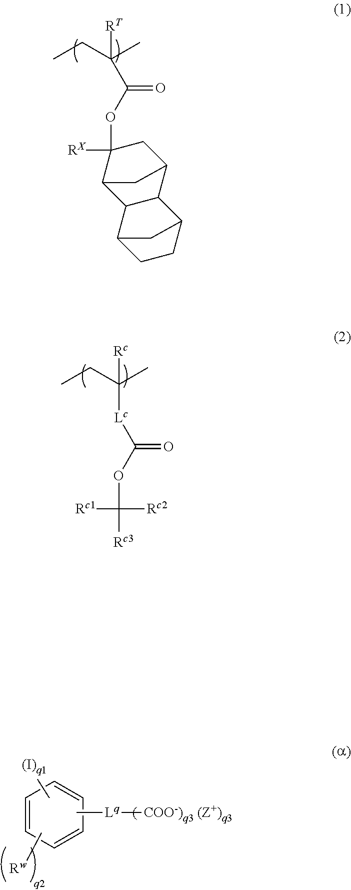

### BACKGROUND OF THE INVENTION

### Field of the Invention

The present invention relates to a radiation-sensitive resin composition and a method for forming a pattern.

### Description of the Related Art

A photolithography technology using a resist composition has been used for the fine circuit formation in a semiconductor device. As the representative procedure, for example, a resist pattern is formed on a substrate by generating an acid by irradiating the coating of the resist composition with a radioactive ray through a mask pattern, and then reacting in the presence of the acid as a catalyst to generate the difference of solubility of a resin into an alkaline or organic developer between an exposed part and a non-exposed part.

In the photolithography technology, pattern miniaturization is promoted by using short-wavelength radiation, such as ArF excimer laser or by combining such radiation with an immersion exposure method (liquid immersion lithography). As a next-generation technology, a shorter wavelength radioactive ray such as an electron beam, an X ray, or EUV (extreme-ultraviolet ray) is tried to be used, and a resist material containing a resin with a ring structure having an enhanced efficiency of absorbing such a radioactive ray has been studied (Japanese Patent No. 6531723).

### PRIOR ART DOCUMENT

### Patent Document

Patent Document 1: JP-B-6531723

### SUMMARY OF THE INVENTION

### Problems to be Solved by the Invention

Even in the above-described next generation technology, various resist performances equivalent to or higher than conventional performances are required in sensitivity, critical dimension uniformity (CDU) performance, which is an index of uniformity of a line width and a hole diameter, residual film ratio, which indicates pattern film thickness retention property between before and after exposure, and the like.

An object of the present invention is to provide a radiation-sensitive resin composition capable of forming a resist film having sensitivity, CDU performance, and residual film ratio at sufficient levels even when a next-generation technology is applied, and a method for forming a pattern.

### Means for Solving the Problems

As a result of intensive studies to solve the present problems, the present inventors have found that the above object can be achieved by adopting the following configurations, and have accomplished the present invention.

The present invention relates to, in one embodiment, a radiation-sensitive resin composition including:
a resin containing at least one among structural units represented by formula (1) (hereinafter also referred to as “structural units (I)”) and structural units represented by formula (2) (hereinafter also referred to as “structural units (II)”), and a structural unit having a phenolic hydroxy group (hereinafter also referred to as “structural unit (III)”);
an acid diffusion controlling agent represented by formula (3); and
a solvent,

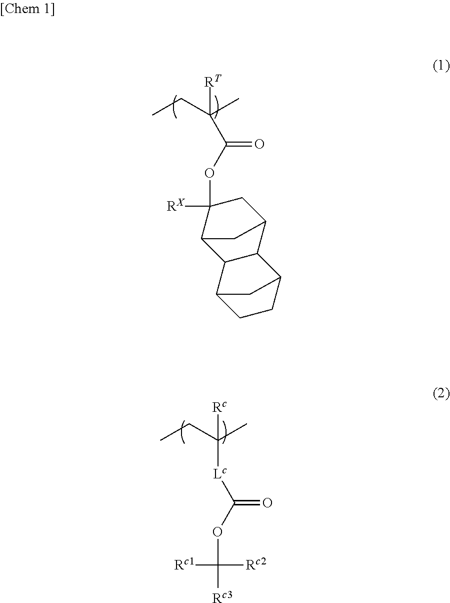

(in formula (1), R^{T} is a hydrogen atom, a fluorine atom, a methyl group, or a trifluoromethyl group; R^{X} is a monovalent hydrocarbon group having 1 to 20 carbon atoms;
in formula (2), R^{c} is a hydrogen atom, a fluorine atom, a methyl group, or a trifluoromethyl group; L^{c} is a single bond or a divalent linking group; and R^{c1}, R^{c2} and R^{c3} are each independently a monovalent hydrocarbon group having 1 to 20 carbon atoms,)

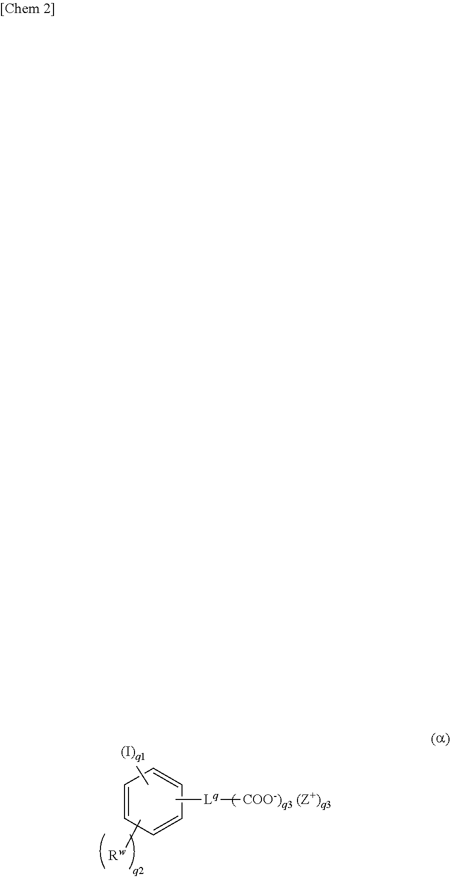

(in formula (3), R^{w} is a monovalent organic group having 1 to 20 carbon atoms, a hydroxy group, or an amino group; when there are a plurality of R^{w}'s, the plurality of R^{w}'s are the same or different from each other; L^{q} is a divalent linking group; when there are a plurality of L^{q}'s, the plurality of L^{q}'s are the same or different from each other; Z⁺ is a monovalent radiation-sensitive onium cation; q₁ is an integer of 1 to 4; q₂ is an integer of 0 to 3; q₃ is an integer of 1 to 3; and an upper limit of q₁+q₂+q₃ is 6.)

With the radiation-sensitive resin composition, a resist film satisfying sensitivity, CDU performance, and residual film ratio can be constructed. The reason for this is not clear and is not limited, but can be expected as follows. Since the acid-dissociable groups of the structural units (I) and (II) in the resin have high acid-dissociation efficiency due to an acid generated by exposure owing to the steric hindrance of a substituent and carbocation stability, the contrast between an exposed area and an unexposed area is increased and superior pattern-forming performance is exhibited. Absorption of radiation such as EUV having a wavelength of 13.5 nm by iodine atoms of the acid diffusion controlling agent is very large, and this makes the radiation-sensitive resin composition highly sensitive. Furthermore, since the acid diffusion controlling agent has a linking group between the benzene ring and the carboxylate ion thereof, good acid scavenging property can be exhibited. In addition, the water repellency of an iodine atom can reduce the solubility of the pattern in the unexposed area in the developer. It is presumed that the resist performance can be exhibited by the combination of these actions.

The present invention relates, in another embodiment, to a method for forming a pattern, including:
directly or indirectly applying the radiation-sensitive resin composition to a substrate to form a resist film;
exposing the resist film; and
developing the exposed resist film with a developer.

The method for forming a resist pattern uses the above-described radiation-sensitive resin composition capable of forming a resist film superior in sensitivity, CDU performance, and residual film ratio, and therefore a high-quality resist pattern can efficiently be formed.

### MODE FOR CARRYING OUT THE INVENTION

Hereinbelow, embodiments of the present invention will specifically be described, but the present invention is not limited to these embodiments.

### <<Radiation-Sensitive Resin Composition>>

The radiation-sensitive resin composition (hereinafter also simply referred to as “composition”) according to the present embodiment contains a resin, an acid diffusion controlling agent, and a solvent. The composition may further contain other optional components as long as the effects of the present invention are not impaired. When the radiation-sensitive resin composition contains the prescribed resin and acid diffusion controlling agent, the radiation-sensitive resin composition can impart high levels of sensitivity, CDU performance and residual film ratio to a resulting resist film.

### <Resin>

The resin is an assembly of polymers that contain at least one among structural units (I) and structural units (II), and a structural unit (III) (hereinafter, this resin is also be referred to as “base resin”). The base resin may contain a structural unit (IV) containing a lactone structure or the like in addition to the structural units (I), (II) and (III). Each of the structural units will be described below.

### (Structural Unit (I))

The structural unit (I) is represented by formula (1),

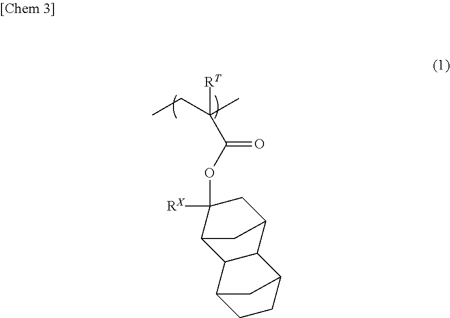

(in formula (1), R^{T} is a hydrogen atom, a fluorine atom, a methyl group, or a trifluoromethyl group; R^{X} is a monovalent hydrocarbon group having 1 to 20 carbon atoms.)

As R^{T}, a hydrogen atom or a methyl group is preferable from the viewpoint of the copolymerizability of a monomer that affords the structural unit (I).

Examples of the monovalent hydrocarbon group having 1 to 20 carbon atoms represented by R^{X} include a chain hydrocarbon group having 1 to 20 carbon atoms, a monovalent alicyclic hydrocarbon group having 3 to 20 carbon atoms, and a monovalent aromatic hydrocarbon group having 6 to 20 carbon atoms.

Examples of the chain hydrocarbon group having 1 to 20 carbon atoms include a linear or branched saturated hydrocarbon group having 1 to 20 carbon atoms and a linear or branched unsaturated hydrocarbon group having 1 to 20 carbon atoms. Examples of the linear or branched saturated hydrocarbon group having 1 to 20 carbon atoms include alkyl groups such as a methyl group, an ethyl group, a n-propyl group, an i-propyl group, a n-butyl group, a 2-methylpropyl group, a 1-methylpropyl group, and a t-butyl group. Examples of the linear or branched unsaturated hydrocarbon group having 1 to 20 carbon atoms include alkenyl groups such as an ethenyl group, a propenyl group, and a butenyl group; and alkynyl groups such as an ethynyl group, a propynyl group, and a butynyl group.

Examples of the alicyclic hydrocarbon group having 3 to 20 carbon atoms include a monocyclic or polycyclic saturated hydrocarbon group and a monocyclic or polycyclic unsaturated hydrocarbon group. Preferred examples of the monocyclic saturated hydrocarbon groups include a cyclopentyl group, a cyclohexyl group, a cycloheptyl group, and a cyclooctyl group. Preferred examples of the polycyclic cycloalkyl groups include bridged alicyclic hydrocarbon groups such as a norbornyl group, an adamantyl group, a tricyclodecyl group, and a tetracyclododecyl group. It is to be noted that the bridged alicyclic hydrocarbon group refers to a polycyclic alicyclic hydrocarbon group in which two carbon atoms that constitute an alicyclic ring and not adjacent to each other are bonded by a bonding chain containing one or more carbon atoms.

Examples of the monovalent aromatic hydrocarbon groups having 6 to 20 carbon atoms include: aryl groups such as a phenyl group, a tolyl group, a xylyl group, a naphthyl group, and an anthryl group; and aralkyl groups such as a benzyl group, a phenethyl group, and a naphthylmethyl group.

As the R^{X}, a monovalent chain hydrocarbon group having 1 to 10 carbon atoms or an alicyclic hydrocarbon group having 3 to 12 carbon atoms is preferable, and a linear saturated hydrocarbon group having 1 to 5 carbon atoms is more preferable.

Examples of the structural unit (I) include structural units represented by formulae (1-1) to (1-4).

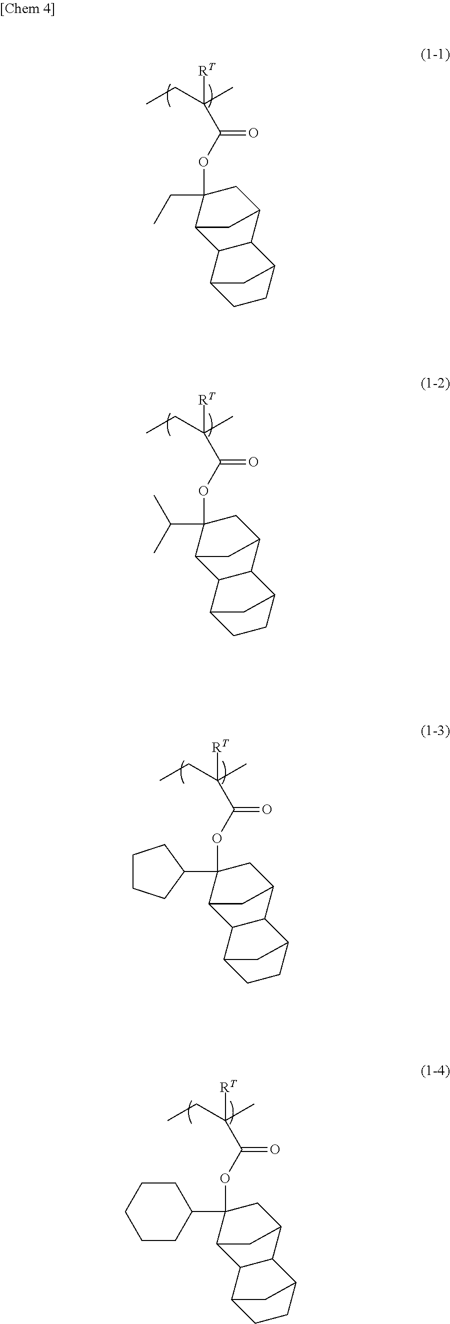

In the above formulas (1-1) to (1-4), R^{T} has the same meaning as in the above formula (1), In particular, the structural unit (I) is preferably represented by formula (1-1).

When the resin contains the structural unit (I), the lower limit of the content of the structural unit (I) (when a plurality of types of the structural unit (I) are contained, the total content thereof is taken) is preferably 5 mol %, more preferably 10 mol %, and still more preferably 15 mol % based on all structural units constituting the resin. The upper limit of the content is preferably 80 mol %, more preferably 70 mol %, still more preferably 60 mol %. When the content of the structural unit (I) is adjusted to within the above range, the sensitivity and CDU performance of the radiation-sensitive resin composition can be further improved.

### (Structural Unit (II))

The structural unit (II) is represented by formula (2),

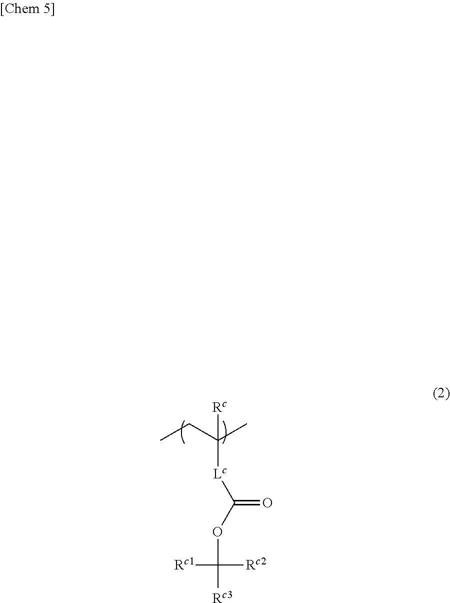

(in formula (2), R^{c} is a hydrogen atom, a fluorine atom, a methyl group, or a trifluoromethyl group, L^{c} is a single bond or a divalent linking group; and R^{c1}, R^{c2} and R^{c3} are each independently a monovalent hydrocarbon group having 1 to 20 carbon atoms.)

As R^{c}, a hydrogen atom or a methyl group is preferable from the viewpoint of the copolymerizability of a monomer that affords the structural unit (II).

Examples of the divalent linking group represented by L^{c} include an alkanediyl group, a cycloalkanediyl group, an alkenediyl group, —OR^{LA}—*, and —COOR^{LB}—* (* represents a bond on the carbonyl group side).

The aforementioned alkanediyl group is preferably an alkanediyl group having 1 to 8 carbon atoms.

Examples of the aforementioned cycloalkanediyl group include monocyclic cycloalkanediyl groups such as a cyclopentanediyl group and a cyclohexanediyl group; and polycyclic cycloalkanediyl groups such as a norbornanediyl group and an adamantanediyl group. The aforementioned cycloalkanediyl group is preferably a cycloalkanediyl group having 5 to 12 carbon atoms.

Examples of the aforementioned alkenediyl group include an ethenediyl group, a propenediyl group, and a butenediyl group. The aforementioned alkenediyl group is preferably an alkenediyl group having 2 to 6 carbon atoms.

Examples of R^{LA} of —OR^{LA}—* include the above-described alkanediyl group, the above-described cycloalkanediyl group, and the above-described alkenediyl group. Examples of R^{LB} of —COOR^{LB}—* include the aforementioned alkanediyl group, the aforementioned cycloalkanediyl group, the aforementioned alkenediyl group, and an arenediyl group. Examples of the arenediyl group include a benzenediyl group, a tolylene group, and a naphthalenediyl group. The aforementioned arenediyl group is preferably an arenediyl group having 6 to 15 carbon atoms.

Among them, L^{c} is preferably a single bond or —COOR^{LB}—*. R^{LB} is preferably an alkanediyl group.

A part or all of the hydrogen atoms on a carbon atom in L^{C} may be substituted with a halogen atom such as a fluorine atom or a chlorine atom, a halogenated alkyl group such as a trifluoromethyl group, an alkoxy group such as a methoxy group, or a cyano group.

As the monovalent hydrocarbon groups having 1 to 20 carbon atoms represented by R^{c1}, R^{c2}, and R^{c3}, the groups disclosed as the monovalent hydrocarbon group having 1 to 20 carbon atoms represented by R^{X} in the above formula (1) and the like can be employed.

Among them, it is preferable that R^{c1} and R^{c2} are each independently a monovalent chain hydrocarbon group having 1 to 10 carbon atoms, and R^{c3} is a monovalent alicyclic or aromatic hydrocarbon group having 6 to 12 carbon atoms.

Examples of the structural unit (II) include structural units represented by formulas (2-1) to (2-18).

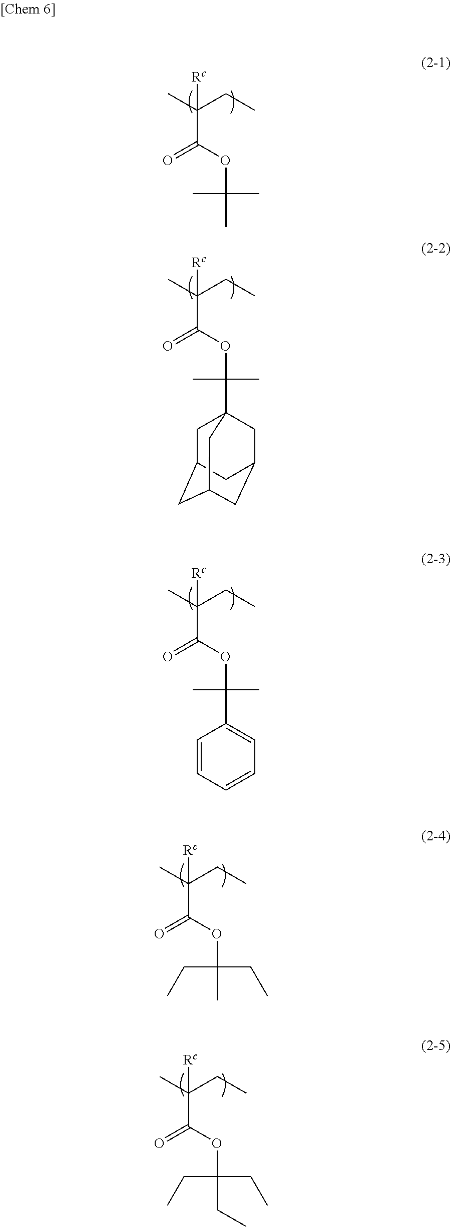

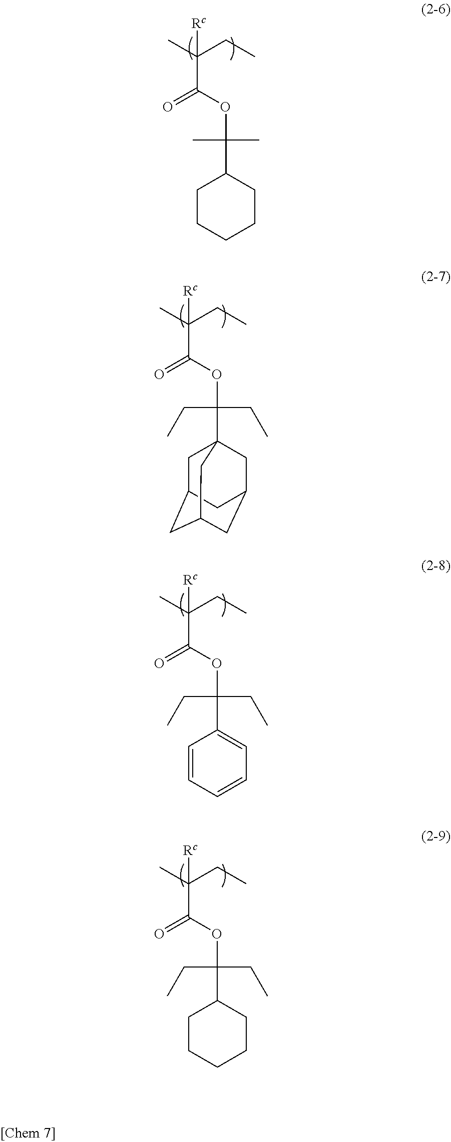

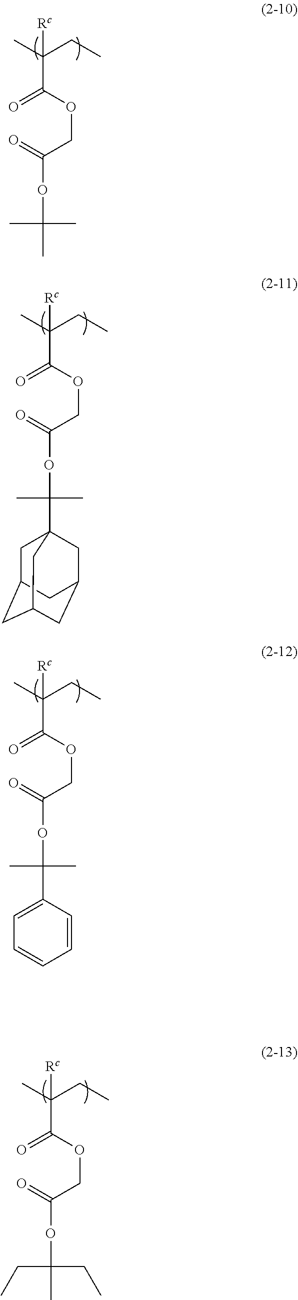

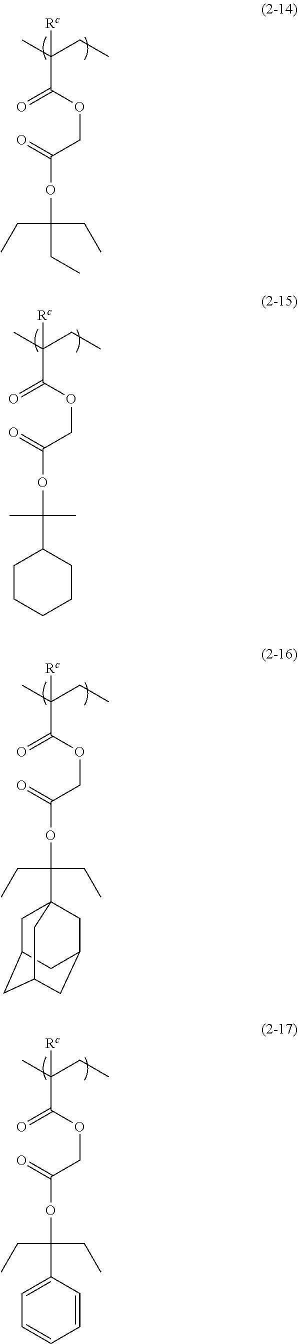

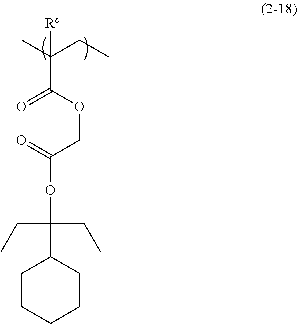

In the above formulas (2-1) to (2-18), R^{c} has the same meaning as in the above formula (2). Among them, the structural unit (II) is preferably represented by formulas (2-1) to (2-3) and (2-10) to (2-12).

When the resin contains the structural unit (II), the lower limit of the content of the structural unit (II) (when a plurality of types of the structural unit (II) are contained, the total content thereof is taken) is preferably 5 mol %, more preferably 10 mol %, and still more preferably 15 mol % based on all structural units constituting the resin. The upper limit of the content is preferably 90 mol %, more preferably 80 mol %, and still more preferably 70 mol %. When the content of the structural unit (II) is adjusted to within the above range, the sensitivity and CDU performance of the radiation-sensitive resin composition can be further improved.

### (Structural Unit (III))

The structural unit (III) is a structural unit having a phenolic hydroxy group or a structural unit that affords a phenolic hydroxy group due to the action of an acid. The phenolic hydroxy group of the structural unit (III) also includes a phenolic hydroxy group generated through deprotection due to the action of an acid generated by exposure as the phenolic hydroxy group of the structural unit (II). When the resin contains the structural unit (III), the sensitivity and the like of the radiation-sensitive resin composition can be further improved. When KrF excimer laser light, EUV, electron beam or the like is used as radiation to be applied in an exposure step in a method for forming a resist pattern, the structural unit (II) contributes to improvement in etching resistance and improvement in the difference in solubility in a developer (namely, dissolution contrast) between an exposed area and an unexposed area. In particular, the resin can be suitably applied to pattern formation using exposure with radiation having a wavelength of 50 nm or less such as electron beam or EUV. The structural unit (III) is preferably represented by the following formula (3),

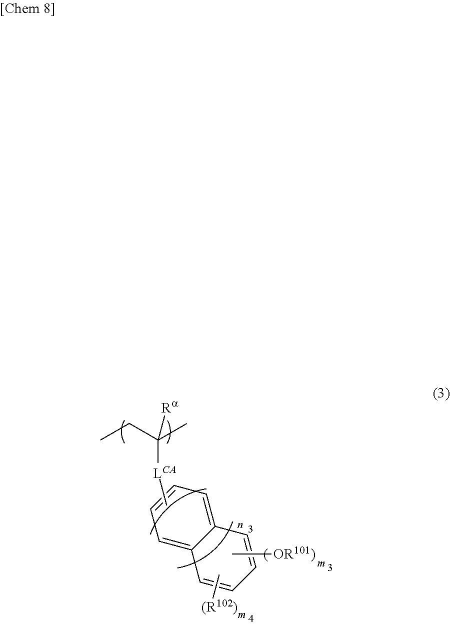

(in formula (2), R^{α} represents a hydrogen atom, a fluorine atom, a methyl group, or a trifluoromethyl group;
L^{CA} is a single bond, —COO—*, or —O—; * is a bond on the aromatic ring side;
R¹⁰¹ is a hydrogen atom or a protective group that is deprotected by the action of an acid; when there are a plurality of R¹⁰¹'s, the plurality of R¹⁰¹'s are the same or different from each other;
R¹⁰² is a cyano group, a nitro group, an alkyl group, a fluorinated alkyl group, an alkoxycarbonyloxy group, an acyl group, or an acyloxy group; when there are a plurality of R¹⁰²'s, the plurality of R¹⁰²'s are the same or different from each other;
n₃ is an integer of 0 to 2, m₃ is an integer of 1 to 8, and m₄ is an integer of 0 to 8, provided that 1 m₃+m₄≤2n₃+5 is satisfied.)

The R^{α} is preferably a hydrogen atom or a methyl group from the viewpoint of the copolymerizability of a monomer that affords the structural unit (III).

The L^{CA} is preferably a single bond or —COO—*.

Examples of the protecting group that is deprotected due to the action of the acid represented by R¹⁰¹ include groups represented by the following formulas (AL-1) to (AL-3).

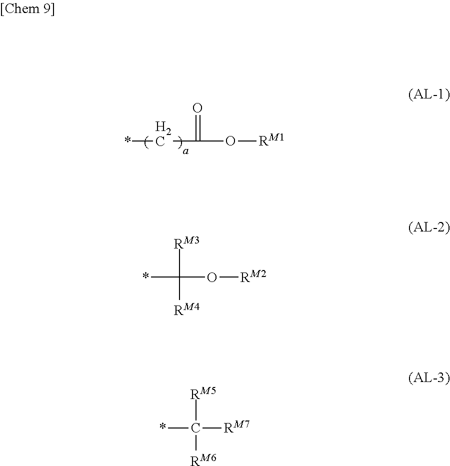

In formulas (AL-1) and (AL-2), R^{M1} and R^{M2} are monovalent hydrocarbon groups, and may contain a heteroatom such as an oxygen atom, a sulfur atom, a nitrogen atom, or a fluorine atom. The monovalent hydrocarbon group may be linear, branched, or cyclic, and is preferably an alkyl group having 1 to 40 carbon atoms, and more preferably an alkyl group having 1 to 20 carbon atoms. In formula (AL-1), a is an integer of 0 to 10, and preferably an integer of 1 to 5. In formulas (AL-1) to (AL-3), * is a bond to another moiety.

In formula (AL-2), R^{M3} and R^{M4} are each independently a hydrogen atom or a monovalent hydrocarbon group, and may contain a heteroatom such as an oxygen atom, a sulfur atom, a nitrogen atom, or a fluorine atom. The monovalent hydrocarbon group may be linear, branched, or cyclic, and is preferably an alkyl group having 1 to 20 carbon atoms. Any two of R^{M2}, R^{M3}, and R^{M4} may be bonded to each other to form a ring having 3 to 20 carbon atoms together with the carbon atom or the carbon atom and the oxygen atom to which they are bonded. The ring is preferably a ring having 4 to 16 carbon atoms, and particularly preferably an alicyclic ring.

In formula (AL-3), R^{M5}, R^{M6}, and R^{M7} are each independently a monovalent hydrocarbon group, and may contain a heteroatom such as an oxygen atom, a sulfur atom, a nitrogen atom, or a fluorine atom. The monovalent hydrocarbon group may be linear, branched, or cyclic, and is preferably an alkyl group having 1 to 20 carbon atoms. Any two of R^{M5}, R^{M6}, and R^{M7} may be bonded to each other to form a ring having 3 to 20 carbon atoms together with the carbon atom to which they are bonded. The ring is preferably a ring having 4 to 16 carbon atoms, and particularly preferably an alicyclic ring.

Among them, the protecting group that is deprotected due to the action of an acid is preferably a group represented by formula (AL-3).

Examples of the alkyl group in R¹⁰² include linear or branched alkyl groups having 1 to 8 carbon atoms such as a methyl group, an ethyl group, and a propyl group. Examples of the fluorinated alkyl group include linear or branched fluorinated alkyl groups having 1 to 8 carbon atoms such as a trifluoromethyl group and a pentafluoroethyl group. Examples of the alkoxycarbonyloxy group include chain or alicyclic alkoxycarbonyloxy groups having 2 to 16 carbon atoms such as a methoxycarbonyloxy group, a butoxycarbonyloxy group, and an adamantylmethyloxycarbonyloxy group. Examples of the acyl group include aliphatic or aromatic acyl groups having 2 to 12 carbon atoms such as an acetyl group, a propionyl group, a benzoyl group, and an acryloyl group. Examples of the acyloxy group include aliphatic or aromatic acyloxy groups having 2 to 12 carbon atoms such as an acetyloxy group, a propionyloxy group, a benzoyloxy group, and an acryloyloxy group.

The n₃ is preferably 0 or 1, and more preferably 0.

The m₃ is preferably an integer of 1 to 3, and more preferably 1 or 2.

The m₄ is preferably an integer of 0 to 3, and more preferably an integer of 0 to 2.

As the structural unit (III), structural units represented by the following formulas (3-1) to (3-12) (hereinafter also referred to as “structural units (3-1) to (3-12)”) and the like are preferable.

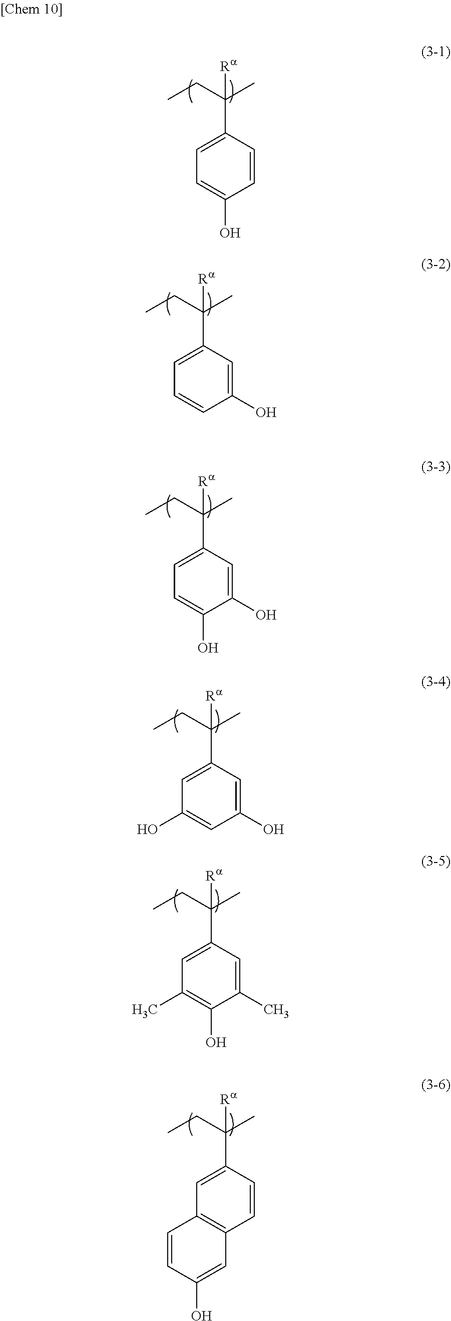

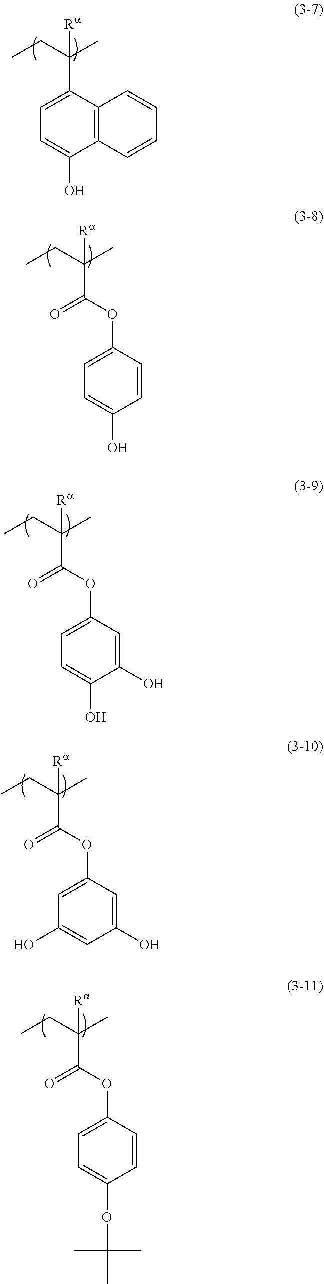

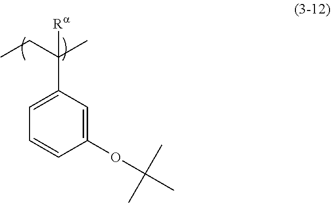

In formulas (3-1) to (3-12), R^{α} is the same as in the above formula (3).

Among them, the structural units (3-1) and (3-8) are preferable.

The lower limit of the content of the structural unit (III) (when a plurality of types of the structural unit (III) are contained, the total content thereof is taken) is preferably 5 mol %, more preferably 10 mol %, and still more preferably 15 mol % based on all structural units constituting the resin. The upper limit of the content is preferably 60 mol %, more preferably 55 mol %, and still more preferably 50 mol %. When the content of the structural unit (III) is set to fall within the above range, the sensitivity, CDU performance, and residual film ratio of the radiation-sensitive resin composition can further be improved.

In the case of polymerizing a monomer having a phenolic hydroxy group such as hydroxystyrene, it is preferable to polymerize the monomer with the phenolic hydroxy group protected by a protecting group such as an alkali-dissociable group and then deprotect it by hydrolysis to obtain a structural unit (III).

### (Structural Unit (IV))

The structural unit (IV) is a structural unit containing at least one structure selected from the group consisting of a lactone structure, a cyclic carbonate structure, and a sultone structure. When the base resin further has the structural unit (IV), the solubility of the base resin in a developer can be adjusted, and as a result, the lithographic performance, such as resolution, of the radiation-sensitive resin composition can be improved. In addition, the adhesion between a resulting resist pattern and a substrate can be improved.

Examples of the structural unit (IV) include structural units represented by the following formulas (T-1) to (T-10).

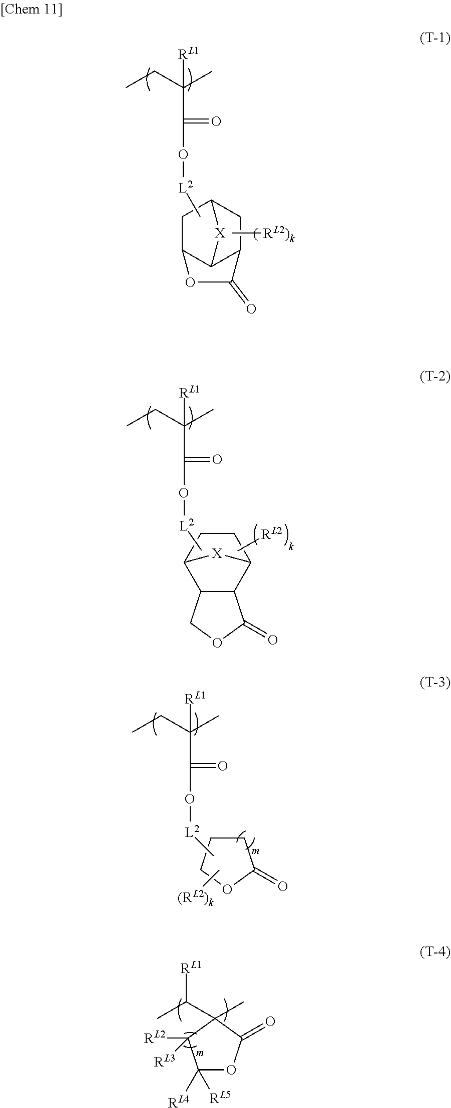

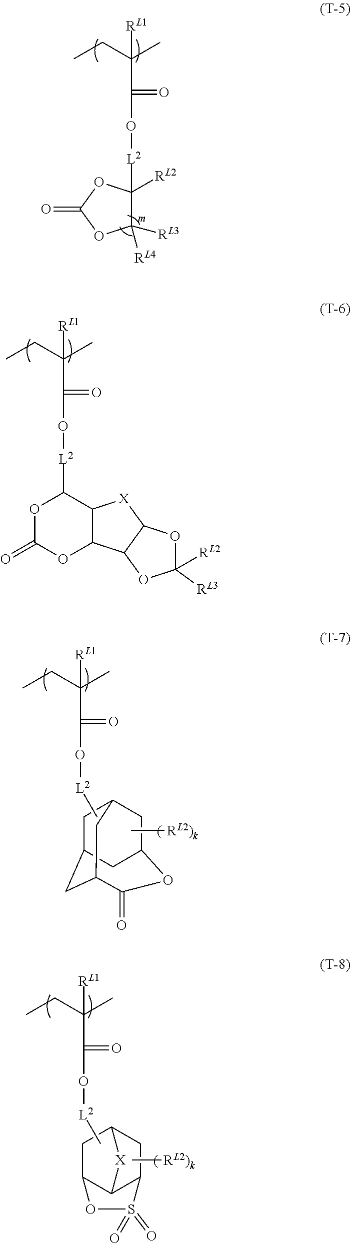

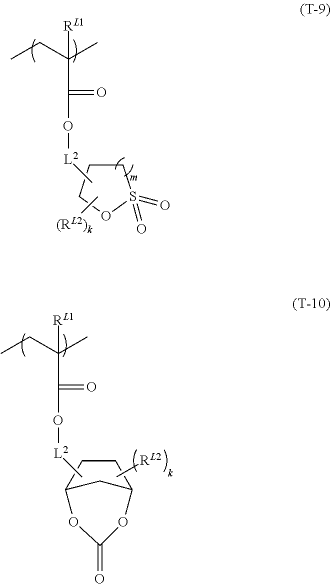

In the above formula, R^{L1} is a hydrogen atom, a fluorine atom, a methyl group, or a trifluoromethyl group. R^{L2} to R^{L5} are each independently a hydrogen atom, an alkyl group having 1 to 4 carbon atoms, a cyano group, a trifluoromethyl group, a methoxy group, a methoxycarbonyl group, a hydroxy group, a hydroxymethyl group, or a dimethylamino group. R^{L4} and R^{L5} may be combined with each other and constitute a divalent alicyclic group having 3 to 8 carbon atoms together with the carbon atom to which they are bonded. L² is a single bond or a divalent linking group. X is an oxygen atom or a methylene group. k is an integer of 0 to 3. m is an integer of 1 to 3.

The divalent alicyclic group having 3 to 8 carbon atoms composed of the R^{L4} and the R^{L5} combined together as well as the carbon atoms to which the R^{L4} and the R^{L5} are bonded is not particularly limited as long as it is a group formed by removing two hydrogen atoms from the same carbon atom contained in a carbon ring of a monocyclic or polycyclic alicyclic hydrocarbon having the aforementioned number of carbon atoms. The group may be either a monocyclic hydrocarbon group or a polycyclic hydrocarbon group, and the polycyclic hydrocarbon group may be either a bridged alicyclic hydrocarbon group or a fused alicyclic hydrocarbon group, and may be either a saturated hydrocarbon group or an unsaturated hydrocarbon group. It is to be noted that the fused alicyclic hydrocarbon group refers to a polycyclic alicyclic hydrocarbon group in which two or more alicyclic rings share a side (a bond between two adjacent carbon atoms).

Among the monocyclic alicyclic hydrocarbon groups, as the saturated hydrocarbon group, a cyclopentanediyl group, a cyclohexanediyl group, a cycloheptanediyl group, a cyclooctanediyl group, and the like are preferable, and as the unsaturated hydrocarbon group, a cyclopentenediyl group, a cyclohexenediyl group, a cycloheptenediyl group, a cyclooctenediyl group, a cyclodecenediyl group, and the like are preferable. As the polycyclic alicyclic hydrocarbon group, bridged alicyclic saturated hydrocarbon groups are preferable, and for example, a bicyclo[2.2.1]heptane-2,2-diyl group (norbornane-2,2-diyl group), a bicyclo[2.2.2]octane-2,2-diyl group, and a tricyclo[3.3.1.1^{3,7}]decane-2,2-diyl group (adamantane-2,2-diyl group) are preferable. One or more hydrogen atoms on the alicyclic group may be replaced by a hydroxy group.

Examples of the divalent linking group represented by L² include a divalent linear or branched hydrocarbon group having 1 to 10 carbon atoms, a divalent alicyclic hydrocarbon group having 4 to 12 carbon atoms, and a group composed of one or more among these hydrocarbon groups and at least one group among —CO—, —O—, —NH—, and —S.

Among them, the structural unit (IV) is preferably a structural unit containing a lactone structure, more preferably a structural unit containing a norbornane lactone structure, and still more preferably a structural unit derived from norbornane lactone-yl (meth)acrylate.

The lower limit of the content of the structural unit (IV) is preferably 3 mol %, more preferably 5 mol %, and still more preferably 8 mol % based on all structural units constituting the resin. The upper limit of the content is preferably 50 mol %, more preferably 45 mol %, and still more preferably 40 mol %. When the content of the structural unit (IV) is adjusted to within the range, the lithographic performance, such as resolution, of the radiation-sensitive resin composition and the adhesion between a resist patter to be formed and a substrate can be further improved.

### (Structural Unit (V))

The structural unit (V) is a structural unit containing an acid-dissociable group (excluding those corresponding to the structural unit (I)). As the structural unit (V), a structural unit represented by formula (4) (hereinafter also referred to as “structural unit (V-1)”) is preferable from the viewpoint of improvement in the pattern-forming performance of the radiation-sensitive resin composition.

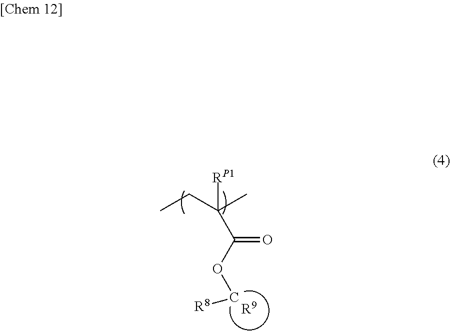

In the above formula (4), R^{P1} is a hydrogen atom, a fluorine atom, a methyl group, or a trifluoromethyl group, R⁸ is a monovalent hydrocarbon group having 1 to 20 carbon atoms, R⁹ represents a divalent alicyclic group having 3 to 20 carbon atoms constituted together with the carbon atom to which R⁹ bonds.

From the viewpoint of the copolymerizability of a monomer that affords the structural unit (V-1), a hydrogen atom and a methyl group are preferable as the R^{P1}, and a methyl group is more preferable.

As the monovalent hydrocarbon groups having 1 to 20 carbon atoms represented by R⁸, the groups disclosed as the monovalent hydrocarbon group having 1 to 20 carbon atoms represented by R^{X} in the above formula (1) and the like can be employed.

R⁸ is preferably a linear or branched saturated hydrocarbon group having 1 to 10 carbon atoms or an alicyclic hydrocarbon group having 3 to 20 carbon atoms.

The divalent alicyclic group having 3 to 20 carbon atoms represented by R⁹ is not particularly limited as long as it is a group obtained by removing two hydrogen atoms from a single carbon atom constituting a carbocycle of the monocyclic or polycyclic alicyclic hydrocarbon having the same number of carbon atoms as that of the carbon atoms of the divalent alicyclic group. The group may be either a monocyclic hydrocarbon group or a polycyclic hydrocarbon group, and the polycyclic hydrocarbon group may be either a bridged alicyclic hydrocarbon group or a fused alicyclic hydrocarbon group, and may be either a saturated hydrocarbon group or an unsaturated hydrocarbon group. It is to be noted that the condensed alicyclic hydrocarbon group refers to a polycyclic alicyclic hydrocarbon group in which two or more alicyclic rings share their sides (bond between two adjacent carbon atoms).

Among the monocyclic alicyclic hydrocarbon groups, a cyclopentanediyl group, a cyclohexanediyl group, a cycloheptanediyl group, a cyclooctanediyl group, and the like are preferable as the saturated hydrocarbon group, and a cyclopentenediyl group, a cyclohexenediyl group, a cycloheptenediyl group, a cyclooctenediyl group, a cyclodecenediyl group, and the like are preferable as the unsaturated hydrocarbon group. The polycyclic alicyclic hydrocarbon group is preferably a bridged alicyclic saturated hydrocarbon group, and preferred examples thereof include a bicyclo[2.2.1]heptane-2,2-diyl group (norbornane-2,2-diyl group), a bicyclo[2.2.2]octane-2,2-diyl group, and a tricyclo[3.3.1.1^{3,7}]decane-2,2-diyl group (adamantane-2,2-diyl group).

Among them, R⁸ is preferably an alkyl group having 1 to 4 carbon atoms, and the alicyclic structure in R⁹ is preferably a monocyclic cycloalkane structure having 5 to 8 carbon atoms.

Examples of the structural unit (V-1) include structural units represented by formulas (4-1) to (4-3) (hereinafter also referred to as “structural units (V-1-1) to (V-1-3)”).

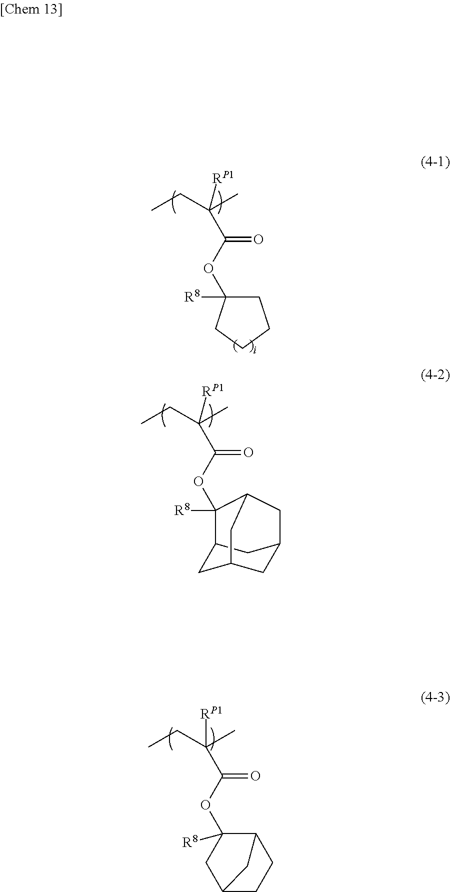

In the above formulas (4-1) to (4-3), R^{P1} and R⁸ have the same meaning as in the above formula (4). i is an integer of 1 to 4.

i is preferably 1 or 2. R⁸ is preferably a methyl group, an ethyl group, an isopropyl group, or a phenyl group.

The base resin may contain one type or a combination of two or more types of the structural unit (V).

When the resin contains the structural unit (V), the lower limit of the content of the structural unit (V) (when a plurality of types of the structural unit (V) are contained, the total content thereof is taken) is preferably 1 mol %, more preferably 2 mol %, and still more preferably 3 mol % based on all structural units constituting the resin. The upper limit of the content is preferably 30 mol %, more preferably 20 mol %, and still more preferably 15 mol %. When the content of the structural unit (V) is set to fall within the above range, the pattern-forming performance of the radiation-sensitive resin composition can further be improved.

### (Structural Unit (VI))

The base resin optionally has other structural units in addition to the structural units (I) to (V). Examples of the other structural units include a structural unit (VI) containing a polar group (excluding those corresponding to the structural units (III) and (VI)). When the base resin further has a structural unit (VI), solubility in the developer can be adjusted. As a result, lithographic performance such as resolution of the radiation-sensitive resin composition can be improved. Examples of the polar group include a hydroxy group, a carboxy group, a cyano group, a nitro group, and a sulfonamide group. Among them, a hydroxy group and a carboxy group are preferable, and a hydroxy group is more preferable.

Examples of the structural unit (VI) include structural units represented by formulas.

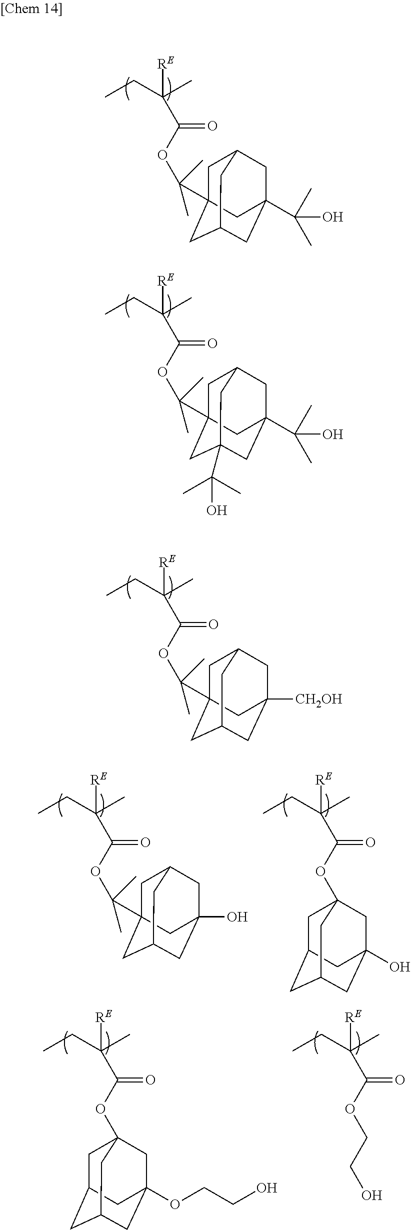

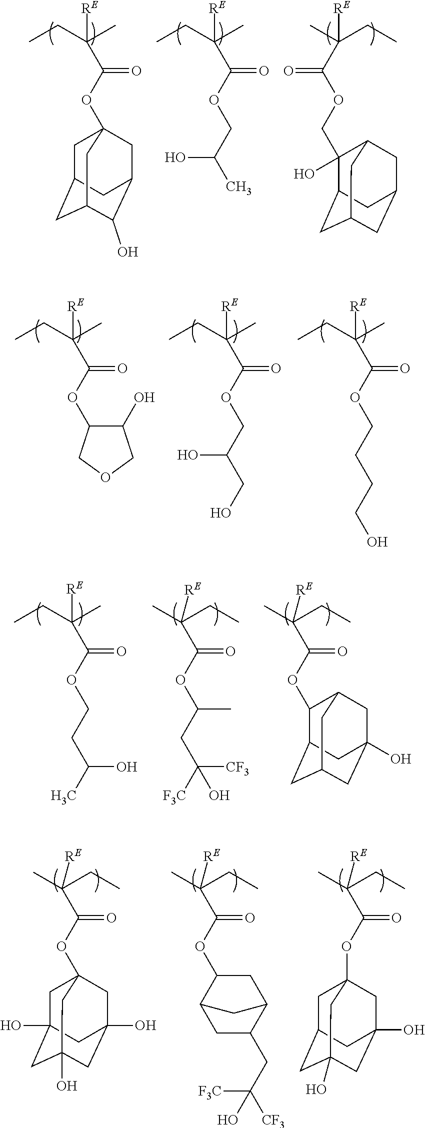

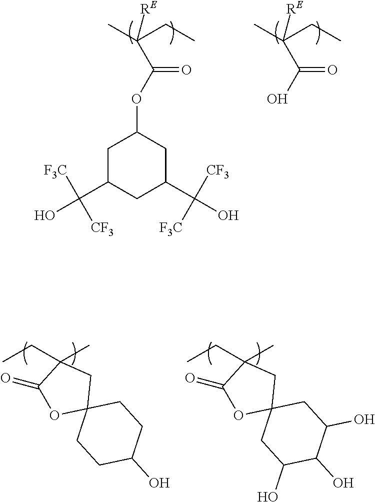

In the above formulas, R^{E} is a hydrogen atom, a fluorine atom, a methyl group, or a trifluoromethyl group.

When the resin contains the structural unit (VI) having a polar group, the lower limit of the content of the structural unit (VI) is preferably 3 mol %, more preferably 5 mol %, and still more preferably 8 mol % based on all structural units constituting the resin. The upper limit of the content is preferably 40 mol %, more preferably 30 mol %, and still more preferably 25 mol %. When the content of the structural unit (VI) is adjusted to within the above range, the lithographic performance such as resolution of the radiation-sensitive resin composition can be further improved.

### (Structural Unit (VII))

The resin may contain a structural unit having an organic acid anion moiety and an onium cation moiety as an additional structural unit (VII). The structural unit (VII) is preferably represented by formula (a1) or (a2).

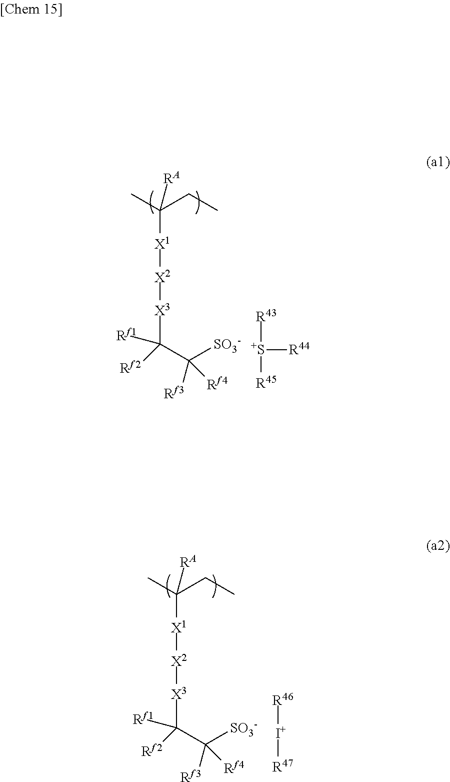

In formulas, R^{A} is a hydrogen atom or a methyl group. X¹ is a single bond or an ester group. X² is a linear, branched or cyclic alkylene group having 1 to 12 carbon atoms or an arylene group having 6 to 10 carbon atoms, and a part of the methylene groups constituting the alkylene group may be replaced by an ether group, an ester group, or a lactone ring-containing group. At least one hydrogen atom contained in X² may be replaced by an iodine atom. X³ is a single bond, an ether group, an ester group, or a linear, branched or cyclic alkylene group having 1 to 12 carbon atoms, and some of the methylene groups constituting the alkylene group may be replaced by an ether group or an ester group. Rf¹ to Rf⁴ are each independently a hydrogen atom, a fluorine atom, or a trifluoromethyl group, and at least one of Rf¹ to Rf⁴ is a fluorine atom or a fluorinated hydrocarbon group. R⁴³ to R⁴⁷ are each independently a monovalent hydrocarbon group having 1 to 20 carbon atoms and optionally containing a heteroatom, and R⁴³ and R⁴⁴ may be bonded to each other to form a ring together with the sulfur atom to which they are bonded.

As the monovalent hydrocarbon group having 1 to 20 carbon atoms and optionally containing a heteroatom in R⁴³ to R⁴⁷, an alkyl group having 1 to 12 carbon atoms, a cycloalkyl group having 3 to 12 carbon atoms, or an aryl group having 6 to 20 carbon atoms is preferable, and some or all of the hydrogen atoms of these groups may be replaced by a hydroxy group, a carboxy group, a halogen atom, an oxo group, a cyano group, an amide group, a nitro group, a sultone group, a sulfone group, or a sulfonium salt-containing group, and some of the methylene groups constituting these groups may be replaced by an ether group, an ester group, a carbonyl group, a carbonate group, or a sulfonic acid ester group.

Formulas (a1) and (a2) are preferably represented by formulas (a1-1) and (a2-1), respectively.

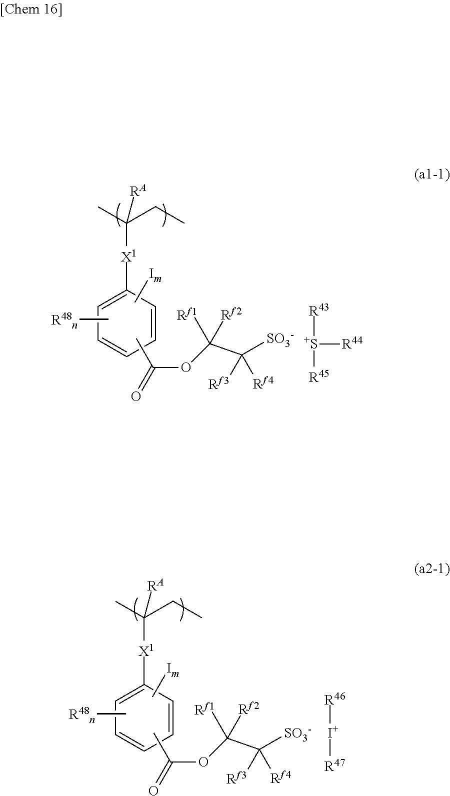

In formulas, R^{A}, R⁴³ to R⁴⁷, Rf¹ to Rf⁴, and X¹ have the same meanings as formula (a1) or (a2). R⁴⁸ is a linear, branched or cyclic alkyl group having 1 to 4 carbon atoms, a halogen atom other than iodine atom, a hydroxy group, a linear, branched or cyclic alkoxy group having 1 to 4 carbon atoms, or a linear, branched or cyclic alkoxycarbonyl group having 2 to 5 carbon atoms. m is an integer of 0 to 4 n is an integer of 0 to 3.

Examples of the organic acid anion moiety of the monomer that affords the structural unit (VII) include, but are not limited to, those shown below. While all of those shown below are organic acid anion moieties having an iodine-substituted aromatic ring structure, organic acid anion moieties having no iodine-substituted aromatic ring structure that can be suitably employed include structures in which the iodine atoms in formulas shown below are replaced by an atom or group other than an iodine atom such as a hydrogen atom or other substituent.

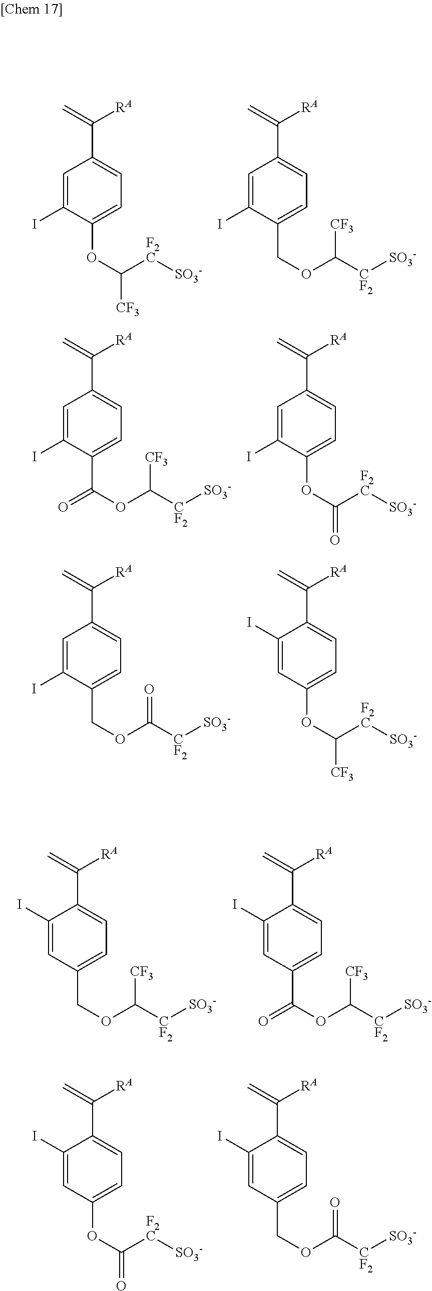

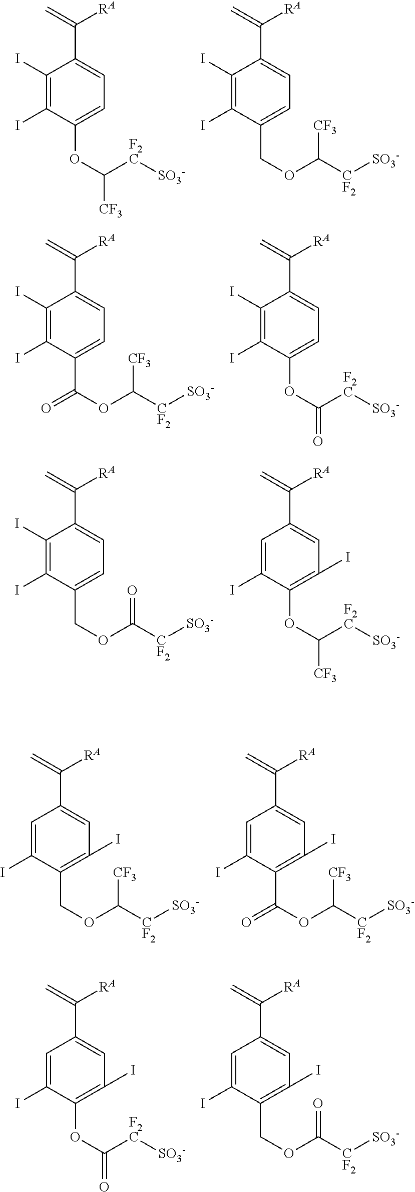

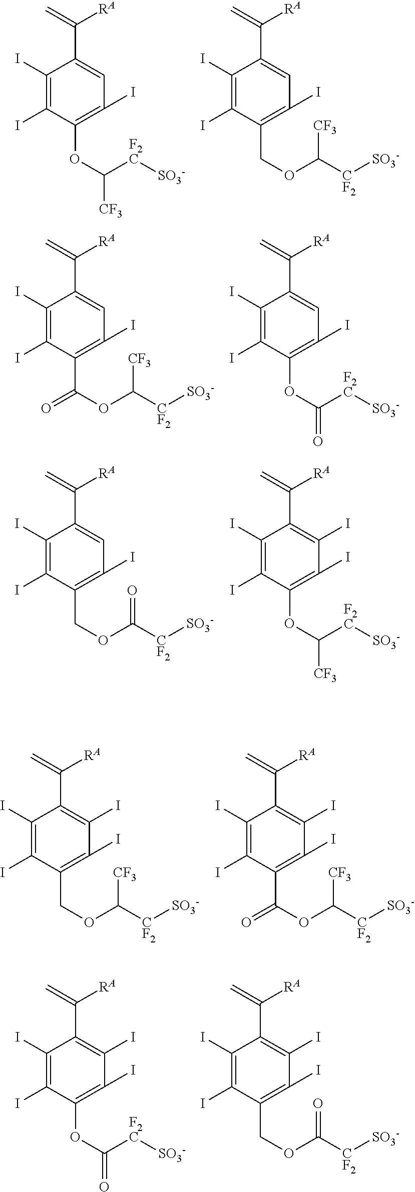

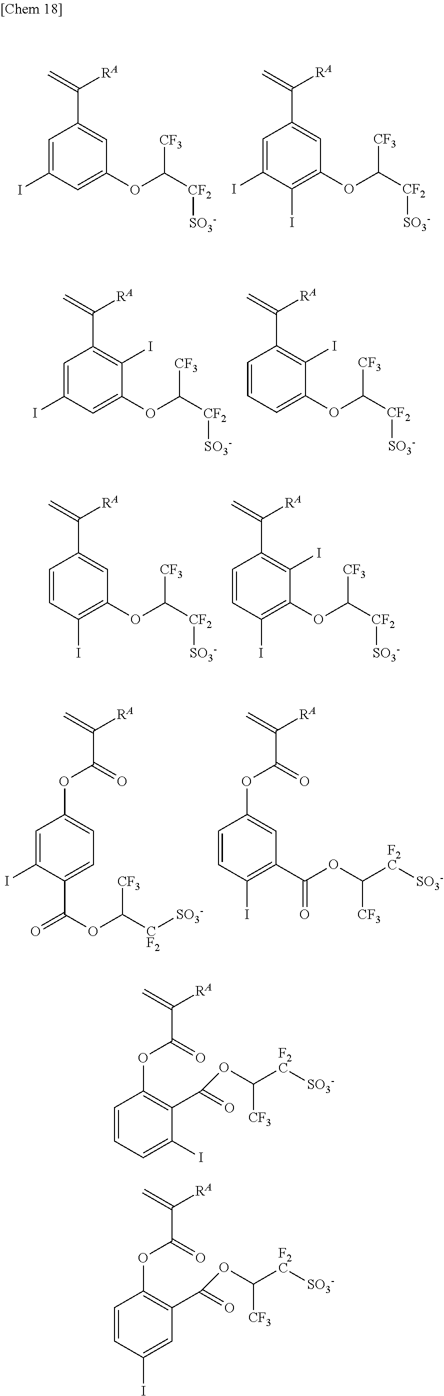

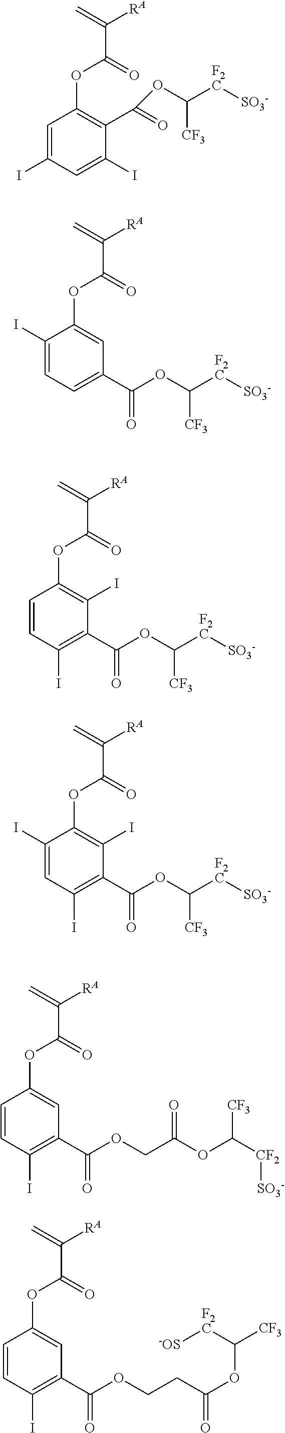

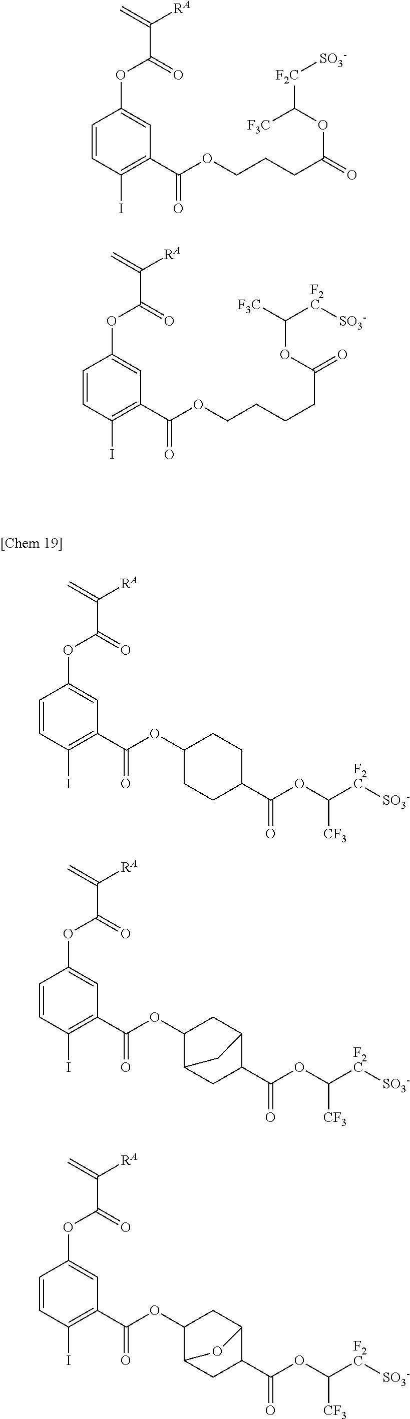

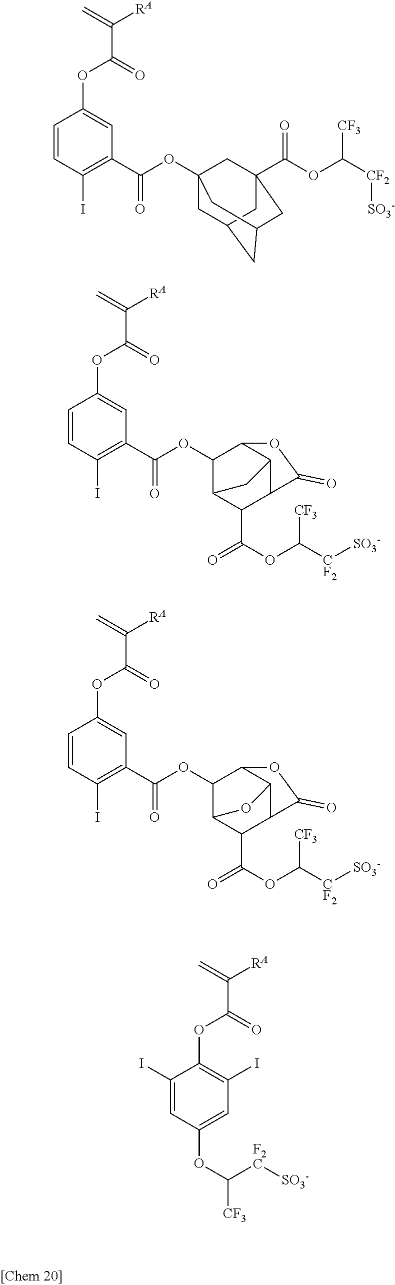

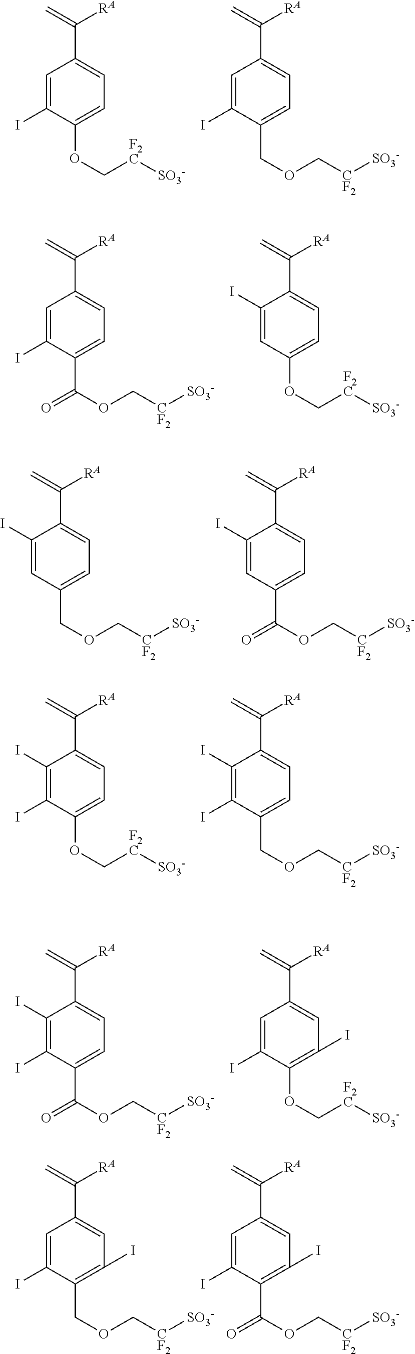

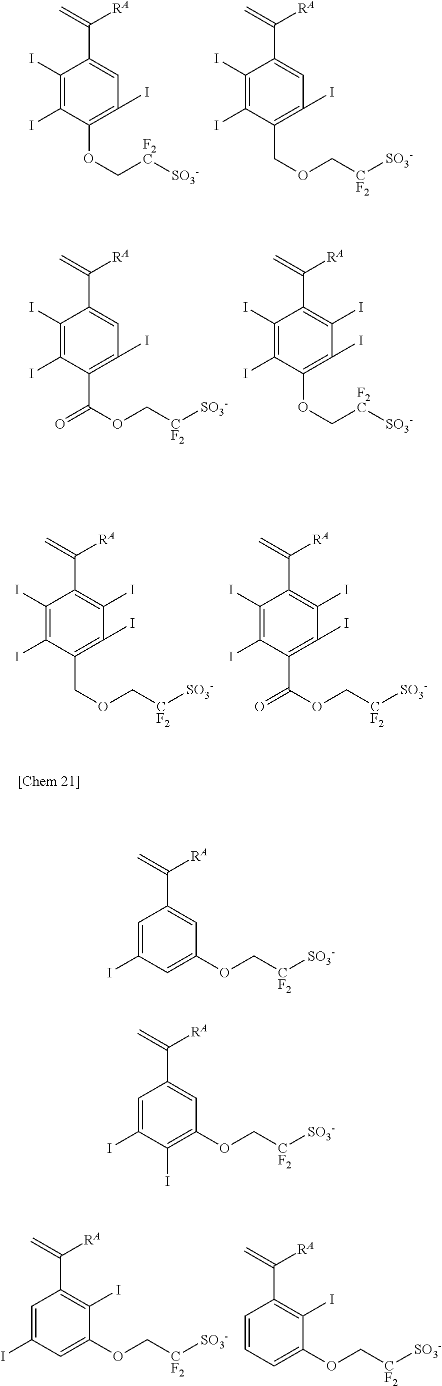

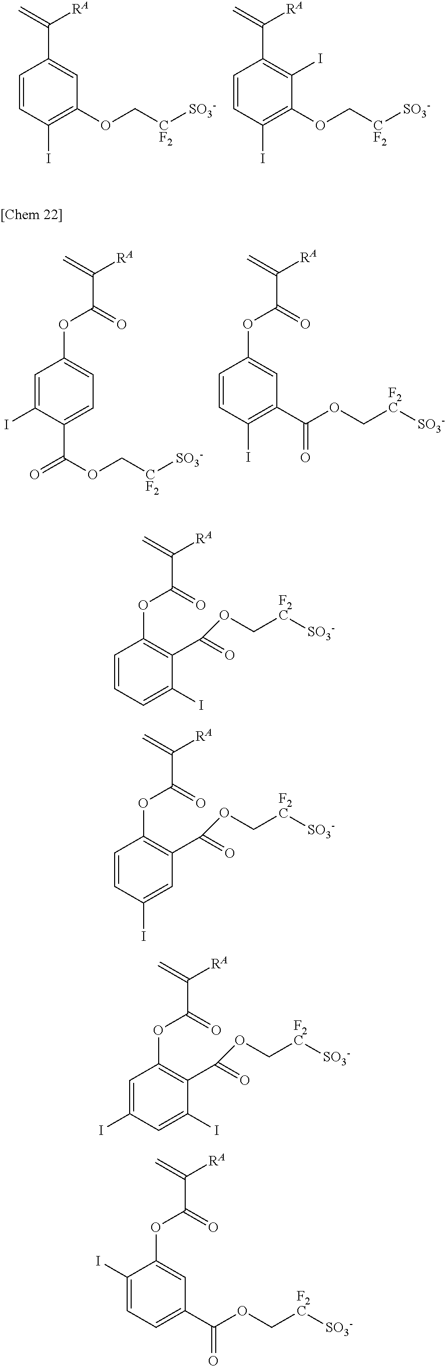

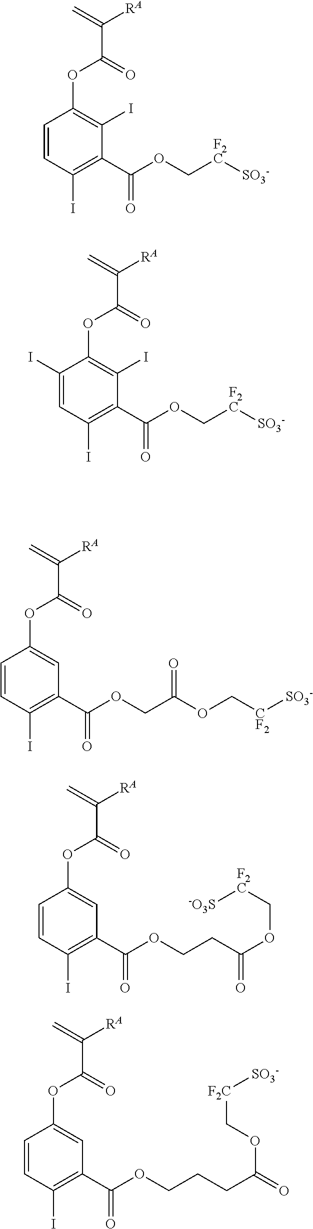

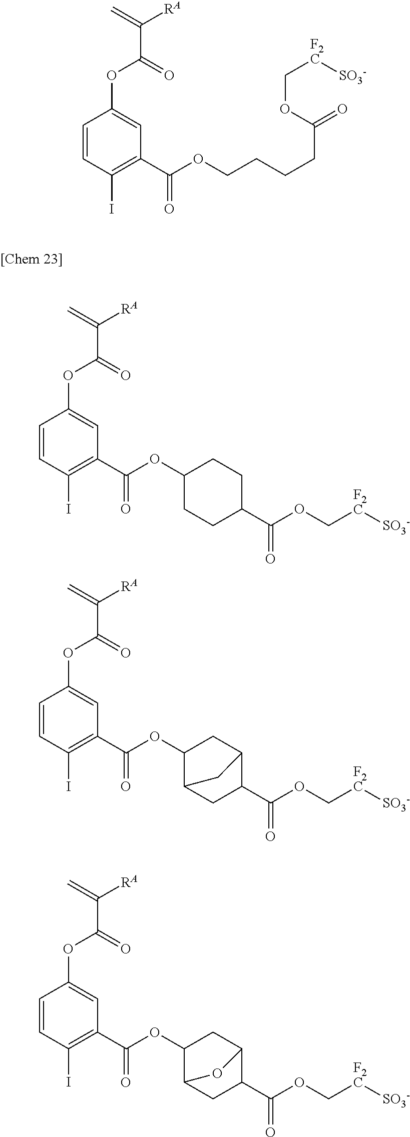

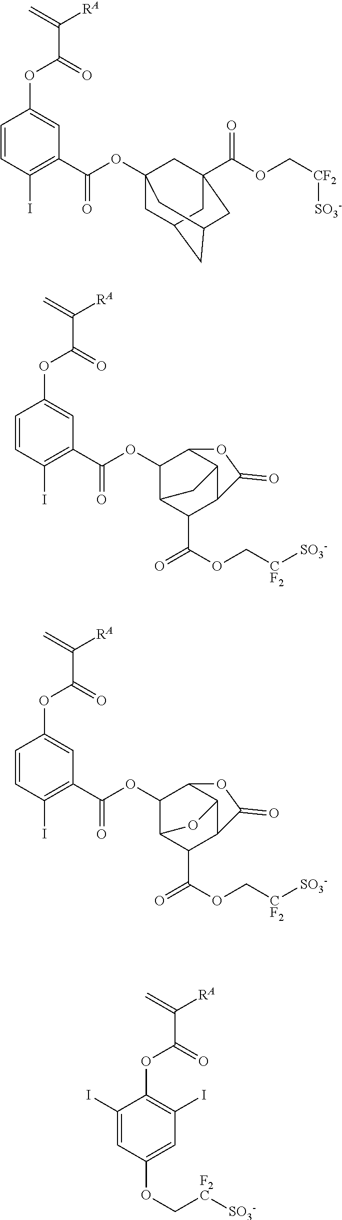

The onium cation moiety of formula (a1) is preferably represented by the following formula (Q-1).

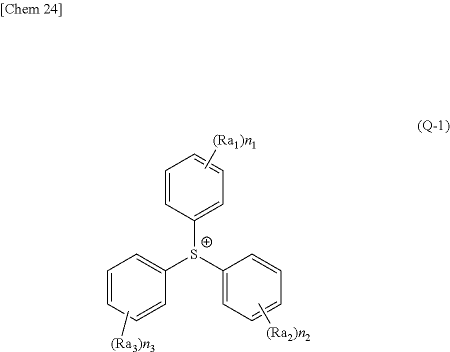

In formula (Q-1), Ra1 and Ra2 each independently represent a substituent. n1 represents an integer of 0 to 5, and when n1 is 2 or more, the plurality of Ra1s may be the same or different. n2 represents an integer of 0 to 5, and when n2 is 2 or more, the plurality of Ra2s may be the same or different. n3 represents an integer of 0 to 5, and when n3 is 2 or more, the plurality of Ra3s may be the same or different. Ra3 represents a fluorine atom or a group having one or more fluorine atoms. When n1 is 1 or more and n2 is 1 or more, Ra1 and Ra2 may be linked to each other to form a ring (namely, a heterocyclic ring containing a sulfur atom). When n1 is 2 or more, a plurality of Ra1's may be linked to each other to form a ring. When n2 is 2 or more, a plurality of Ra2's may be linked to each other to form a ring.

The substituent represented by Ra1 and Ra2 is preferably an alkyl group, a cycloalkyl group, an alkoxy group, a cycloalkyloxy group, an alkoxycarbonyl group, an alkylsulfonyl group, a hydroxy group, a halogen atom, or a halogenated hydrocarbon group.

The alkyl group as Ra1 and Ra2 may be either a linear alkyl group or a branched alkyl group. The alkyl group is preferably one having 1 to 10 carbon atoms, and examples thereof include a methyl group, an ethyl group, a n-propyl group, an i-propyl group, a n-butyl group, a 2-methylpropyl group, a 1-methylpropyl group, a t-butyl group, a n-pentyl group, a neopentyl group, a n-hexyl group, a n-heptyl group, a n-octyl group, a 2-ethylhexyl group, a n-nonyl group, and a n-decyl group. Among them, a methyl group, an ethyl group, a n-butyl group, and a t-butyl group are particularly preferable.

Examples of the cycloalkyl group as Ra1 and Ra2 include monocyclic or polycyclic cycloalkyl groups (preferably cycloalkyl groups having 3 to 20 carbon atoms), and examples thereof include a cyclopropyl group, a cyclobutyl group, a cyclopentyl group, a cyclohexyl group, a cycloheptyl group, a cyclooctyl group, a cyclododecanyl group, a cyclopentenyl group, a cyclohexenyl group, and a cyclooctadienyl group. Among these, a cyclopropyl group, a cyclopentyl group, a cyclohexyl group, a cyclohexyl group, a cycloheptyl group, and a cyclooctyl group are particularly preferable.

Examples of the alkyl group moiety of the alkoxy group as Ra1 and Ra2 include those listed above as the alkyl group as Ra1 and Ra2. As the alkoxy group, a methoxy group, an ethoxy group, a n-propoxy group, and a n-butoxy group are particularly preferable.

Examples of the cycloalkyl group moiety of the cycloalkyloxy group as Ra1 and Ra2 include those listed above as the cycloalkyl group as Ra1 and Ra2. As the cycloalkyloxy group, a cyclopentyloxy group and a cyclohexyloxy group are particularly preferable.

Examples of the alkoxy group moiety of the alkoxycarbonyl group as Ra1 and Ra2 include those listed above as the alkoxy group as Ra1 and Ra2. As the alkoxycarbonyl group, a methoxycarbonyl group, an ethoxycarbonyl group, and a n-butoxycarbonyl group are particularly preferable.

Examples of the alkyl group moiety of the alkylsulfonyl group as Ra1 and Ra2 include those listed above as the alkyl group as Ra1 and Ra2. Examples of the cycloalkyl group moiety of the cycloalkylsulfonyl group as Ra1 and Ra2 include those listed above as the cycloalkyl group as Ra1 and Ra2. As the alkylsulfonyl group or the cycloalkylsulfonyl group, a methanesulfonyl group, an ethanesulfonyl group, a n-propanesulfonyl group, a n-butanesulfonyl group, a cyclopentanesulfonyl group, and a cyclohexanesulfonyl group are particularly preferable.

Each of the groups Ra1 and Ra2 may further have a substituent. Examples of the substituent include a halogen atom such as a fluorine atom (preferably a fluorine atom), a hydroxy group, a carboxy group, a cyano group, a nitro group, an alkoxy group, a cycloalkyloxy group, an alkoxyalkyl group, a cycloalkyloxyalkyl group, an alkoxycarbonyl group, a cycloalkyloxycarbonyl group, an alkoxycarbonyloxy group, and a cycloalkyloxycarbonyloxy group.

Examples of the halogen atom as Ra1 and Ra2 include a fluorine atom, a chlorine atom, a bromine atom, and an iodine atom, and a fluorine atom is preferable.

As the halogenated hydrocarbon group as Ra1 and Ra2, a halogenated alkyl group is preferable. Examples of the alkyl group and the halogen atom constituting the halogenated alkyl group include those described above. Among them, a fluorinated alkyl group is preferable, and CF₃ is more preferable.

As described above, Ra1 and Ra2 may be linked to each other to form a ring (namely, a heterocyclic ring containing a sulfur atom). In this case, it is preferable that Ra1 and Ra2 are bonded to each other to form a single bond or a divalent linking group. Examples of the divalent linking group include —COO—, —OCO—, —CO—, —O—, —S—, —SO—, —SO₂—, an alkylene group, a cycloalkylene group, an alkenylene group, and combinations of two or more thereof, and those having of 20 or less carbon atoms in total are preferable. When Ra1 and Ra2 are linked to each other to form a ring, it is preferable that Ra1 and Ra2 are bonded to each other to form —COO—, —OCO—, —CO—, —O—, —S—, —SO—, —SO₂—, or a single bond. Among them, it is more preferable to form —O—, —S—, or a single bond, and it is particularly preferable to form a single bond. When n1 is 2 or more, a plurality of Ra1's may be linked to each other to form a ring, and when n2 is 2 or more, a plurality of Ra2's may be linked to each other to form a ring. Examples thereof include an embodiment in which two Ra1's are linked to each other to form a naphthalene ring together with a benzene ring to which they are bonded.

Ra3 is a fluorine atom or a group having one or more fluorine atoms. Examples of the group having a fluorine atom include groups in which an alkyl group, a cycloalkyl group, an alkoxy group, a cycloalkyloxy group, an alkoxycarbonyl group, and an alkylsulfonyl group as Ra1 and Ra2 are substituted with a fluorine atom. Among them, fluorinated alkyl groups are suitable, CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉ are more suitable, and CF₃ is particularly suitable.

Ra3 is preferably a fluorine atom or CF₃, and more preferably a fluorine atom.

n1 and n2 are each independently preferably an integer of 0 to 3, and preferably an integer of 0 to 2.

n3 is preferably an integer of 1 to 3, and more preferably 1 or 2.

(n1+n2+n3) is preferably an integer of 1 to 15, more preferably an integer of 1 to 9, still more preferably an integer of 2 to 6, and particularly preferably an integer of 3 to 6. When (n1+n2+n3) is 1, it is preferable that n3=1 and Ra3 is a fluorine atom or CF₃. When (n1+n2+n3) is 2, a combination in which n1=n3=1 and Ra1 and Ra3 are each independently a fluorine atom or CF₃ and a combination in which n3=2 and Ra3 is a fluorine atom or CF₃ are preferable. When (n1+n2+n3) is 3, a combination in which n1=n2=n3=1 and Ra1 to Ra3 are each independently a fluorine atom or CF₃ is preferable. When (n1+n2+n3) is 4, a combination in which n1=n3=2 and Ra1 and Ra3 are each independently a fluorine atom or CF₃ is preferable. When (n1+n2+n3) is 5, a combination in which n1=n2=1 and n3=3 and Ra1 to Ra3 are each independently a fluorine atom or CF₃, a combination in which n1=n2=2 and n3=1 and Ra1 to Ra3 are each independently a fluorine atom or CF₃, and a combination in which n3=5 and Ra3 are each independently a fluorine atom or CF₃ are preferable. When (n1+n2+n3) is 6, a combination in which n1=n2=n3=2 and Ra1 to Ra3 are each independently a fluorine atom or CF₃ is preferable.

Examples of such an onium cation moiety represented by formula (Q-1) include those shown below. While all of those shown below are sulfonium cation moieties having a fluorine-substituted aromatic ring structure (including a structure with a connecting group between a fluorine atom and an aromatic ring), onium cation moieties having no fluorine-substituted aromatic ring structure that can be suitably employed include structures in which the fluorine atoms or CF₃ in formulas shown below are replaced by an atom or group other than a fluorine atom such as a hydrogen atom or other substituent.

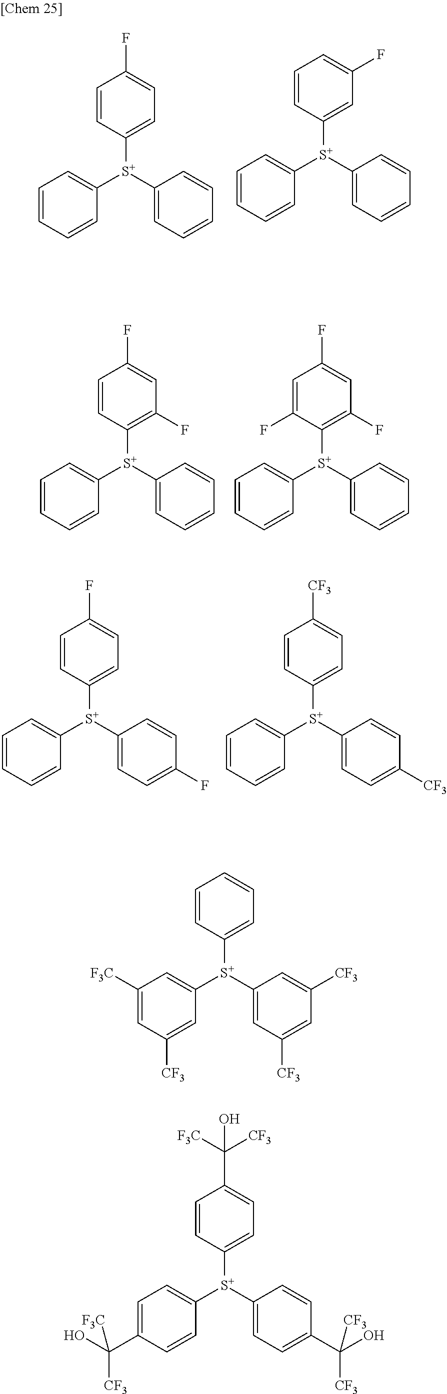

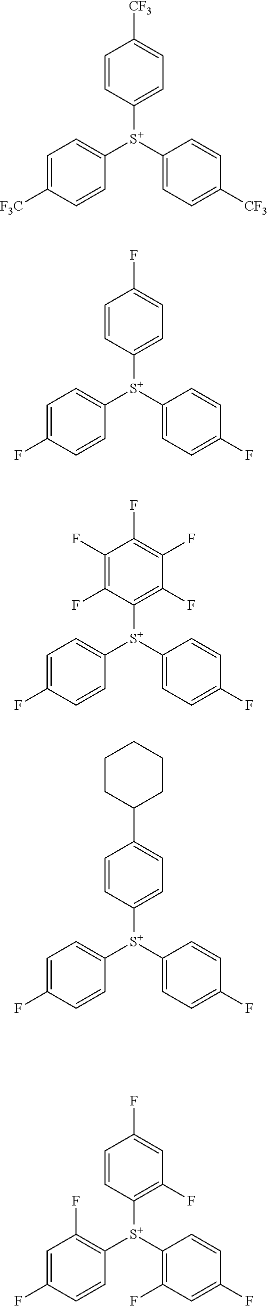 [SMILES: FC(F)(F)c1ccc([S+](c2ccc(C(F)(F)F)cc2)c2ccc(C(F)(F)F)cc2)cc1 ; Fc1ccc([S+](c2ccc(F)cc2)c2ccc(F)cc2)cc1 ; Fc1ccc([S+](c2ccc(F)cc2)c2c(F)c(F)c(F)c(F)c2F)cc1 ; Fc1ccc([S+](c2ccc(F)cc2)c2ccc(C3CCCCC3)cc2)cc1 ; Fc1ccc([S+](c2ccc(F)cc2F)c2ccc(F)cc2F)c(F)c1]

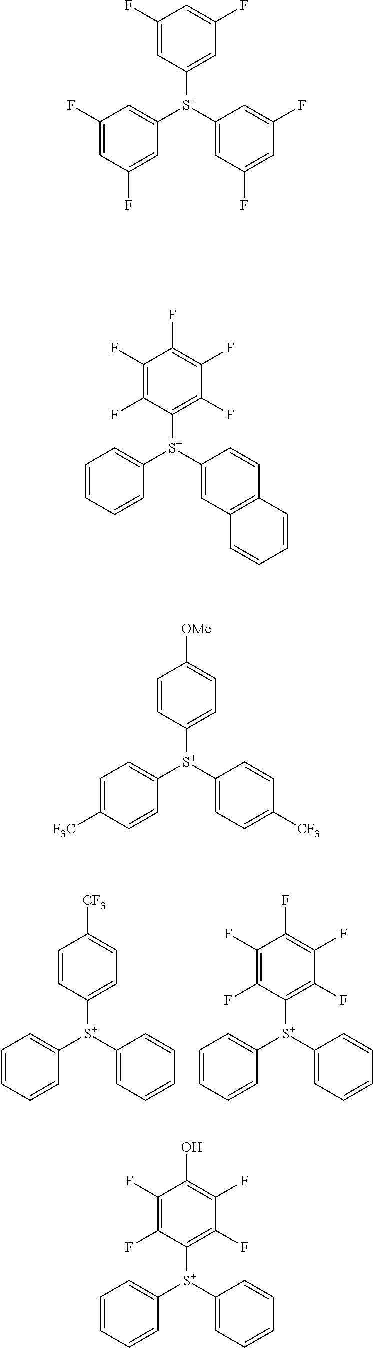 [SMILES: Fc1cc(F)cc([S+](c2cc(F)cc(F)c2)c2cc(F)cc(F)c2)c1 ; Fc1c(F)c(F)c([S+](c2ccccc2)c2ccc3ccccc3c2)c(F)c1F ; COc1ccc([S+](c2ccc(C(F)(F)F)cc2)c2ccc(C(F)(F)F)cc2)cc1 ; FC(F)(F)c1ccc([S+](c2ccccc2)c2ccccc2)cc1 ; Fc1c(F)c(F)c([S+](c2ccccc2)c2ccccc2)c(F)c1F ; Oc1c(F)c(F)c([S+](c2ccccc2)c2ccccc2)c(F)c1F]

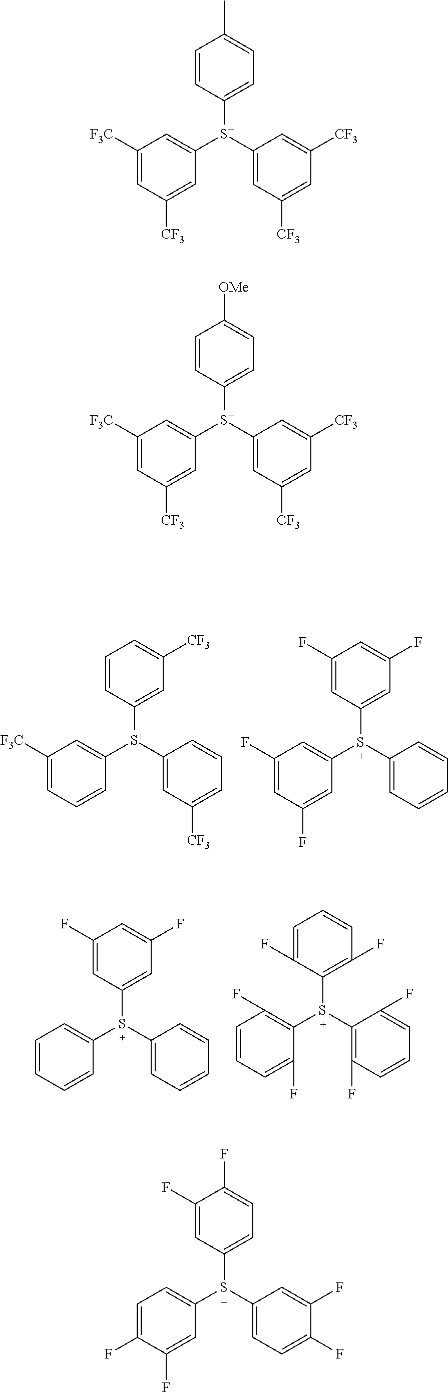

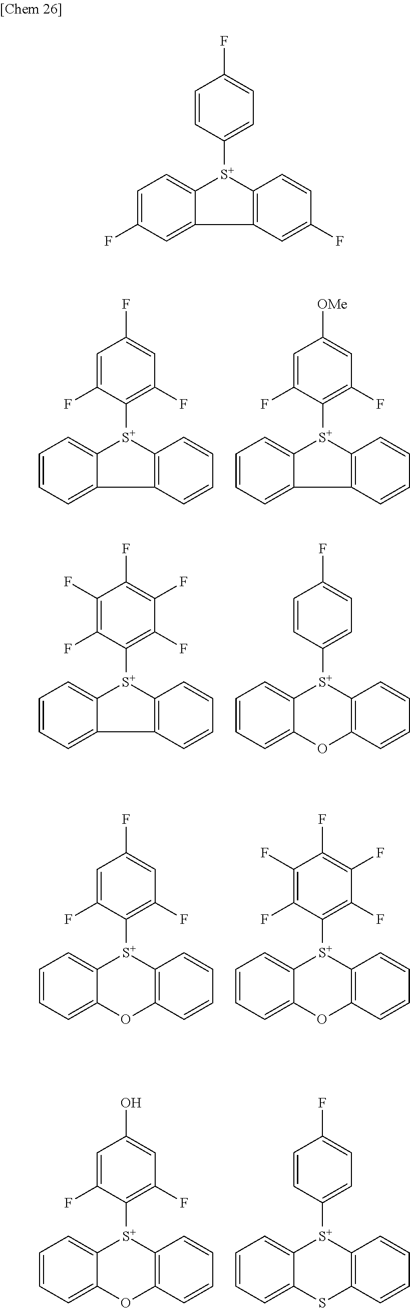

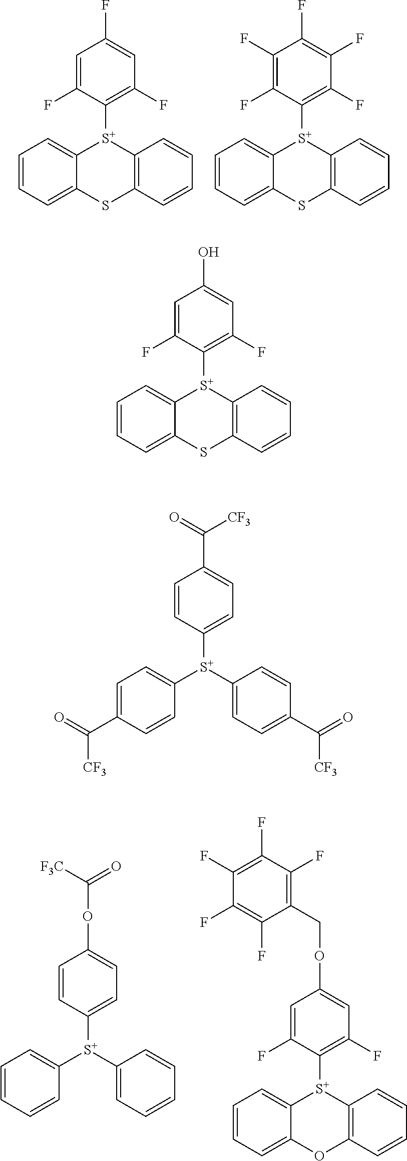 [SMILES: Fc1cc(F)c([S+]2c3ccccc3Sc3ccccc32)c(F)c1 ; Fc1c(F)c(F)c([S+]2c3ccccc3Sc3ccccc32)c(F)c1F ; Oc1cc(F)c([S+]2c3ccccc3Sc3ccccc32)c(F)c1 ; O=C(c1ccc([S+](c2ccc(C(=O)C(F)(F)F)cc2)c2ccc(C(=O)C(F)(F)F)cc2)cc1)C(F)(F)F ; O=C(Oc1ccc([S+](c2ccccc2)c2ccccc2)cc1)C(F)(F)F ; Fc1cc(OCc2c(F)c(F)c(F)c(F)c2F)cc(F)c1[S+]1c2ccccc2Oc2ccccc21]

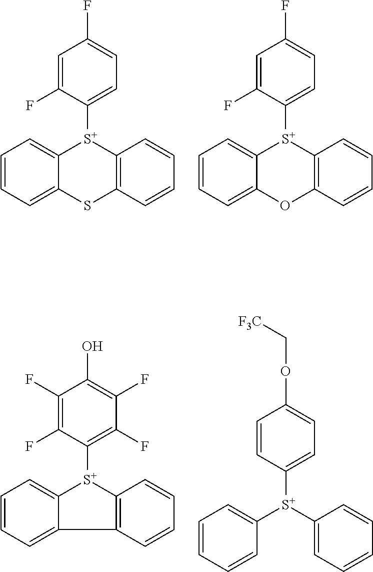 [SMILES: Fc1ccc([S+]2c3ccccc3Sc3ccccc32)c(F)c1 ; Fc1ccc([S+]2c3ccccc3Oc3ccccc32)c(F)c1 ; Oc1c(F)c(F)c(-[s+]2c3ccccc3c3ccccc32)c(F)c1F ; FC(F)(F)COc1ccc([S+](c2ccccc2)c2ccccc2)cc1]

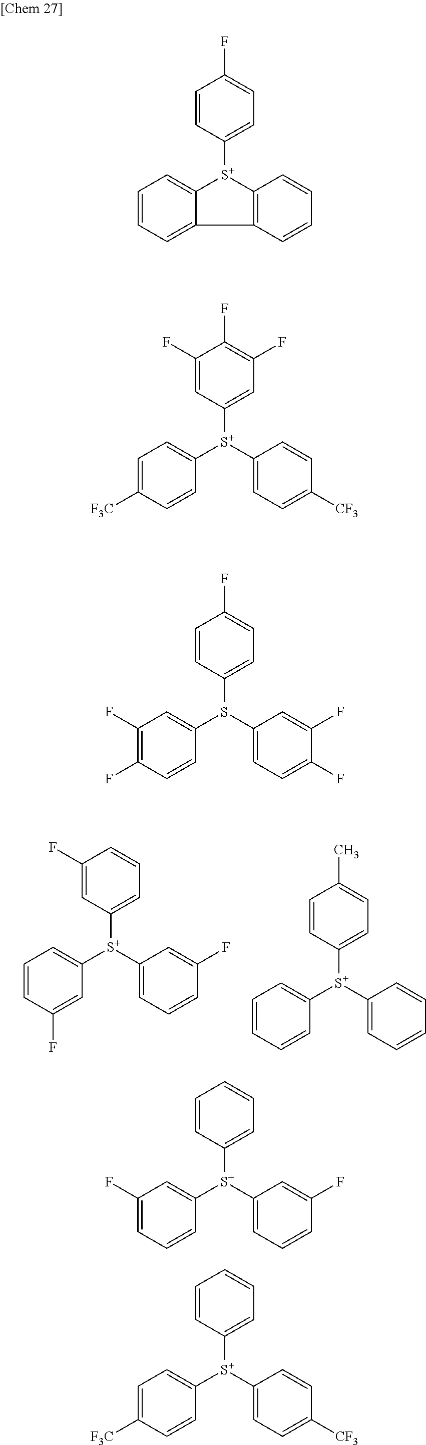

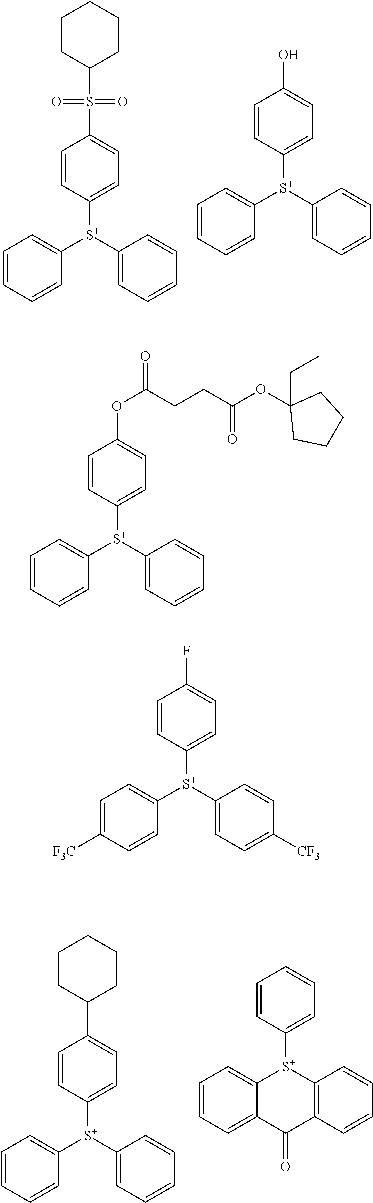 [SMILES: O=S(=O)(c1ccc([S+](c2ccccc2)c2ccccc2)cc1)C1CCCCC1 ; Oc1ccc([S+](c2ccccc2)c2ccccc2)cc1 ; CCC1(OC(=O)CCC(=O)Oc2ccc([S+](c3ccccc3)c3ccccc3)cc2)CCCC1 ; Fc1ccc([S+](c2ccc(C(F)(F)F)cc2)c2ccc(C(F)(F)F)cc2)cc1 ; c1ccc([S+](c2ccccc2)c2ccc(C3CCCCC3)cc2)cc1 ; O=c1c2ccccc2[s+](-c2ccccc2)c2ccccc12]

When the onium cation moiety of formula (a2) contains a fluorine-substituted aromatic ring structure, the onium cation moiety is preferably a diaryliodonium cation having one or more fluorine atoms. Among them, the onium cation moiety is preferably represented by the following formula (Q-2).

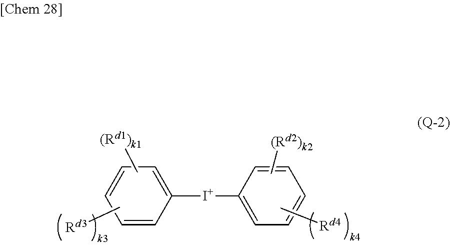

In formula, R^{d1} and R^{d2} are each independently a substituted or unsubstituted linear or branched alkyl group, alkoxy group or alkoxycarbonyl group having 1 to 12 carbon atoms, a substituted or unsubstituted aromatic hydrocarbon group having 6 to 12 carbon atoms, or a nitro group; R^{d3} and R^{d4} are each independently a fluorine atom or a group having a fluorine atom; k1 and k2 are each independently an integer of 0 to 5, k3 and k4 are each independently an integer of 0 to 5, provided that (k1+k3) and (k2+k4) are each 5 or less, and (k3+k4) is an integer of 1 to 10; and when there are a plurality of R^{d1}'s to R^{d4}'s, the plurality of R^{d1}'s to R^{d4}'s may be the same or different, respectively.

Examples of the alkyl group, the alkoxy group, and the alkoxycarbonyl group represented by R^{d1} and R^{d2} and the group having a fluorine atom represented by R^{d3} and R^{d4} include the same groups as those represented by the above formula (Q-1).

Examples of the monovalent aromatic hydrocarbon groups having 6 to 12 carbon atoms include aryl groups such as a phenyl group, a tolyl group, a xylyl group, and a naphthyl group; and aralkyl groups such as a benzyl group and a phenethyl group.

Examples of the substituent of the respective groups include halogen atoms such as a fluorine atom, a chlorine atom, a bromine atom, and an iodine atom; a hydroxy group; a carboxy group; a cyano group; a nitro group; an alkyl group, an alkoxy group, an alkoxycarbonyl group, an alkoxycarbonyloxy group, an acyl group, an acyloxy group, or a group in which a hydrogen atom of these groups has been substituted with a halogen atom; and an oxo group (═O).

k1 and k2 are each preferably 0 to 2, and more preferably 0 or 1. k3 and k4 are each preferably 1 to 3, and more preferably 1 or 2. (k3+k4) is an integer of 1 to 10, preferably an integer of 1 to 6, more preferably an integer of 1 to 4, and still more preferably 1 or 2.

Examples of such an onium cation moiety represented by formula (Q-2) include those shown below. While all of those shown below are iodonium cation moieties having a fluorine-substituted aromatic ring structure (including a structure with a connecting group between a fluorine atom and an aromatic ring), onium cation moieties having no fluorine-substituted aromatic ring structure that can be suitably employed include structures in which the fluorine atoms or CF₃ in formulas shown below are replaced by an atom or group other than a fluorine atom such as a hydrogen atom or other substituent.

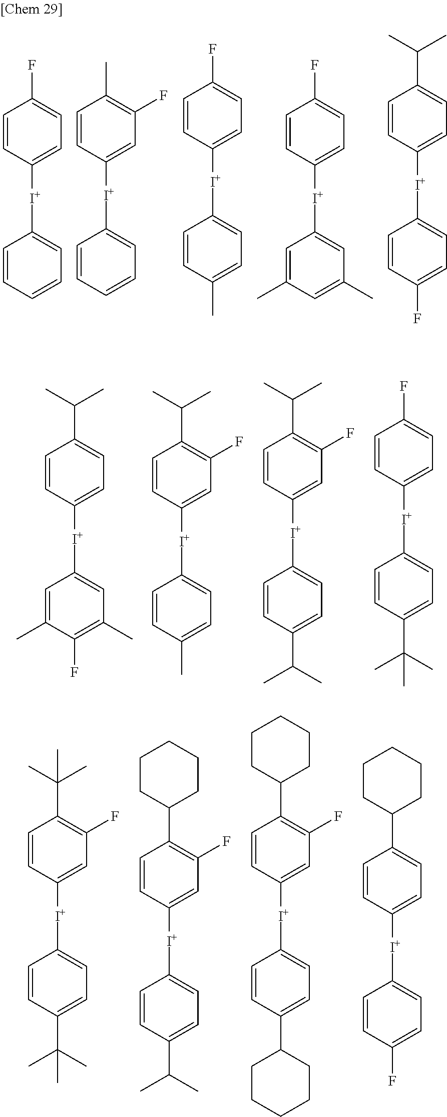

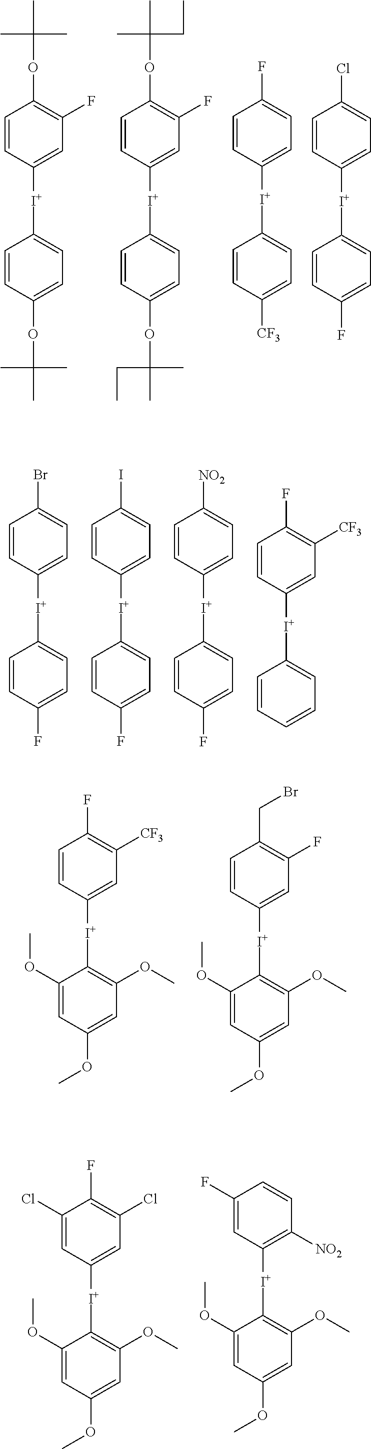

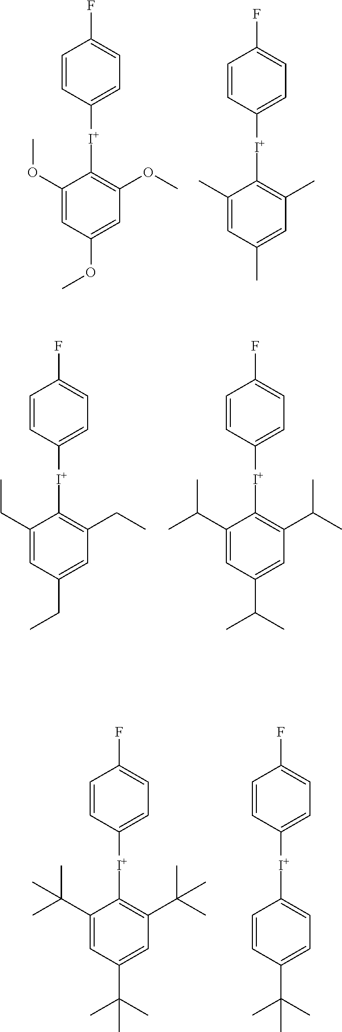

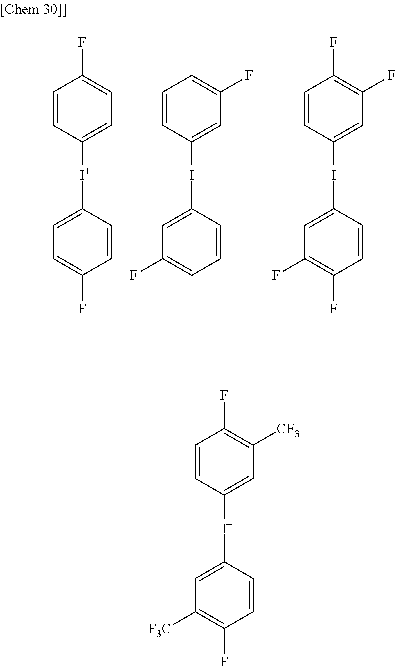 [SMILES: Fc1ccc([I+]c2ccc(F)cc2)cc1 ; Fc1cccc([I+]c2cccc(F)c2)c1 ; Fc1ccc([I+]c2ccc(F)c(F)c2)cc1F ; Fc1ccc([I+]c2ccc(F)c(C(F)(F)F)c2)cc1C(F)(F)F]

When the resin contains the structural unit (VII), the lower limit of the content of the structural unit (VII) (when a plurality of types of the structural unit (VII) are contained, the total content thereof is taken) is preferably 3 mol %, more preferably 5 mol %, and still more preferably 8 mol % based on all structural units constituting the resin. The upper limit of the content is preferably 30 mol %, more preferably 25 mol %, and still more preferably 20 mol %. When the content of the structural unit (VII) is adjusted to within the above range, a function of the resin as an acid generator can be sufficiently exhibited.

The monomer that affords the structural unit (VII) can be synthesized, for example, by the same method as that for the sulfonium salt having a polymerizable anion described in Japanese Patent No. 5201363.

### (Other Structural Units)

The resin may contain a structural unit derived from styrene in addition to the structural units (I) to (VII). A part or all of the hydrogen atoms of the benzene ring in styrene may be replaced by a halogen atom. The halogen atom is preferably an iodine atom.

When the resin contains a structural unit derived from styrene, the lower limit of the content of the structural unit derived from styrene is preferably 1 mol %, more preferably 2 mol %, and still more preferably 3 mol % based on all structural units constituting the resin. The upper limit of the content is preferably 10 mol % or less, more preferably 8 mol % or less, and still more preferably 6 mol % or less.

### (Method for Synthesizing Resin)

The resin as a base resin can be synthesized by, for example, subjecting monomers that will afford structural units to a polymerization reaction in an appropriate solvent using a publicly known radical polymerization initiator or the like.

The molecular weight of the resin as a base resin is not particularly limited, and the weight average molecular weight (Mw) as determined by Gel Permeation Chromatography (GPC) relative to standard polystyrene is preferably 1,000 or more, more preferably 2,000 or more, still more preferably 3,000 or more, and particularly preferably 4,000 or more. The Mw of the high fluorine-containing resin is preferably 50,000 or less, more preferably 30,000 or less, still more preferably 15,000 or less, and particularly preferably 12,000 or less. When the Mw of the resin is within the above range, a resulting resist film is good in heat resistance and developability.

The ratio (Mw/Mn) of Mw to the number average molecular weight (Mn) of the resin as a base resin as determined by GPC relative to standard polystyrene is usually 1 or more and 5 or less, preferably 1 or more and 3 or less, and more preferably 1 or more and 2 or less.

The method for measuring Mw and Mn of the resin in this specification is based on the description in Examples.

The content of the resin is preferably 70% by mass or more, more preferably 75% by mass or more, and still more preferably 80% by mass based on the total solid content of the radiation-sensitive resin composition.

### <Other Resins>

The radiation-sensitive resin composition of the present embodiment may contain a resin having a higher content by mass of fluorine atoms than the base resin as described above (hereinafter also referred as “high fluorine-containing resin”) as other resin. When the radiation-sensitive resin composition contains the high fluorine-containing resin, the high fluorine-containing resin can be localized in the surface layer of a resist film compared to the base resin, and as a result, the state of the surface of the resist film and the component distribution in the resist film can be controlled to a desired state.

The high fluorine-containing resin preferably has a structural unit represented by formula (6) (hereinafter, also referred to as “structural unit (VIII)”). The high fluorine-containing resin may have any of the structural units (I), (II), (IV), and (V) in the base resin, as necessary.

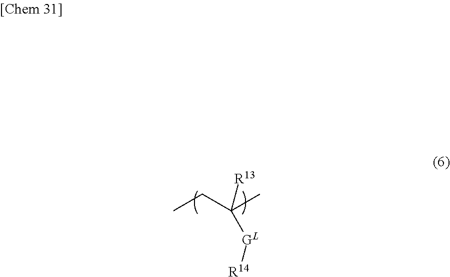

In the above formula (6), R¹³ is a hydrogen atom, a methyl group, or a trifluoromethyl group. G is a single bond, an oxygen atom, a sulfur atom, —COO—, —SO₂ONH—, —CONH—, or —OCONH—. R¹⁴ is a monovalent fluorinated chain hydrocarbon group having 1 to 20 carbon atoms or a monovalent fluorinated alicyclic hydrocarbon group having 3 to 20 carbon atoms.

As the R¹³, a hydrogen atom and a methyl group are preferable from the viewpoint of the copolymerizability of a monomer that affords the structural unit (VIII), and a methyl group is more preferable.

As the GL, a single bond and —COO— are preferable from the viewpoint of the copolymerizability of a monomer that affords the structural unit (VIII), and —COO— is more preferable.

Example of the monovalent fluorinated chain hydrocarbon group having a carbon number of 1 to 20 represented by R¹⁴ as described above includes a group in which a part of or all of hydrogen atoms in the straight or branched chain alkyl group having a carbon number of 1 to 20 is/are substituted with a fluorine atom.

Example of the monovalent fluorinated alicyclic hydrocarbon group having a carbon number of 3 to 20 represented by R¹⁴ as described above includes a group in which a part of or all of hydrogen atoms in the monocyclic or polycyclic hydrocarbon group having a carbon number of 3 to 20 is/are substituted with a fluorine atom.

As the R¹⁴, fluorinated chain hydrocarbon groups are preferable, fluorinated alkyl groups are more preferable, and a 2,2,2-trifluoroethyl group, a 1,1,1,3,3,3-hexafluoropropyl group, a 5,5,5-trifluoro-1,1-diethylpentyl group, and a 1,1,1,2,2,3,3-heptafluoro-6 methyl-4 octyl group are still more preferable.

When the high fluorine-containing resin contains the structural unit (VIII), the lower limit of the content of the structural unit (VIII) is preferably 50 mol %, more preferably 60 mol %, still more preferably 70 mol %, and particularly preferably 80 mol % based on all structural units constituting the high fluorine-containing resin. The upper limit of the content is preferably 100 mol %, more preferably 98 mol %, and still more preferably 95 mol %. When the content of the structural unit (VIII) is adjusted to within the above range, the content by mass of fluorine atoms in the high fluorine-containing resin can more appropriately be adjusted and the localization in the surface layer of a resist film can be further promoted.

The high fluorine-containing resin may have a fluorine atom-containing structural unit represented by the following formula (f-1) (hereinafter also referred to as structural unit (IX) in addition to the structural unit (VIII). When the high fluorine-containing resin has the structural unit (IX), solubility in an alkaline developer is improved, and the occurrence of development defects can be suppressed.

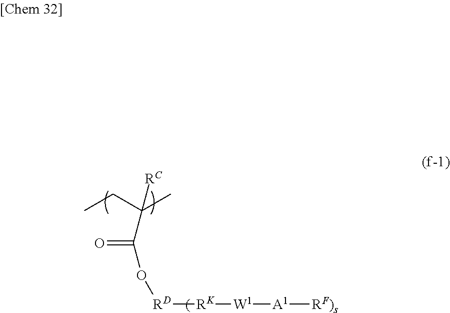

The structural unit (IX) is classified into two groups: a unit having an alkali soluble group (x); and a unit having a group (y) in which the solubility into the alkaline developing solution is increased by the dissociation by alkali (hereinafter, simply referred as an “alkali-dissociable group”). In both cases of (x) and (y), R^{c} in the above formula (f-1) is a hydrogen atom, a fluorine atom, a methyl group, or a trifluoromethyl group; R^{D} is a single bond, a hydrocarbon group having a carbon number of 1 to 20 with the valency of (s+1), a structure in which an oxygen atom, a sulfur atom, —NR^{dd}—, a carbonyl group, —COO— or —CONH— is connected to the terminal on R^{E} side of the hydrocarbon group, or a structure in which a part of hydrogen atoms in the hydrocarbon group is substituted with an organic group having a hetero atom; R^{dd} is a hydrogen atom, or a monovalent hydrocarbon group having a carbon number of 1 to 10; and s is an integer of 1 to 3.

When the structural unit (IX) has the alkali soluble group (x), R^{F} is a hydrogen atom; A¹ is an oxygen atom, —COO—* or —SO₂O—*; * refers to a bond to R^{F}; W¹ is a single bond, a hydrocarbon group having a carbon number of 1 to 20, or a divalent fluorinated hydrocarbon group. When A¹ is an oxygen atom, W¹ is a fluorinated hydrocarbon group having a fluorine atom or a fluoroalkyl group on the carbon atom connecting to A¹. R^{K} is a single bond, or a divalent organic group having a carbon number of 1 to 20. When s is 2 or 3, a plurality of R^{K}, W¹, A¹ and R^{F} may be each identical or different. The affinity of the high fluorine-content resin into the alkaline developing solution can be improved by including the structural unit (IX) having the alkali soluble group (x), and thereby prevent from generating the development defect. As the structural unit (IX) having the alkali soluble group (x), particularly preferred is a structural unit in which A¹ is an oxygen atom and W¹ is a 1,1,1,3,3,3-hexafluoro-2,2-methanediyl group.

When the structural unit (IX) has the alkali-dissociable group (y), R^{F} is a monovalent organic group having carbon number of 1 to 30; A¹ is an oxygen atom, —NR^{aa}—, —COO—*, or —SO₂O—*; R^{aa} is a hydrogen atom, or a monovalent hydrocarbon group having a carbon number of 1 to 10; * refers to a bond to R^{F}; W¹ is a single bond, or a divalent fluorinated hydrocarbon group having a carbon number of 1 to 20; R^{K} is a single bond, or a divalent organic group having a carbon number of 1 to 20. When A¹ is —COO—* or —SO₂O—*, W¹ or R^{F} has a fluorine atom on the carbon atom connecting to A¹ or on the carbon atom adjacent to the carbon atom. When A¹ is an oxygen atom, W¹ and R^{K}are a single bond; R^{D} is a structure in which a carbonyl group is connected at the terminal on R^{K} side of the hydrocarbon group having a carbon number of 1 to 20; and R^{F} is an organic group having a fluorine atom. When s is 2 or 3, a plurality of R^{K}, W¹, A¹ and R^{F} may be each identical or different. The surface of the resist film is changed from hydrophobic to hydrophilic in the alkaline developing step by including the structural unit (IX) having the alkali-dissociable group (y). As a result, the affinity of the high fluorine-content resin into the alkaline developing solution can be significantly improved, and thereby prevent from generating the development defect more efficiently. As the structural unit (IX) having the alkali-dissociable group (y), particularly preferred is a structural unit in which A¹ is —COO—*, and R^{F} or W¹, or both is/are a fluorine atom.

In terms of the copolymerizability of monomers resulting in the structural unit (IX), R^{C} is preferably a hydrogen atom or a methyl group, and more preferably a methyl group.

When R^{K} is a divalent organic group, R^{K} is preferably a group having a lactone structure, more preferably a group having a polycyclic lactone structure, and further preferably a group having a norbornane lactone structure.

When the high fluorine-content resin has the structural unit (IX), the lower limit of the content of the structural unit (IX) is preferably 10 mol %, more preferably 20 mol %, even more preferably 30 mol %, and particularly preferably 35 mol % with respect to the total amount of all the structural units constituting the high fluorine-content resin. The upper limit of the content is preferably 90 mol %, more preferably 75 mol %, even more preferably 60 mol %. When the content of the structural unit (IX) is set to fall within the above range, water repellency of a resist film during immersion exposure can further be improved.

The Mw of the high fluorine-containing resin is preferably 1,000 or more, more preferably 2,000 or more, still more preferably 3,000 or more, and particularly preferably 5,000 or more. The Mw of the high fluorine-containing resin is preferably 50,000 or less, more preferably 30,000 or less, still more preferably 20,000 or less, and particularly preferably 15,000 or less.

The Mw/Mn of the high fluorine-containing resin is usually 1 or more, and more preferably 1.1 or more. The Mw/Mn of the high fluorine-containing resin is usually 5 or less, preferably 3 or less, more preferably 2 or less, and still more preferably 1.9 or less.

The content of the high fluorine-containing resin is preferably 0.1 parts by mass or more, more preferably 0.5 parts by mass or more, still more preferably 1 part by mass or more, and particularly preferably 1.5 parts by mass or more based on 100 parts by mass of the base resin. The content is preferably 12 parts by mass or less, more preferably 10 parts by mass or less, still more preferably 8 parts by mass or less, and particularly preferably 5 parts by mass or less.

When the content of the high fluorine-containing resin is adjusted to within the above range, the high fluorine-containing resin can be more effectively localized in the surface layer of a resist film, and as a result, the elusion of a top portion of a pattern is controlled during development and the rectangularity of a pattern can be enhanced. The radiation-sensitive resin composition may contain one or two or more high fluorine-containing resins.

### (Method for Synthesizing High Fluorine-Containing Resin)

The high fluorine-containing resin can be synthesized by the same method as the method for synthesizing a base resin described above.

### <Acid Diffusion Controlling Agent>

The acid diffusion controlling agent is represented by formula (a).

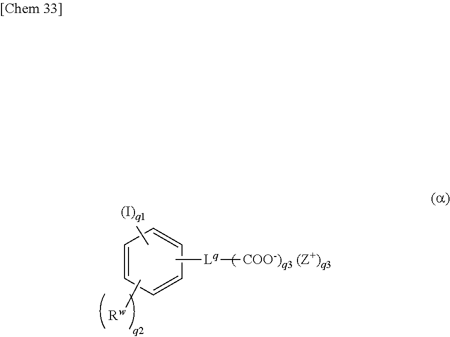

In formula (α), R^{w} is a monovalent organic group having 1 to 20 carbon atoms, a hydroxy group, or an amino group. when there are a plurality of R^{w}'s, the plurality of R^{w}'s are the same or different from each other; La is a divalent linking group; when there are a plurality of L^{q}'s, the plurality of L^{q}'s are the same or different from each other; Z⁺ is a monovalent radiation-sensitive onium cation; q₁ is an integer of 1 to 4; q₂ is an integer of 0 to 3; q₃ is an integer of 1 to 3; and The upper limit of q₁+q₂+q₃ is 6. The organic group refers to a group containing at least one carbon atom.

Examples of the monovalent organic group having 1 to 20 carbon atoms represented by R^{w} include a monovalent hydrocarbon group having 1 to 20 carbon atoms, a group obtained by introducing a divalent heteroatom-containing group between two carbon atoms or at the bonding hand-side end of the hydrocarbon group, a group obtained by substituting a part or all of the hydrogen atoms of the group or the hydrocarbon group with a monovalent heteroatom-containing group, and combinations of two or more of the foregoing groups.

Examples of the monovalent hydrocarbon group having 1 to 20 carbon atoms include:
chain hydrocarbon groups including:
alkyl groups such as a methyl group, an ethyl group, a propyl group, and a butyl group,
alkenyl groups such as an ethenyl group, a propenyl group, and a butenyl group, and
alkynyl groups such as an ethynyl group, a propynyl group, and a butynyl group;
alicyclic hydrocarbon groups including:
cycloalkyl groups such as a cyclopropyl group, a cyclopentyl group, a cyclohexyl group, a cyclooctyl group, a norbornyl group, and an adamantyl group, and
cycloalkenyl groups such as a cyclopropenyl group, a cyclopentenyl group, a cyclohexenyl group, and a norbornenyl group; and
aromatic hydrocarbon groups including:
aryl groups such as a phenyl group, a tolyl group, a xylyl group, a naphthyl group, and an anthryl group, and
aralkyl groups such as a benzyl group, a phenethyl group, and a naphthylmethyl group.

Examples of the divalent heteroatom-containing group include —O—, —CO—, —CO—O—, —S—, —CS—, —SO₂—, —NR′—, and a group obtained by combining two or more of them. R′ is a hydrogen atom or a monovalent hydrocarbon group.

Examples of the monovalent heteroatom-containing group include a halogen atom such as a fluorine atom, a chlorine atom, a bromine atom, or an iodine atom, a hydroxy group, a carboxy group, a cyano group, an amino group, and a sulfanyl group (—SH).

Examples of the divalent linking group represented by L^{q} include a group obtained by further removing one hydrogen atom from a monovalent organic group having 1 to 20 carbon atoms represented by R^{w}.

In formula (α), q₁ is preferably an integer of 1 to 3, and more preferably 2 or 3. q₂ is preferably 0 or 1. q₃ is preferably 1 or 2, and more preferably 1.

The anion moiety of the acid diffusion controlling agent represented by formula (a) is not limited, and examples thereof include those shown below.

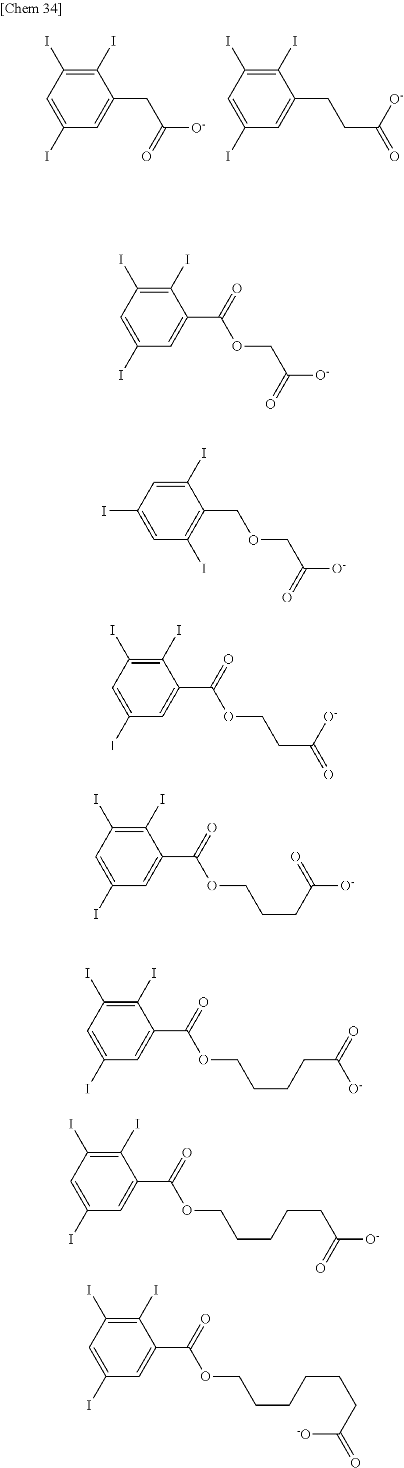

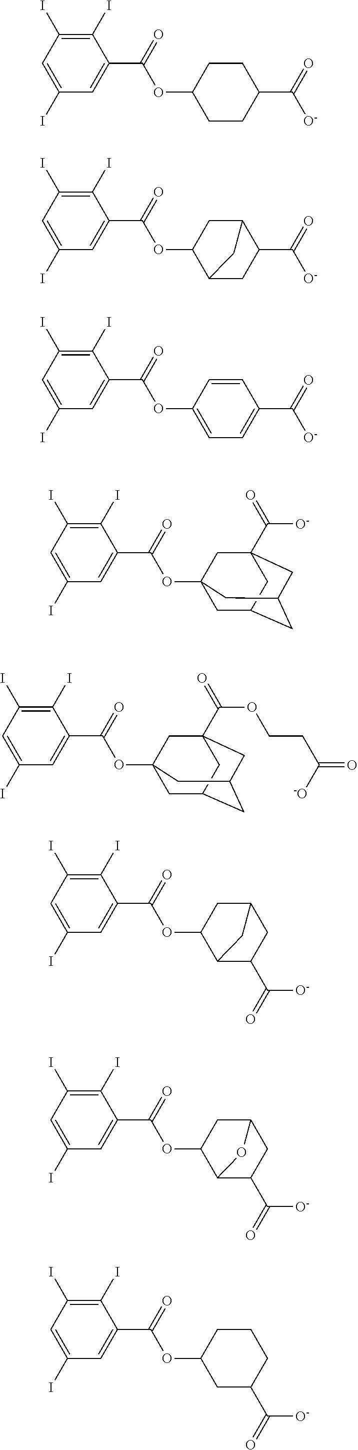

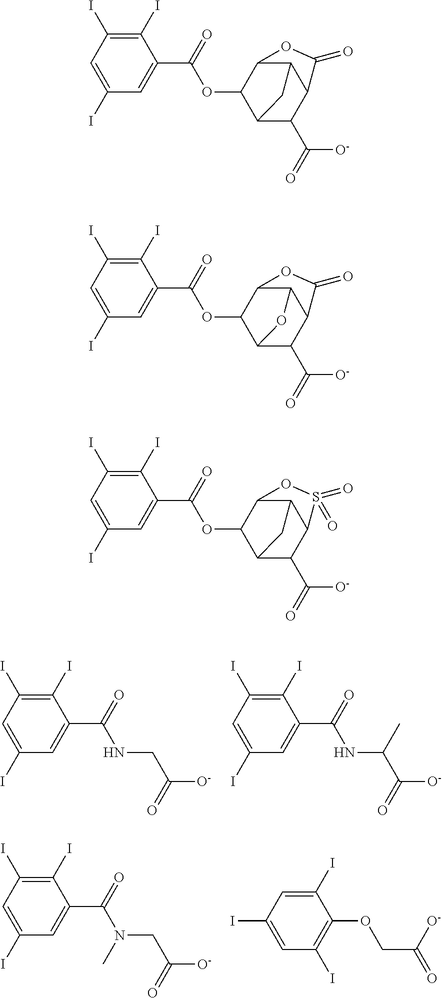

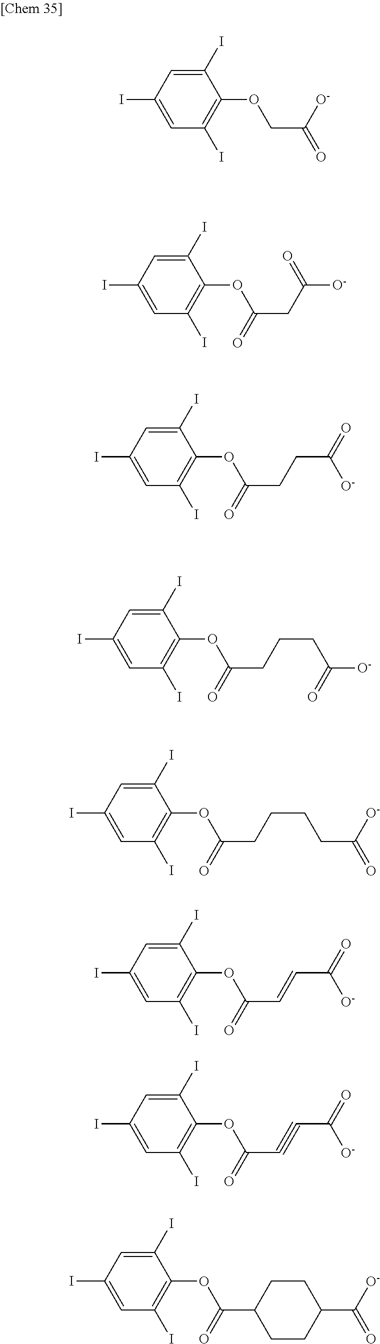

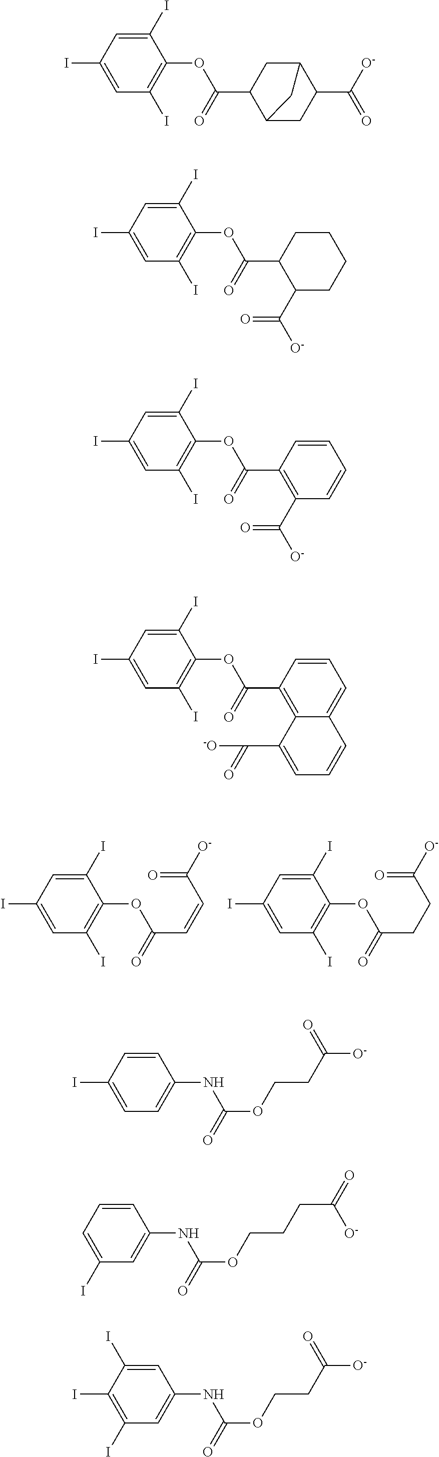

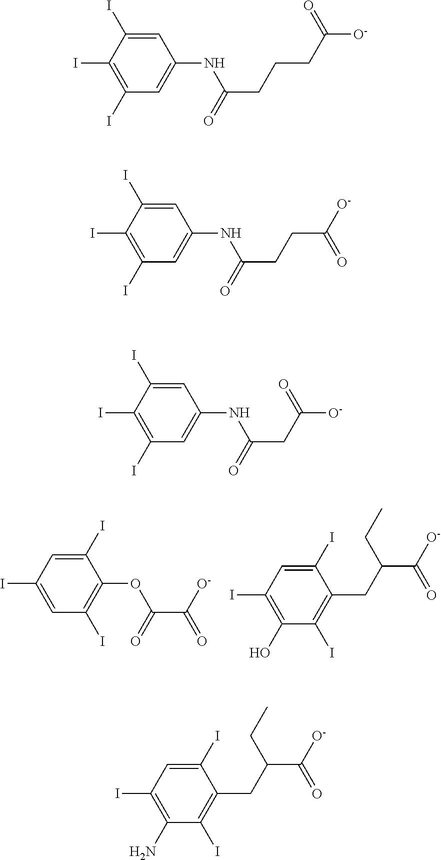 [SMILES: O=C([O-])CCCC(=O)Nc1cc(I)c(I)c(I)c1 ; O=C([O-])CCC(=O)Nc1cc(I)c(I)c(I)c1 ; O=C([O-])CC(=O)Nc1cc(I)c(I)c(I)c1 ; O=C([O-])C(=O)Oc1c(I)cc(I)cc1I ; CCC(Cc1c(I)cc(I)c(O)c1I)C(=O)[O-] ; CCC(Cc1c(I)cc(I)c(N)c1I)C(=O)[O-]]

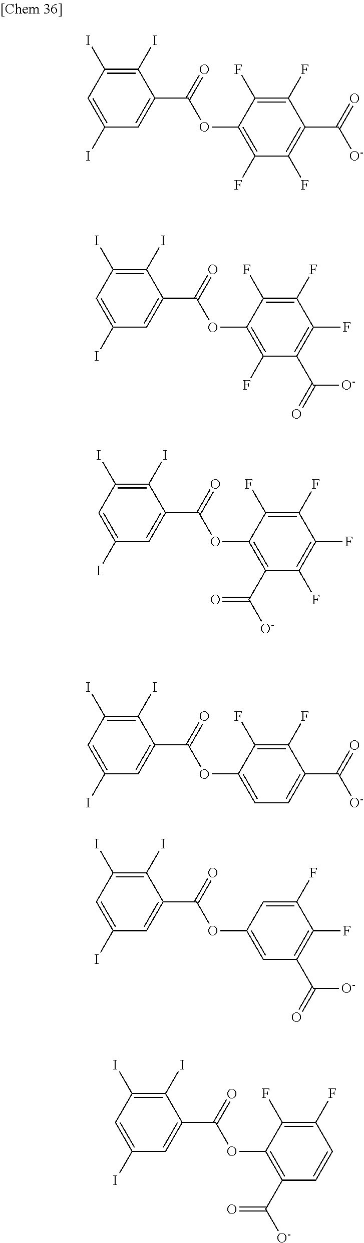 [SMILES: O=C(Oc1c(F)c(F)c(C(=O)[O-])c(F)c1F)c1cc(I)cc(I)c1I ; O=C(Oc1c(F)c(F)c(F)c(C(=O)[O-])c1F)c1cc(I)cc(I)c1I ; O=C(Oc1c(F)c(F)c(F)c(F)c1C(=O)[O-])c1cc(I)cc(I)c1I ; O=C([O-])c1ccc(OC(=O)c2cc(I)cc(I)c2I)c(F)c1F ; O=C([O-])c1cc(OC(=O)c2cc(I)cc(I)c2I)cc(F)c1F ; O=C(Oc1c(C(=O)[O-])ccc(F)c1F)c1cc(I)cc(I)c1I]

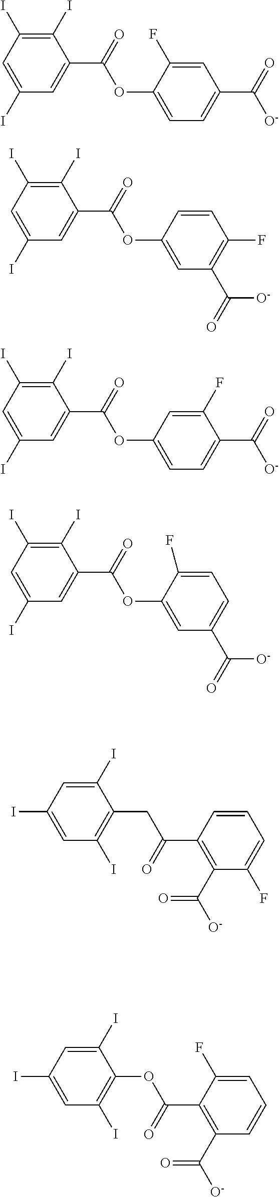 [SMILES: O=C([O-])c1ccc(OC(=O)c2cc(I)cc(I)c2I)c(F)c1 ; O=C([O-])c1cc(OC(=O)c2cc(I)cc(I)c2I)ccc1F ; O=C([O-])c1ccc(OC(=O)c2cc(I)cc(I)c2I)cc1F ; O=C([O-])c1ccc(F)c(OC(=O)c2cc(I)cc(I)c2I)c1 ; O=C(Cc1c(I)cc(I)cc1I)c1cccc(F)c1C(=O)[O-] ; O=C([O-])c1cccc(F)c1C(=O)Oc1c(I)cc(I)cc1I]

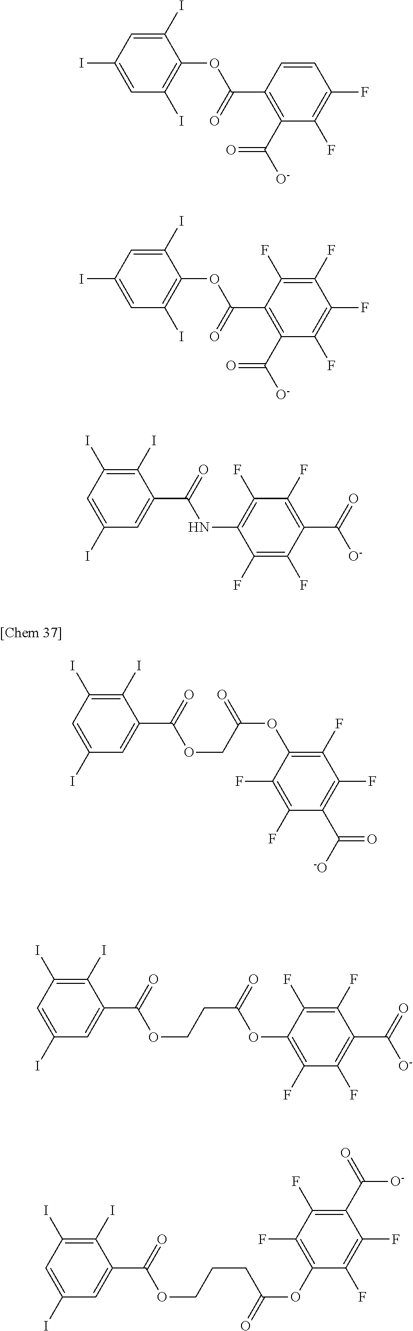

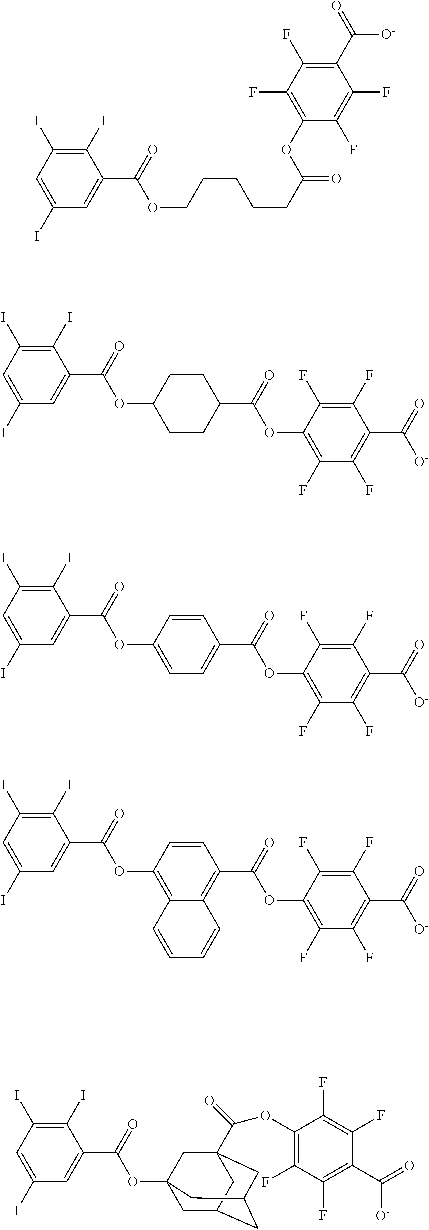 [SMILES: O=C(CCCCCOC(=O)c1cc(I)cc(I)c1I)Oc1c(F)c(F)c(C(=O)[O-])c(F)c1F ; O=C(OC1CCC(C(=O)Oc2c(F)c(F)c(C(=O)[O-])c(F)c2F)CC1)c1cc(I)cc(I)c1I ; O=C(Oc1c(F)c(F)c(C(=O)[O-])c(F)c1F)c1ccc(OC(=O)c2cc(I)cc(I)c2I)cc1 ; O=C(Oc1ccc(C(=O)Oc2c(F)c(F)c(C(=O)[O-])c(F)c2F)c2ccccc12)c1cc(I)cc(I)c1I ; O=C(OC12CC3CC(C1)CC(C(=O)Oc1c(F)c(F)c(C(=O)[O-])c(F)c1F)(C3)C2)c1cc(I)cc(I)c1I]

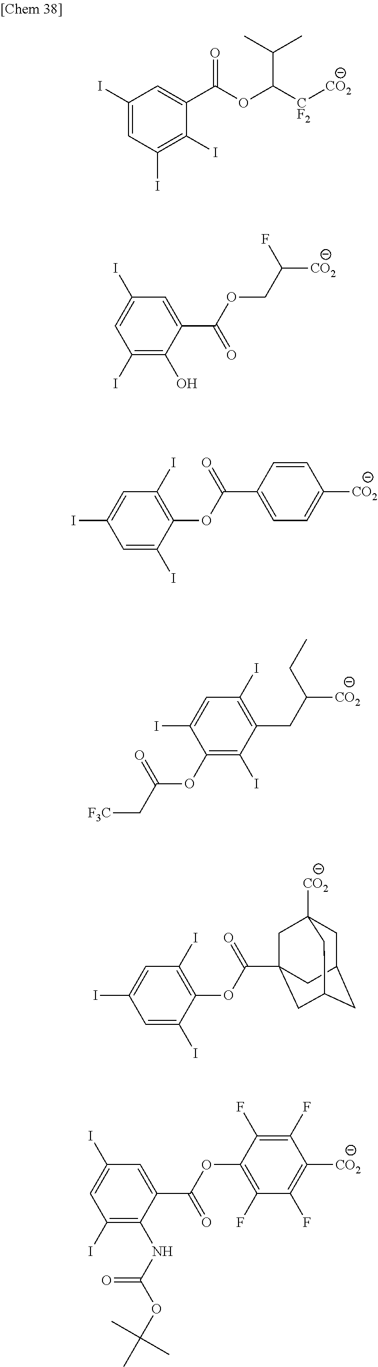

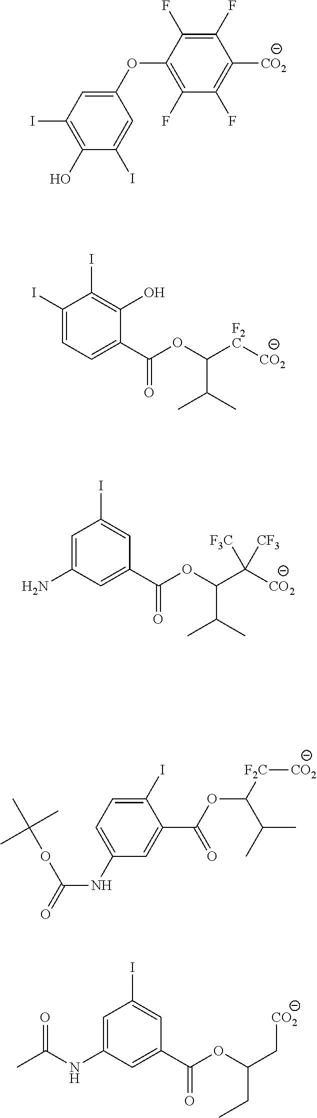

As the monovalent radiation-sensitive onium cation represented by Z⁺, the structures represented as the onium cation moieties represented by the above (Q-1) and (Q-2) in the structural unit (VII) which may be contained in the resin may be suitably employed. Z⁺ preferably contains an aromatic ring structure having a fluorine atom.

The acid diffusion controlling agent represented by formula (a) can be synthesized also by a known method, particularly by a salt exchange reaction.

The acid diffusion controlling agent represented by formula (a) may be used alone or in combination of two or more thereof. The lower limit of the content of the acid diffusion controlling agent is preferably 0.5 parts by mass or more, more preferably 1 part by mass or more, and still more preferably 1.5 parts by mass or more based on 100 parts by mass of the base resin. The content is preferably 12 parts by mass or less, more preferably 8 parts by mass or less, and still more preferably 5 parts by mass or less based on 100 parts by mass of the resin. As a result, superior sensitivity, CDU performance, and residual film ratio can be exhibited when forming a resist pattern. In the radiation-sensitive resin composition of the present embodiment, another acid diffusion controlling agent may be used in combination with the acid diffusion controlling agent represented by formula (a). As the other acid diffusion controlling agent, a known substance can be used.

### <Radiation-Sensitive Acid Generator>

The radiation-sensitive resin composition preferably further contains a radiation-sensitive acid generator that generates an acid having a pKa lower than that of the acid generated from the acid diffusion controlling agent by irradiation with radiation (exposure). When the radiation-sensitive resin composition contains the radiation-sensitive acid generator, the acid generated by exposure dissociates the acid-dissociable group of the resin to generate a carboxy group or the like. As a result, the polarity of the resin in the exposed area increases, so that in the case of development with an aqueous alkaline solution, the resin in the exposed area is soluble in the developer, whereas in the case of development with an organic solvent, the resin in the exposed area is hardly soluble in the developer.

The radiation-sensitive acid generator preferably contains an organic acid anion moiety and an onium cation moiety. The organic acid anion moiety preferably has at least one type of anion selected from the group consisting of a sulfonate anion and a sulfonimide anion. Examples of the acid generated by exposure include a sulfonic acid and a sulfonimide corresponding to the organic acid anion moiety. The organic acid anion moiety preferably contains an iodine-substituted aromatic ring structure.

In particular, a compound in which one or more fluorine atoms or fluorinated hydrocarbon groups are bonded to a carbon atom adjacent to a sulfonate anion can be suitably employed as a radiation-sensitive acid generator that affords a sulfonic acid by exposure.

The radiation-sensitive acid generator is preferably represented by the following formula (A-1) or (A-2).

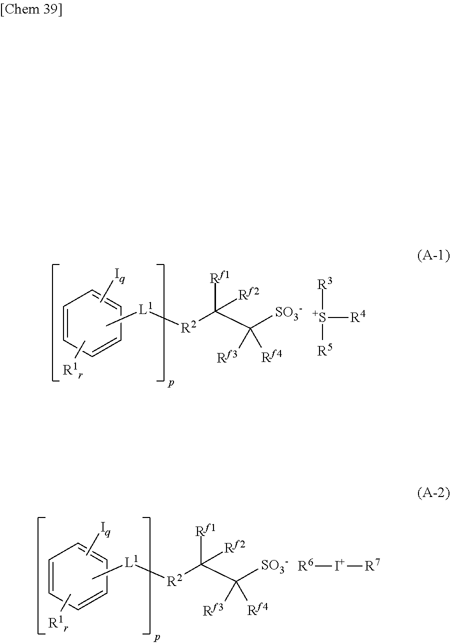

In formulas (A-1) and (A-2), L1 is a single bond, an ether linkage, an ester linkage, or an alkylene group having 1 to 6 carbon atoms and optionally containing an ether linkage or an ester linkage in the chain. The alkylene group may be linear, branched, or cyclic.

R¹ is a hydroxy group, a carboxy group, a fluorine atom, a chlorine atom, a bromine atom, or an amino group; or is an alkyl group having 1 to 20 carbon atoms, an alkoxy group having 1 to 20 carbon atoms, an alkoxycarbonyl group having 2 to 10 carbon atoms, an acyloxy group having 2 to 20 carbon atoms, or an alkylsulfonyloxy group having 1 to 20 carbon atoms, each optionally containing a fluorine atom, a chlorine atom, a bromine atom, a hydroxy group, an amino group, or an alkoxy group having 1 to 10 carbon atoms; or is —NR^{B}—C(═O)—R⁹ or —NR^{B}—C(═O)—O—R⁹, wherein R⁸ is a hydrogen atom or an alkyl group having 1 to 6 carbon atoms and optionally containing a halogen atom, a hydroxy group, an alkoxy group having 1 to 6 carbon atoms, an acyl group having 2 to 6 carbon atoms, or an acyloxy group having 2 to 6 carbon atoms, and R⁹ is an alkyl group having 1 to 16 carbon atoms, an alkenyl group having 2 to 16 carbon atoms, or an aryl group having 6 to 12 carbon atoms and optionally contains a halogen atom, a hydroxy group, an alkoxy group having 1 to 6 carbon atoms, an acyl group having 2 to 6 carbon atoms, or an acyloxy group having 2 to 6 carbon atoms. The alkyl group, alkoxy group, alkoxycarbonyl group, acyloxy group, acyl group, and alkenyl group may be linear, branched, or cyclic.

Among them, R¹ is preferably a hydroxy group, —NR⁸—C(═O)—R⁹, a fluorine atom, a chlorine atom, a bromine atom, a methyl group, a methoxy group, or the like.

R² is a single bond or a divalent linking group having 1 to 20 carbon atoms when p is 1, and is a trivalent or tetravalent linking group having 1 to 20 carbon atoms when p is 2 or 3, and the linking groups may contain an oxygen atom, a sulfur atom, or a nitrogen atom.

Rf¹ to Rf⁴ are each independently a hydrogen atom, a fluorine atom, or a trifluoromethyl group, and at least one of Rf¹ to Rf⁴ is a fluorine atom or a trifluoromethyl group. Rf¹ and Rf² may be combined to form a carbonyl group. In particular, both Rf³ and Rf⁴ are preferably fluorine atoms.

R³, R⁴, R⁵, R⁶, and R⁷ are each independently a monovalent hydrocarbon group having 1 to 20 carbon atoms and optionally containing a heteroatom. When the onium cation moiety of the radiation-sensitive acid generator has fluorine, at least one of R³, R⁴, and R⁵ contains one or more fluorine atoms, and at least one of R⁶ and R⁷ contains one or more fluorine atoms. Any two of R³, R⁴, and R⁵ may be bonded to each other to form a ring together with the sulfur atom to which they are bonded. The monovalent hydrocarbon group may be linear, branched, or cyclic, and examples thereof include an alkyl group having 1 to 12 carbon atoms, an alkenyl group having 2 to 12 carbon atoms, an alkynyl group having 2 to 12 carbon atoms, an aryl group having 6 to 20 carbon atoms, and an aralkyl group having 7 to 12 carbon atoms. Some or all of the hydrogen atoms of these groups may be replaced by a hydroxy group, a carboxy group, a halogen atom, a cyano group, an amide group, a nitro group, a mercapto group, a sultone group, a sulfone group, or a sulfonium salt-containing group, and some of the carbon atoms of these groups may be replaced by an ether linkage, an ester linkage, a carbonyl group, a carbonate group, or a sulfonic acid ester linkage.

p is an integer satisfying 1≤p≤3. q and r are integers satisfying 0≤q≤5, 0≤r≤3, and 0≤q+r≤5. q is preferably an integer satisfying 1 q 3, and more preferably 2 or 3. r is preferably an integer satisfying 0≤r≤2.

Examples of the organic acid anion moiety of the radiation-sensitive acid generators represented by formulas (A-1) and (A-2) include, but are not limited to, those shown below. While all of those shown below are organic acid anion moieties having an iodine-substituted aromatic ring structure, organic acid anion moieties having no iodine-substituted aromatic ring structure that can be suitably employed include structures in which the iodine atoms in formulas shown below are replaced by an atom or group other than an iodine atom such as a hydrogen atom or other substituent.

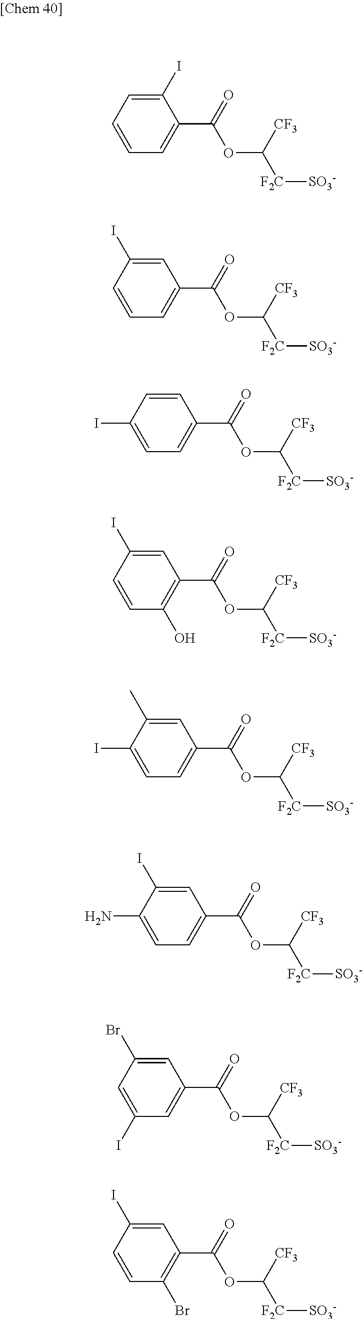

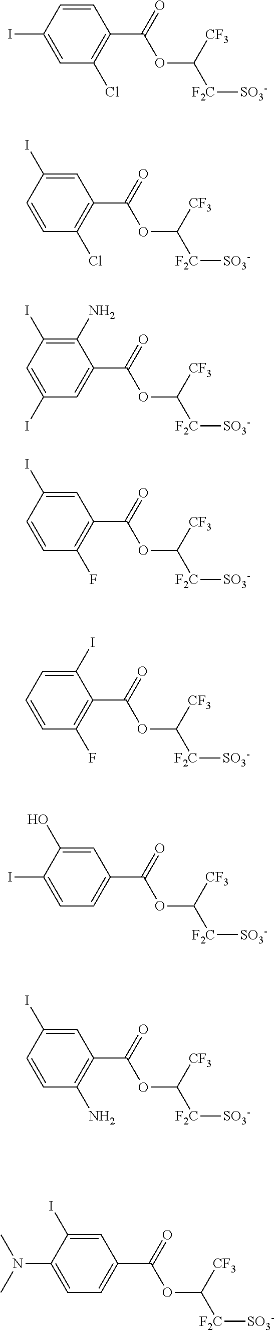

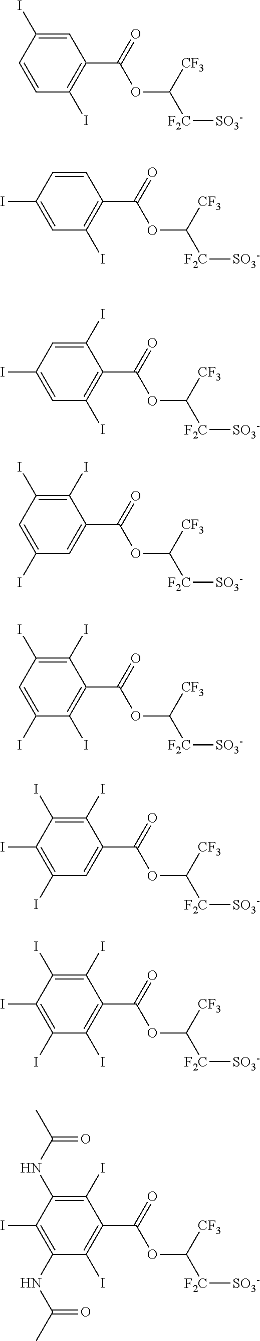

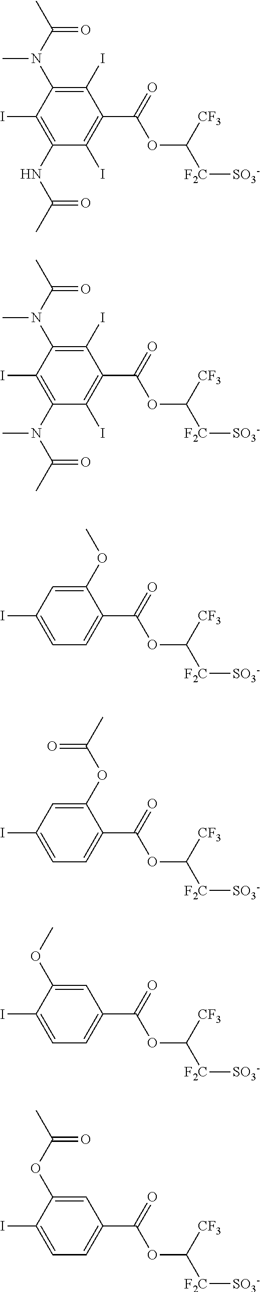

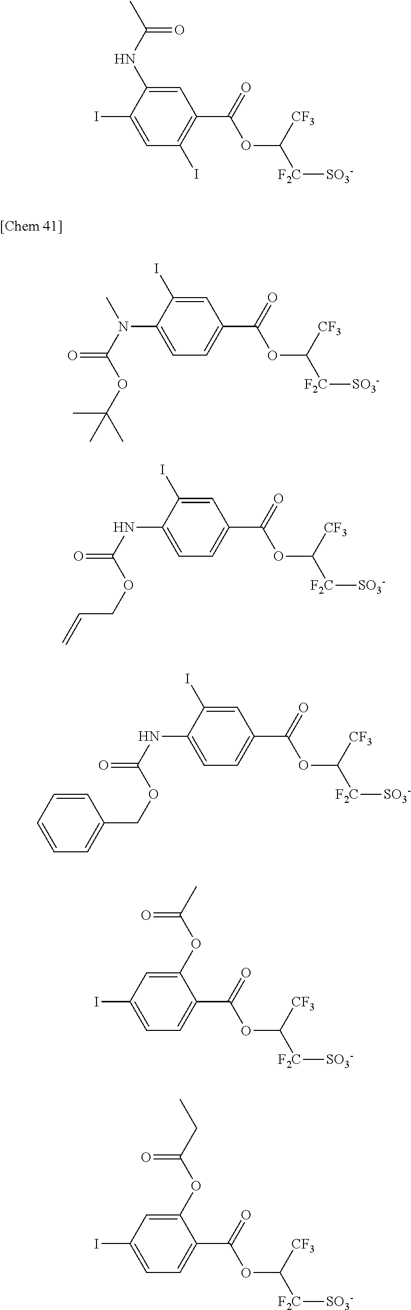

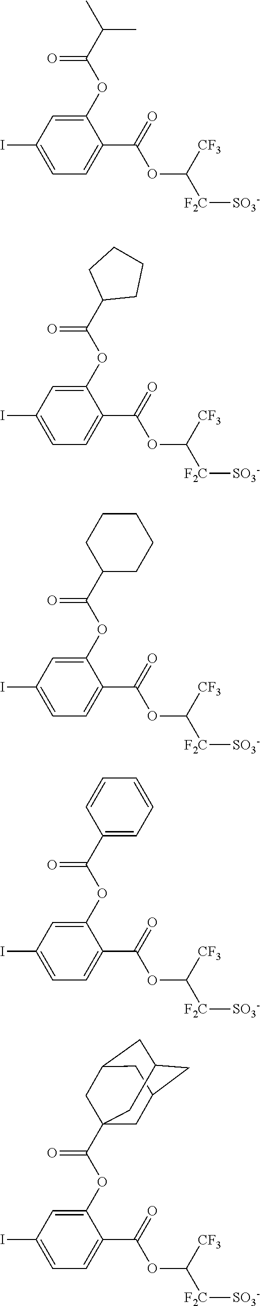

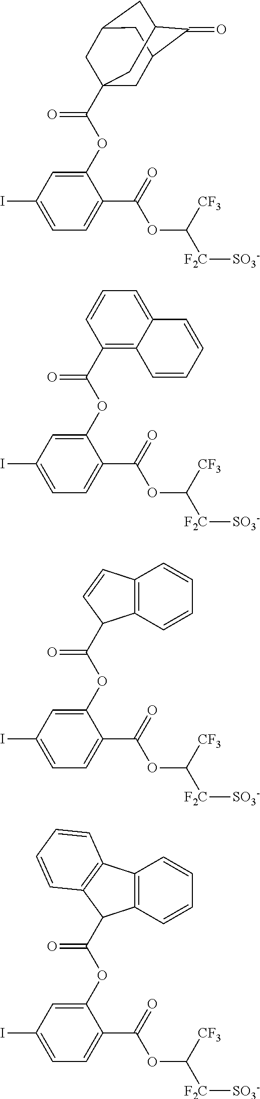

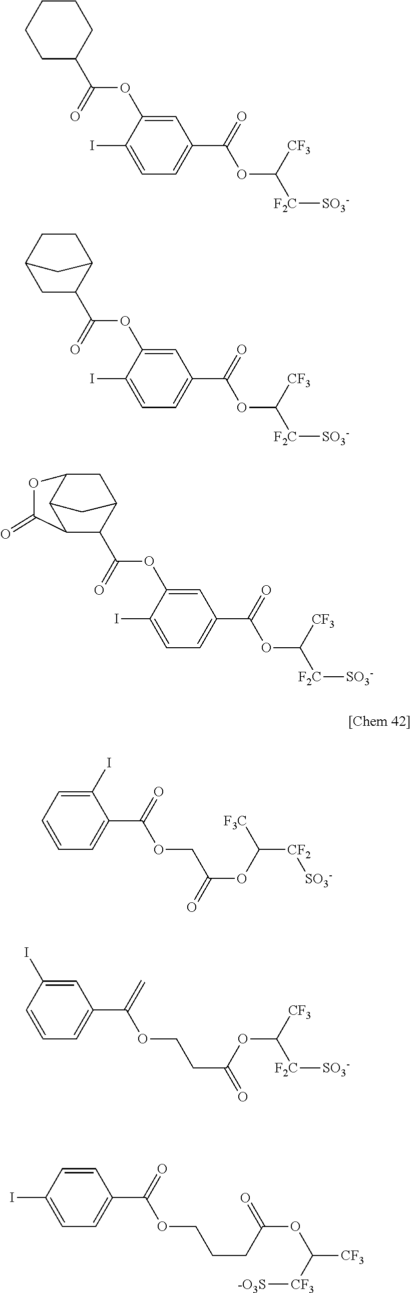

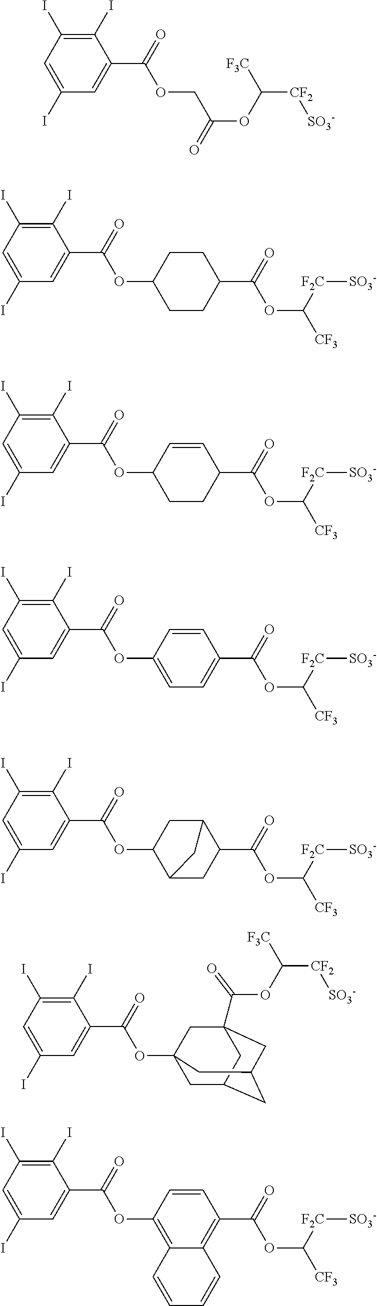

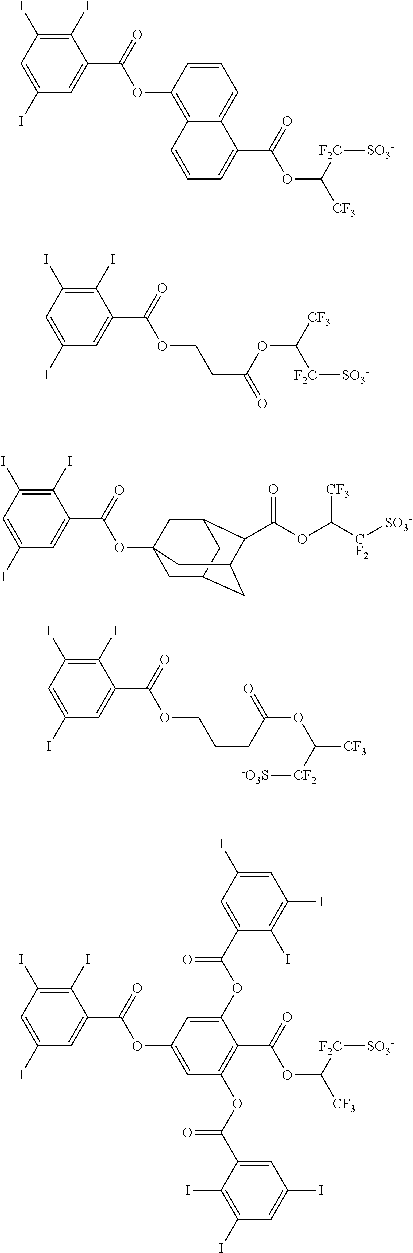

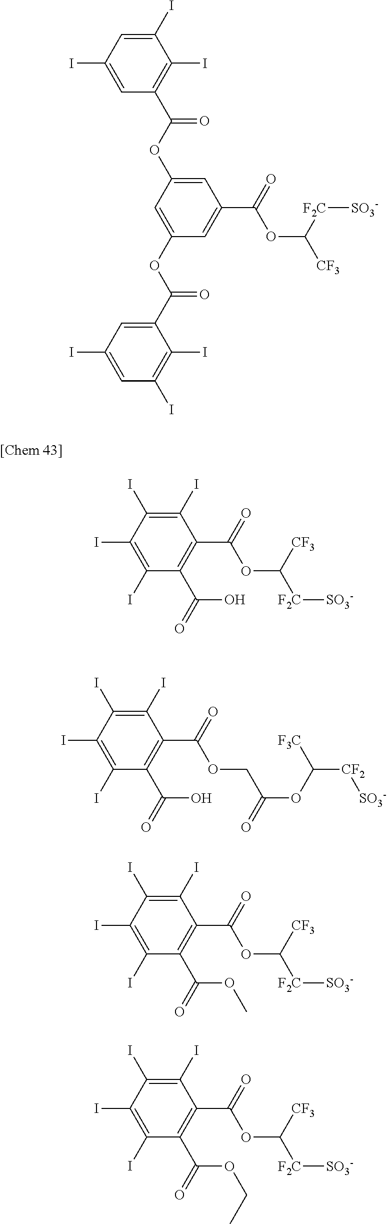

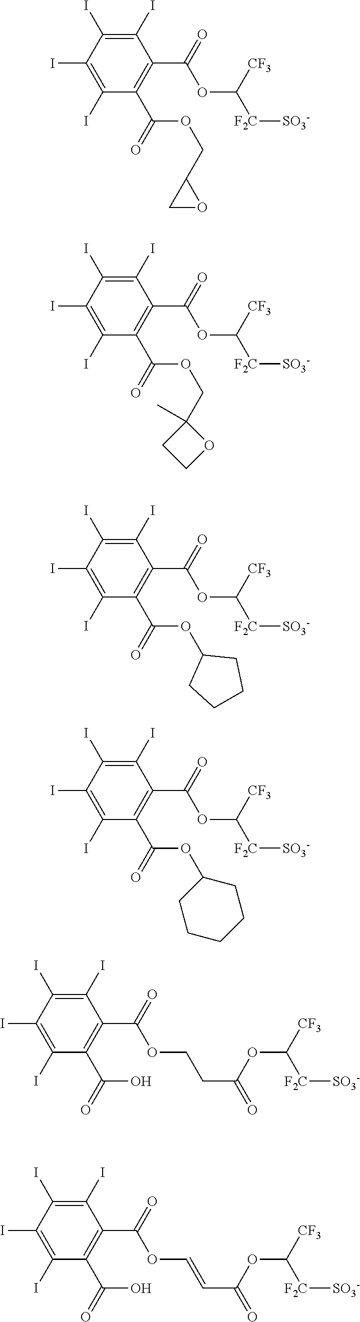

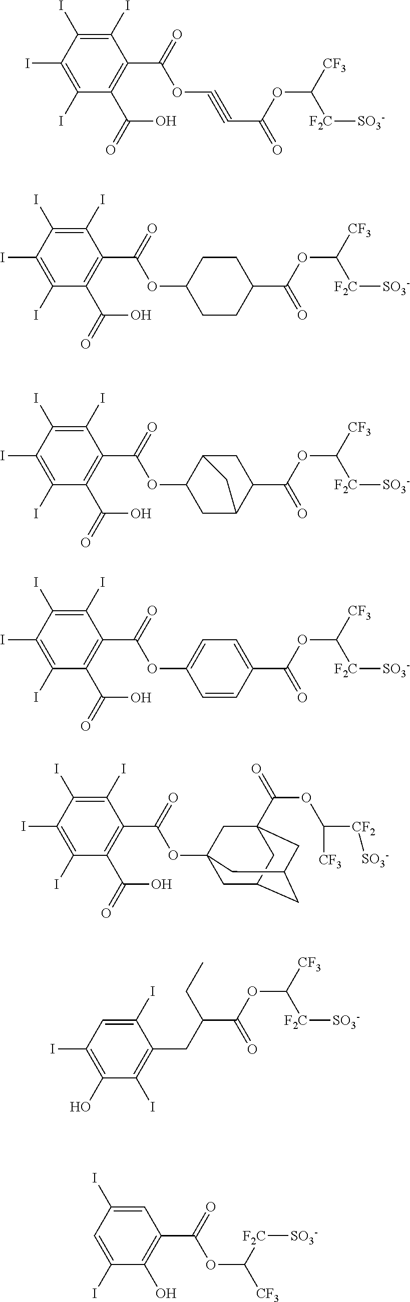

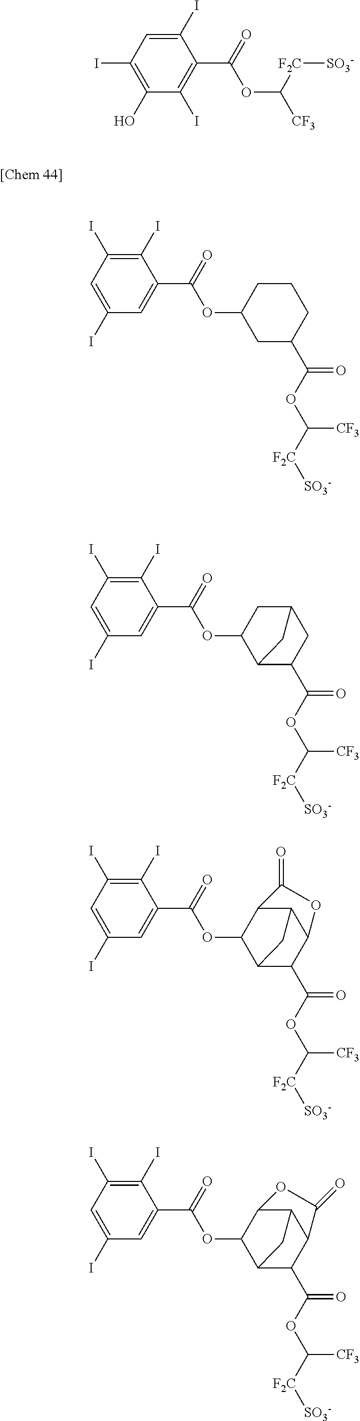

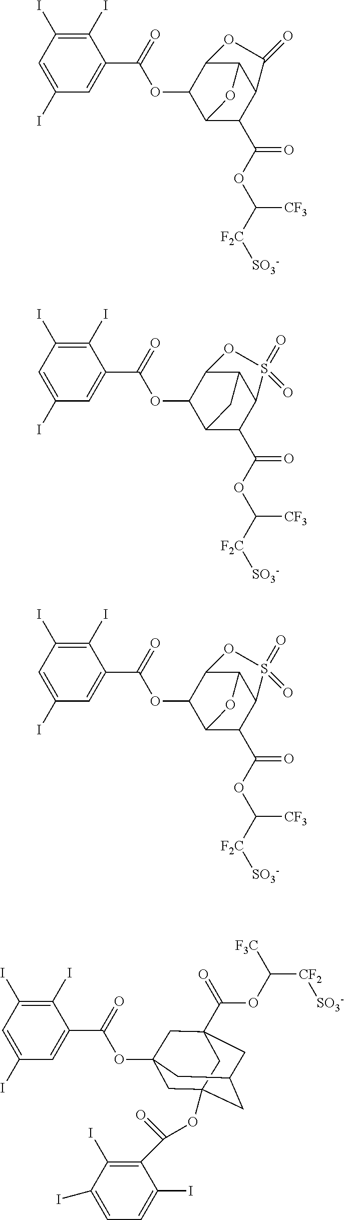

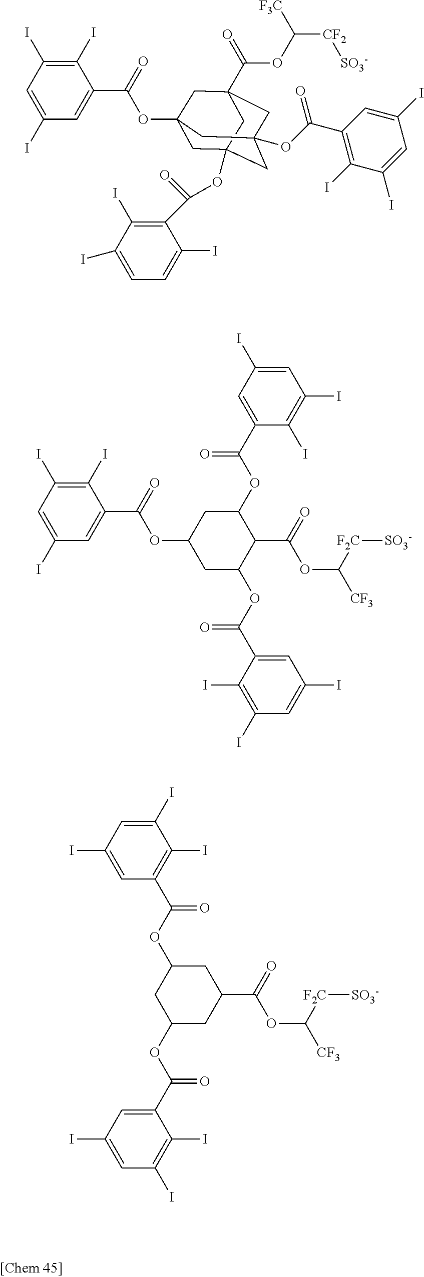

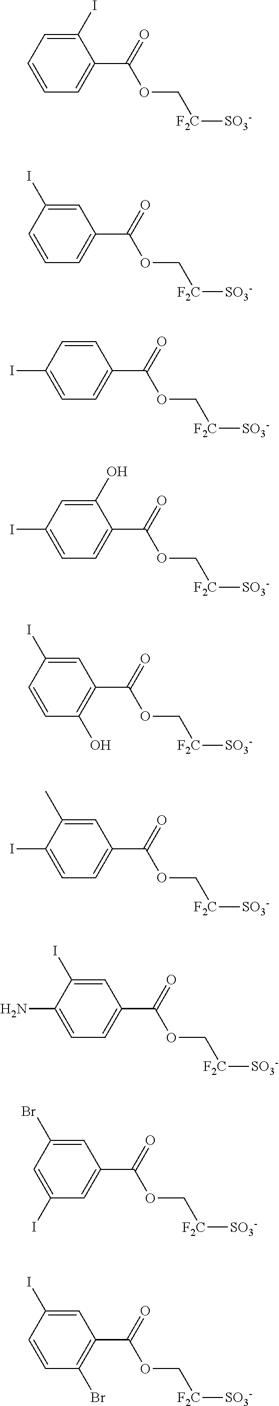

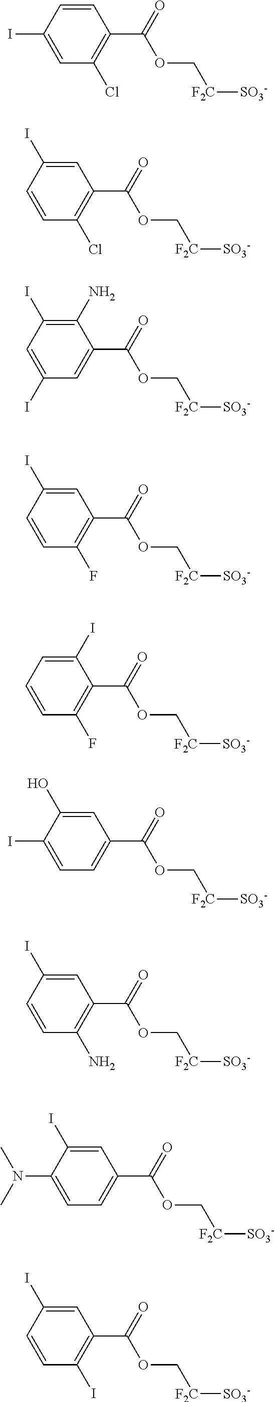

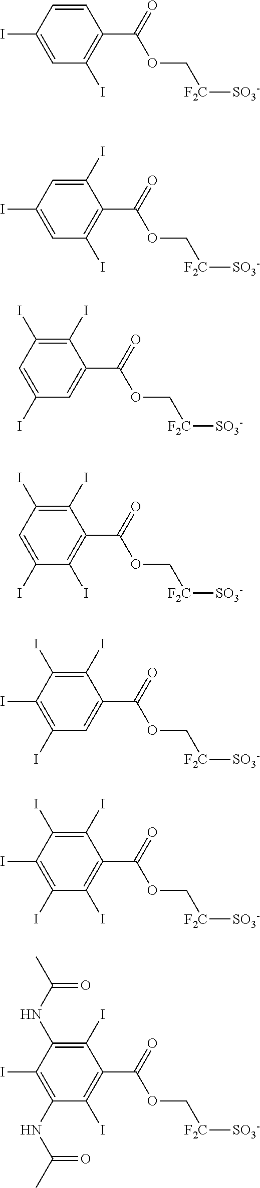

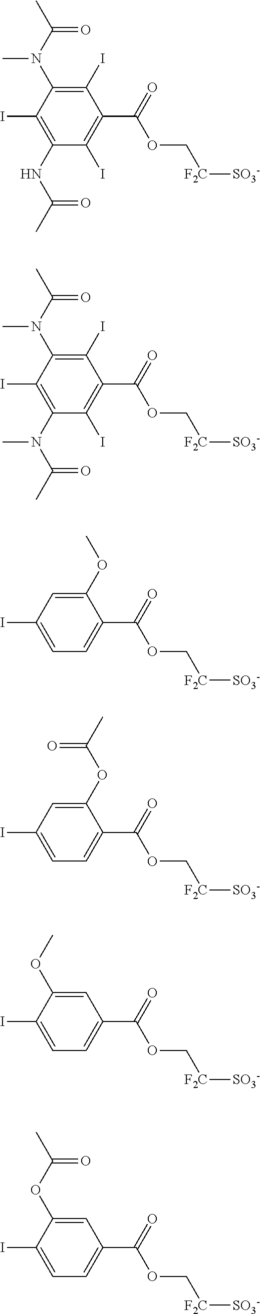

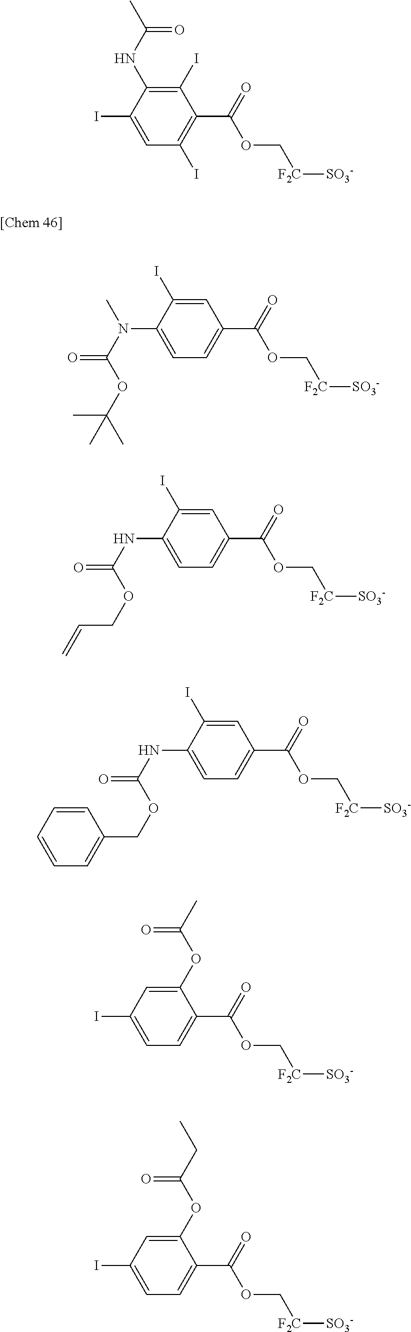

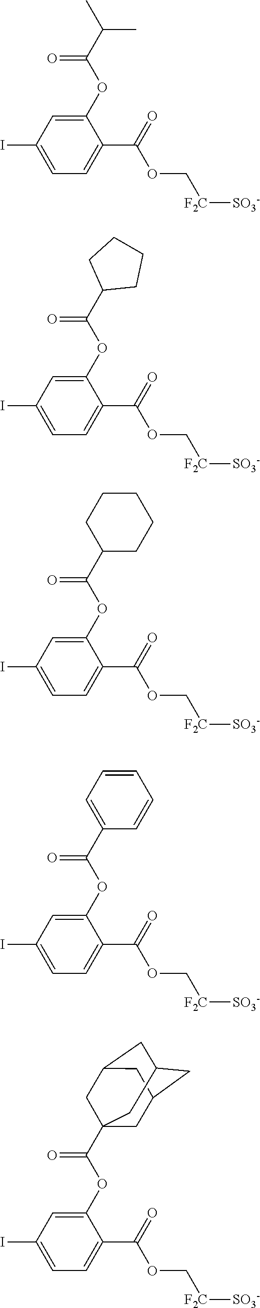

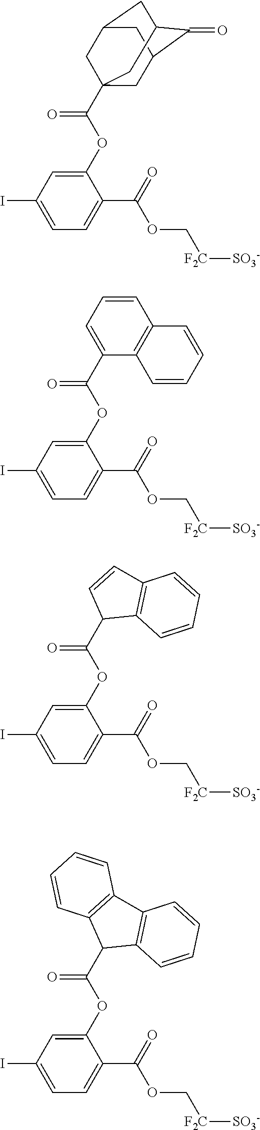

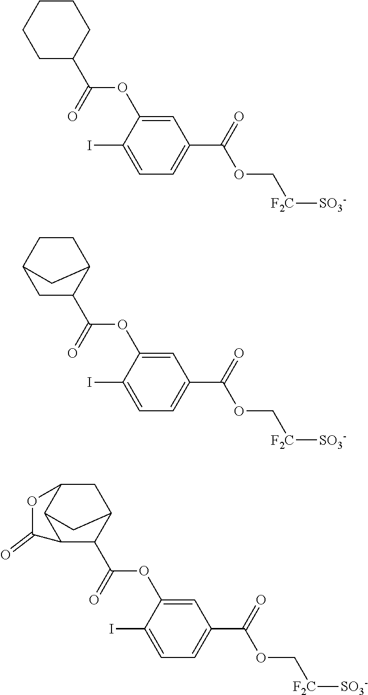

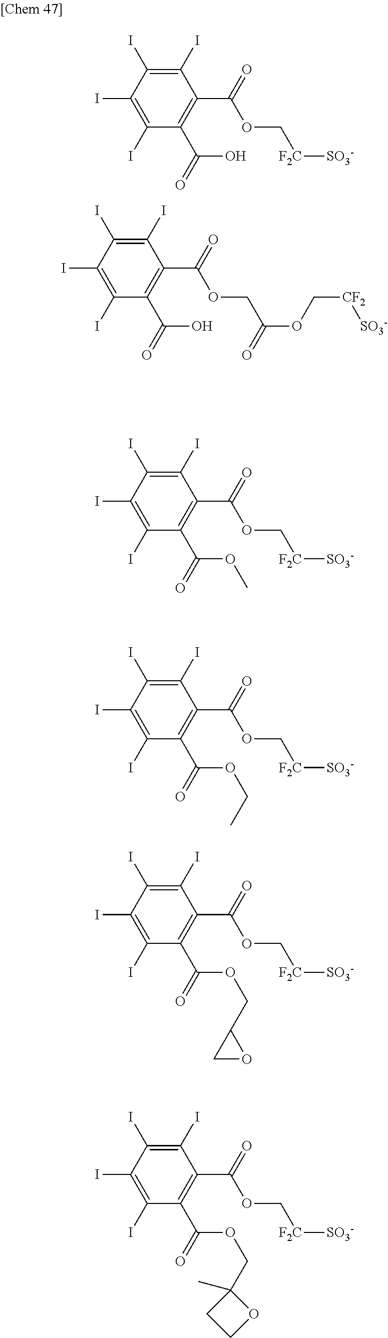

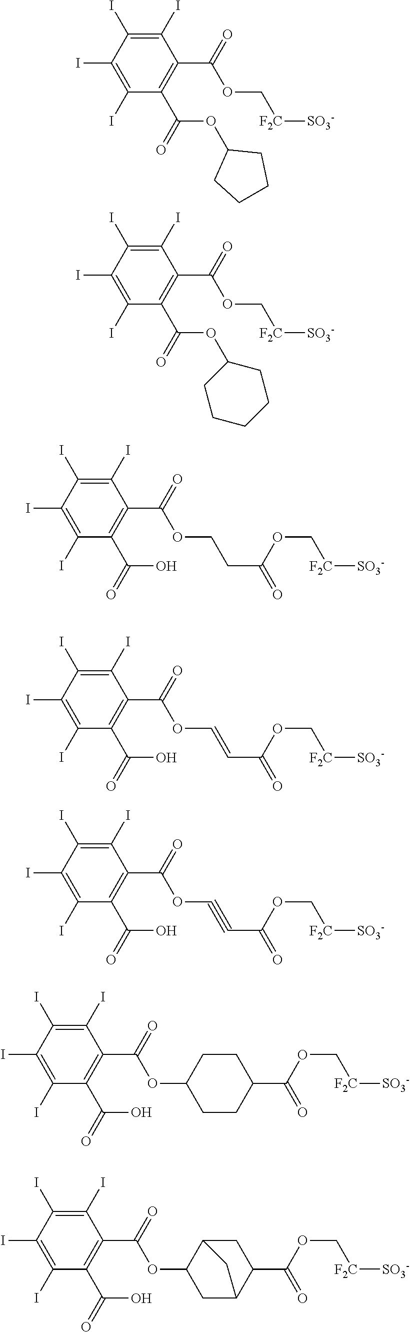

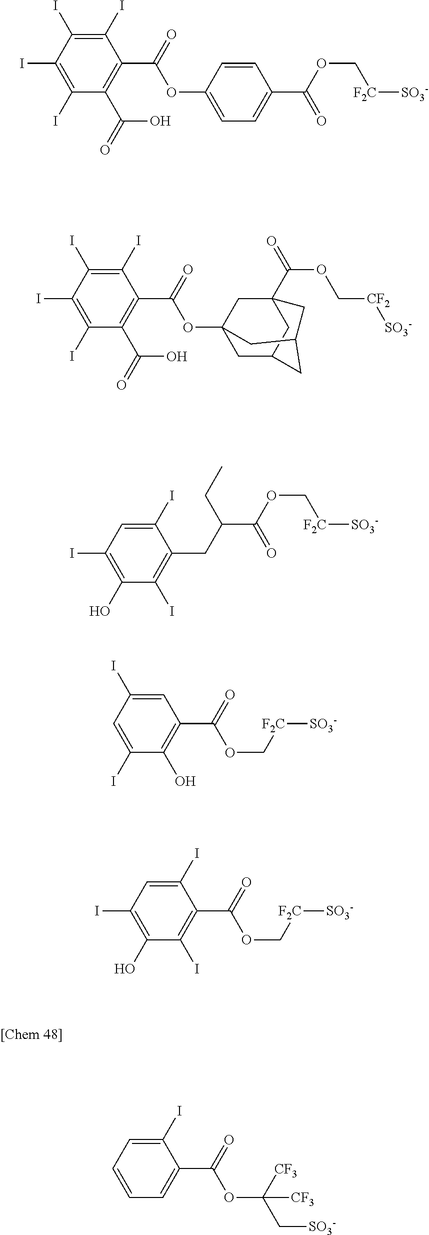

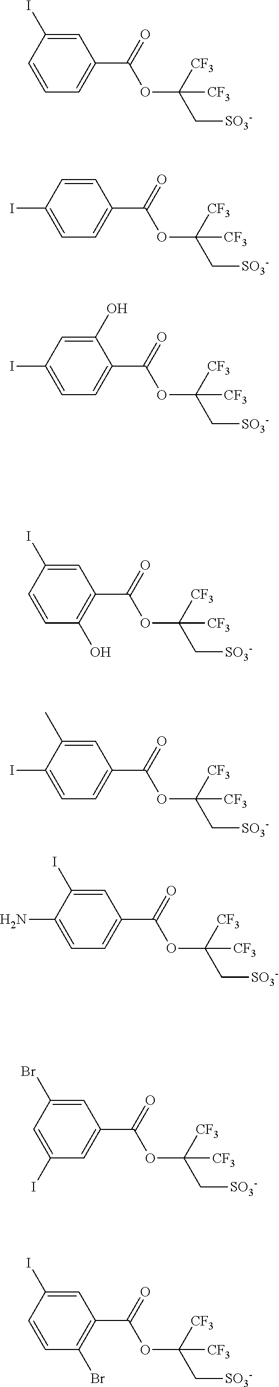

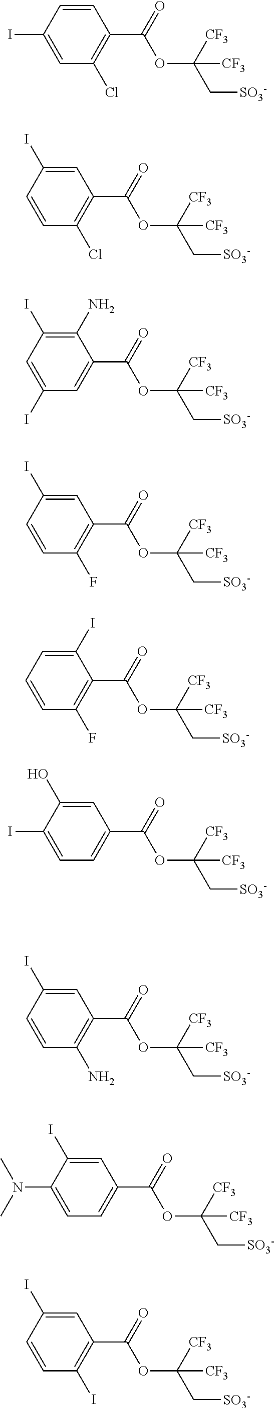

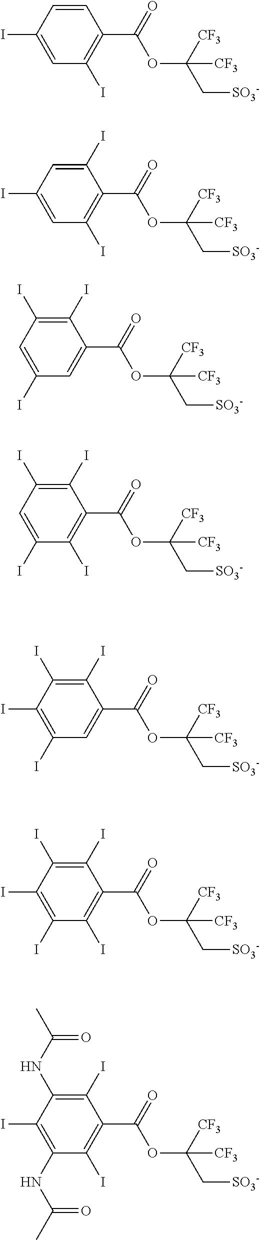

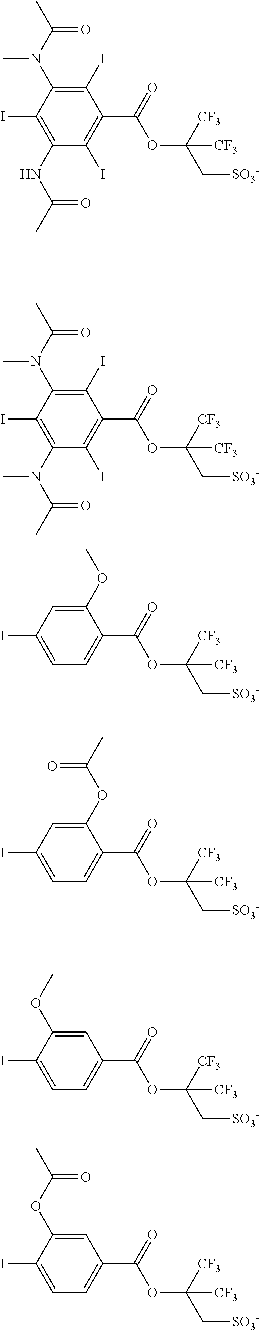

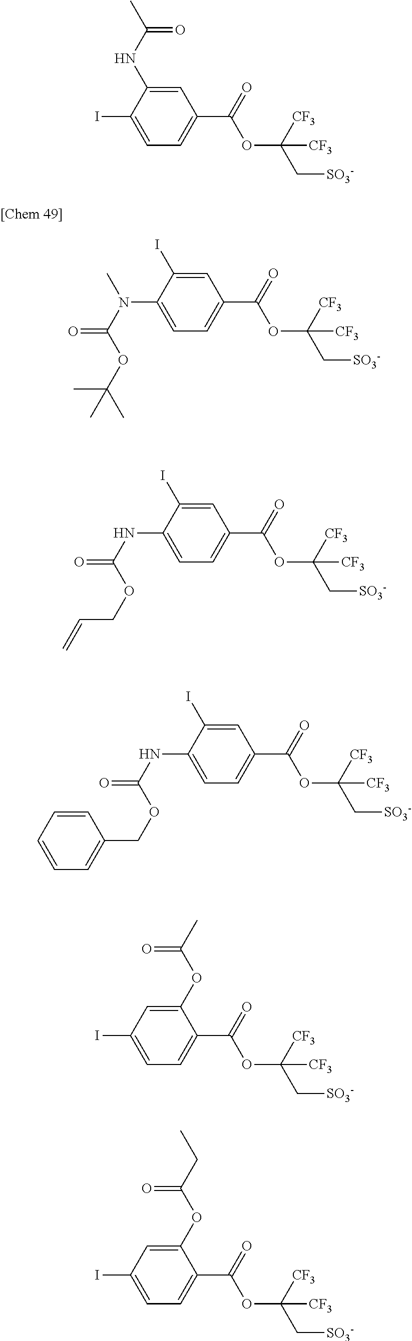

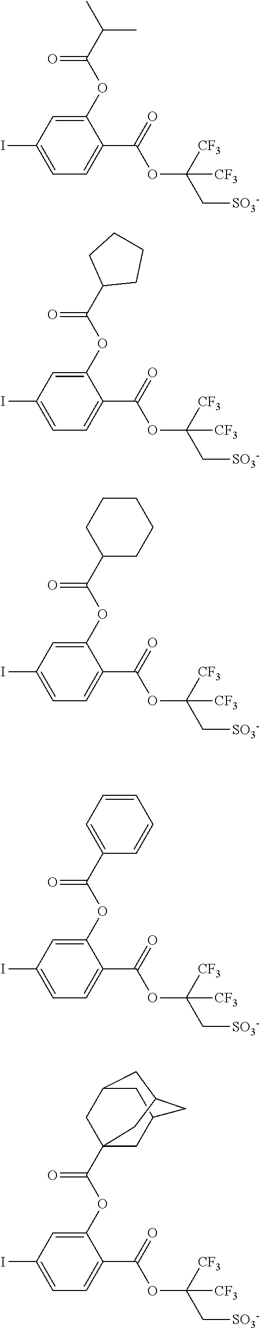

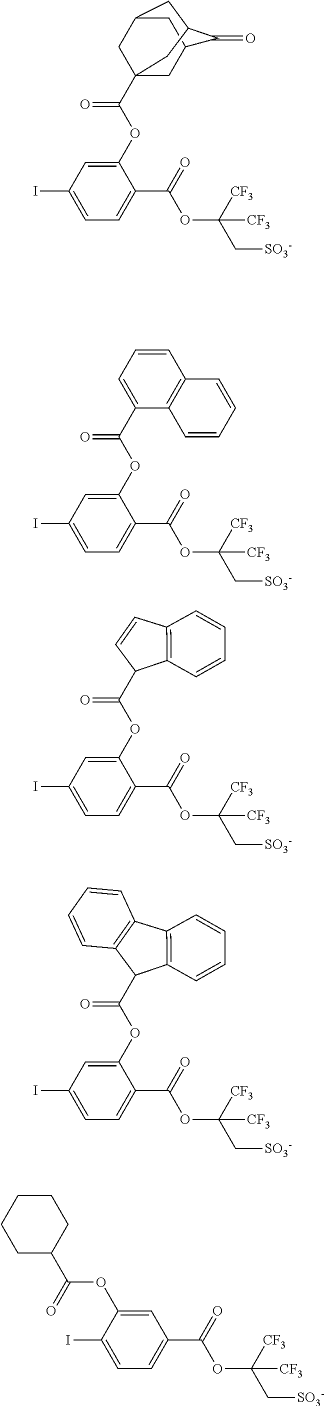

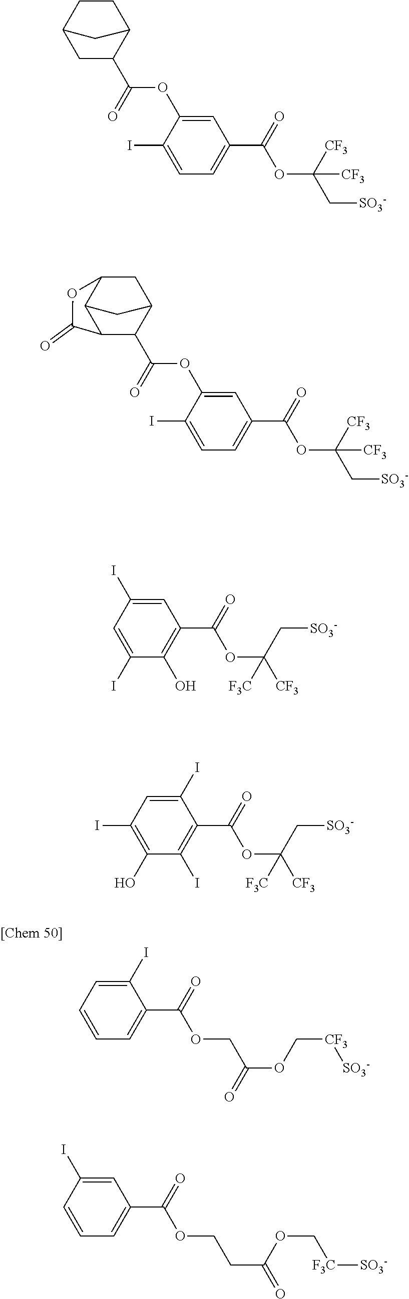

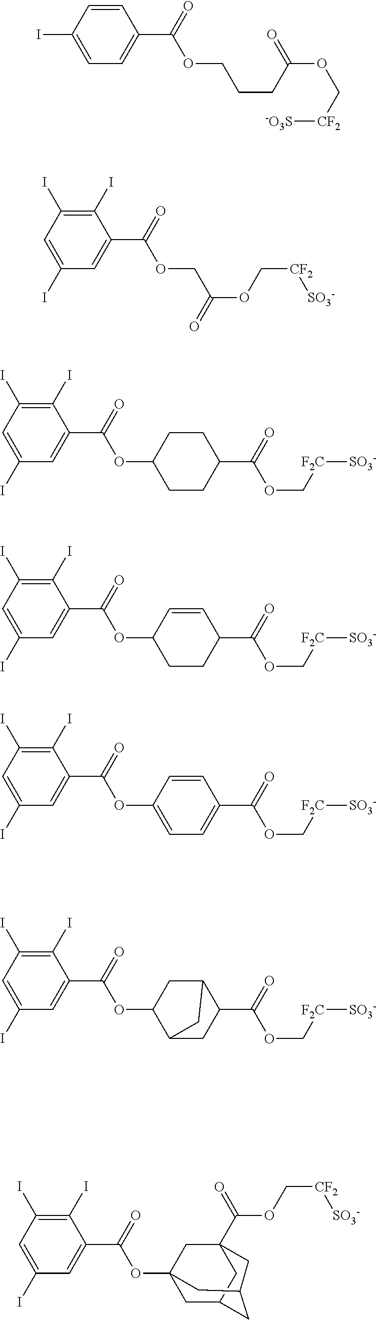

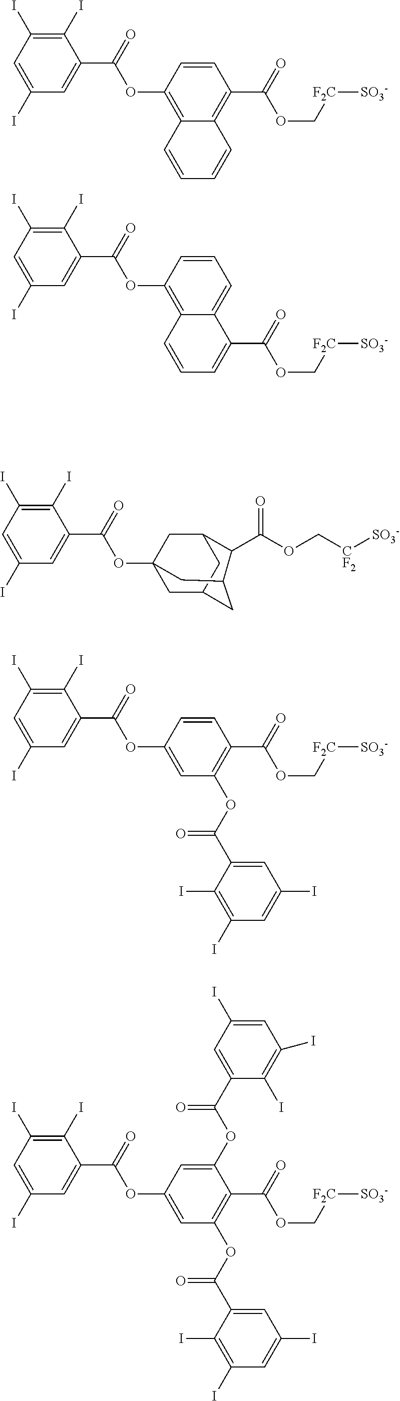

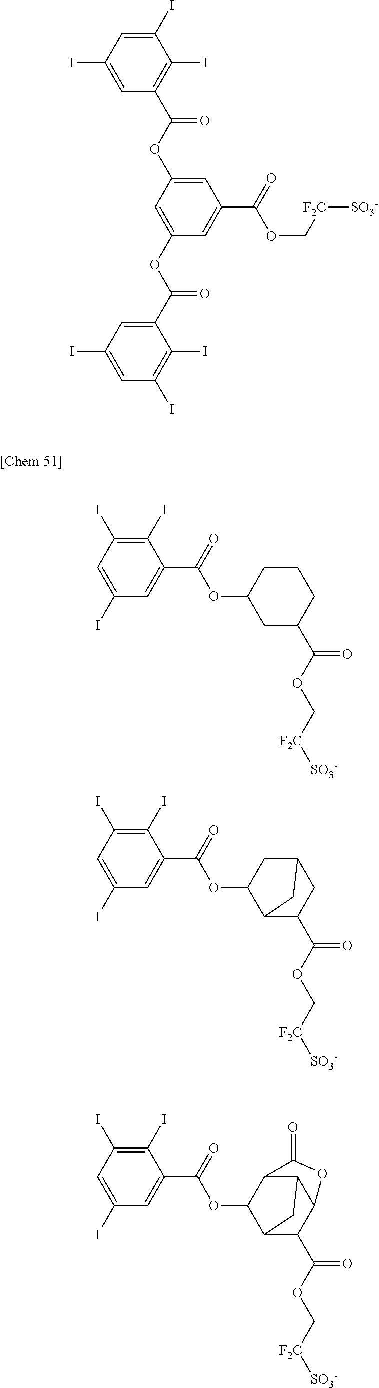

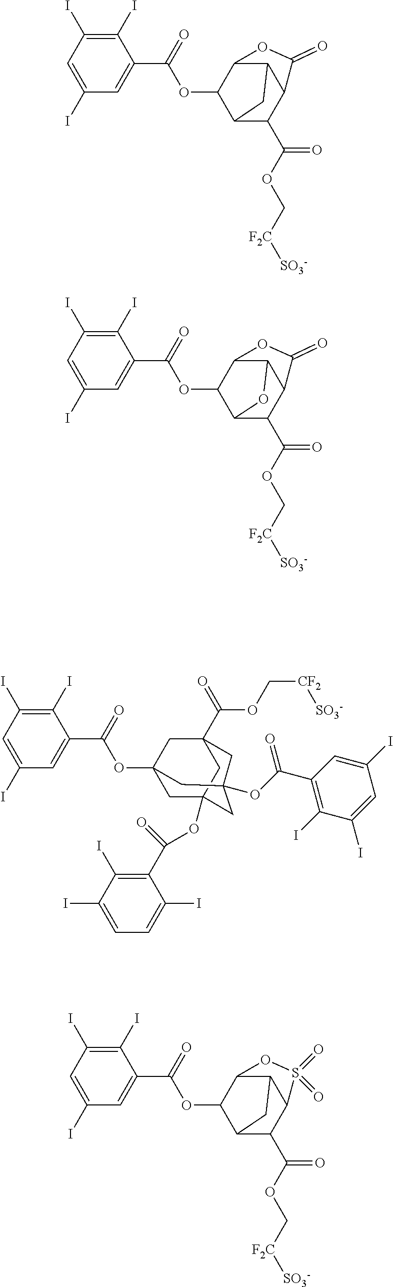

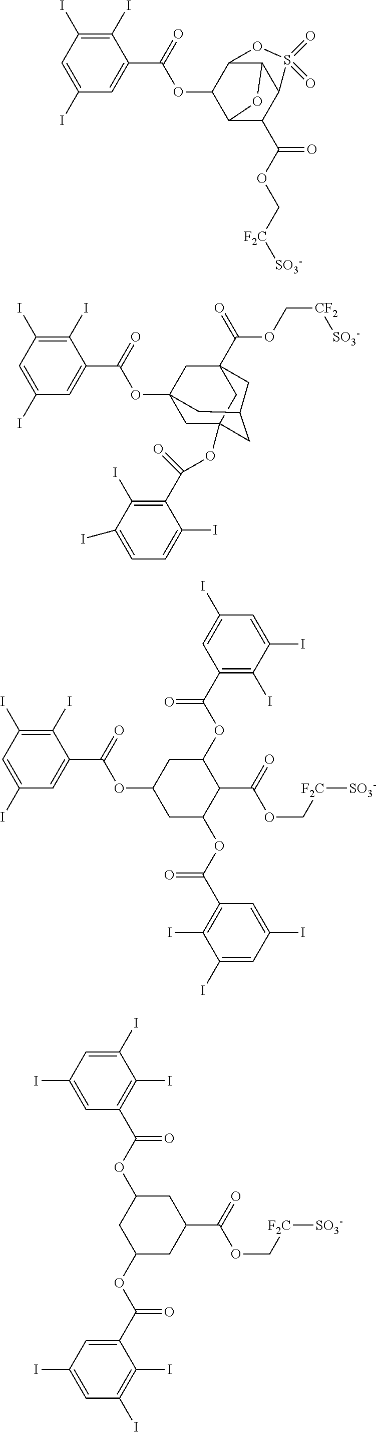

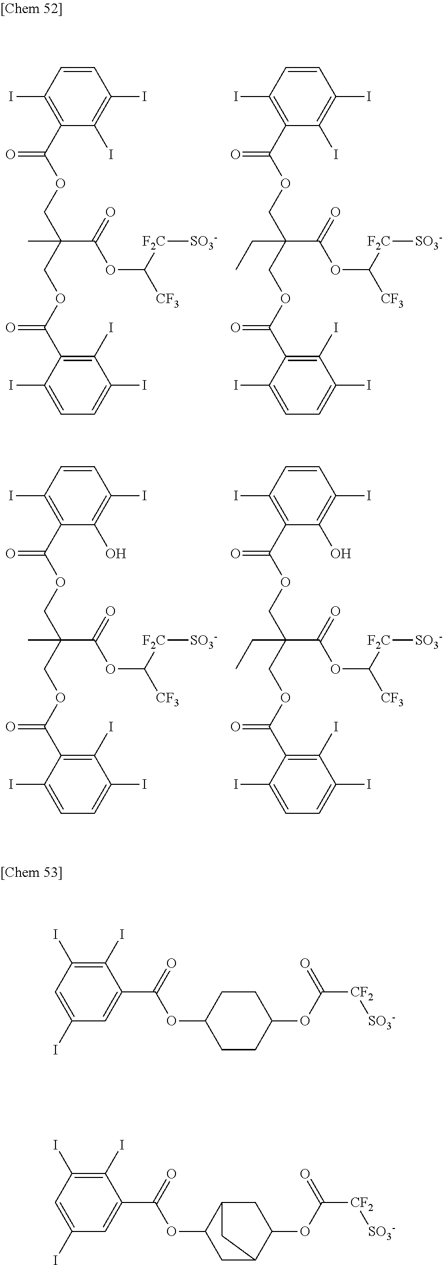

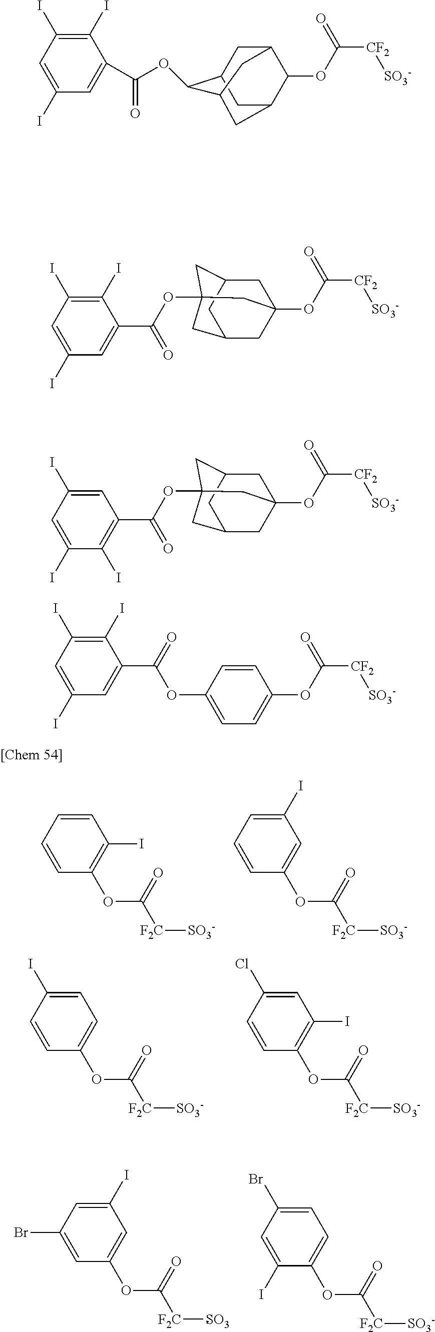

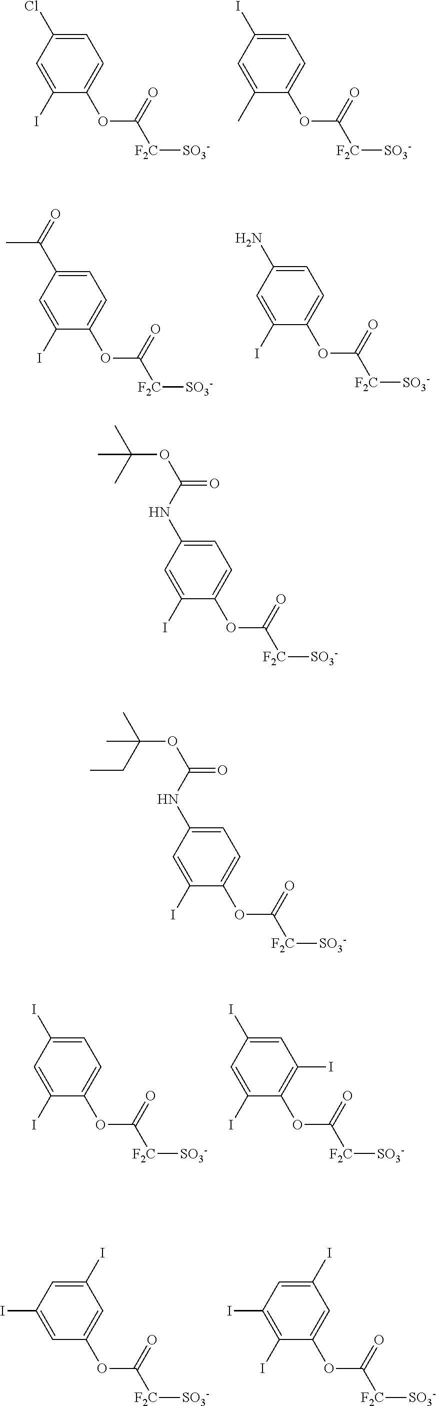

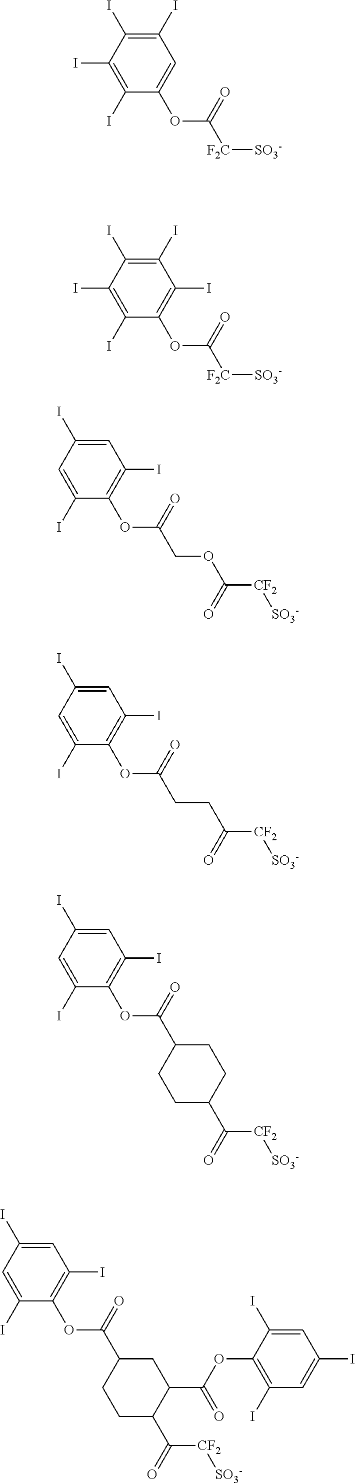

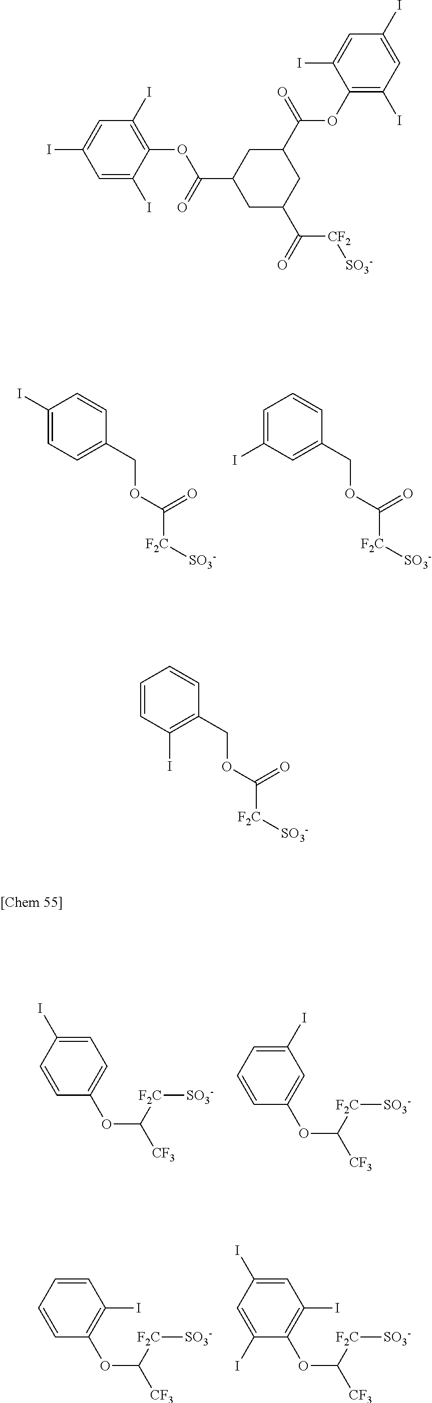

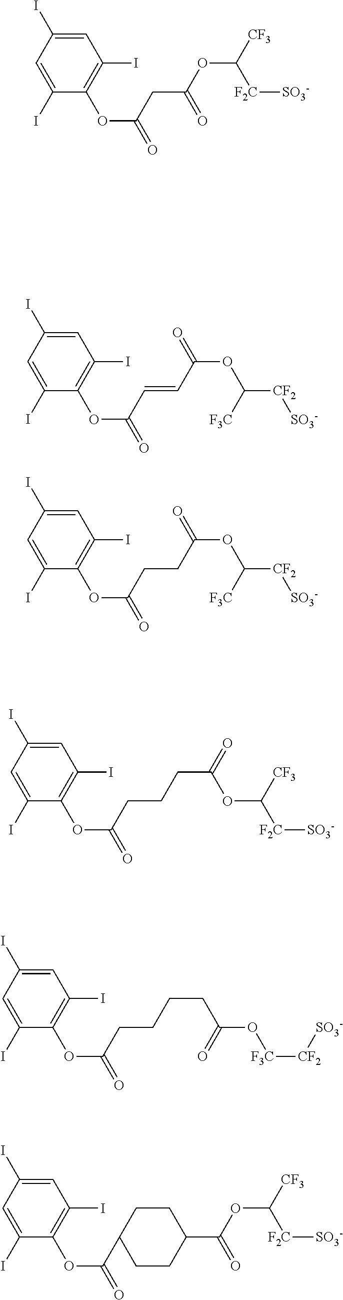

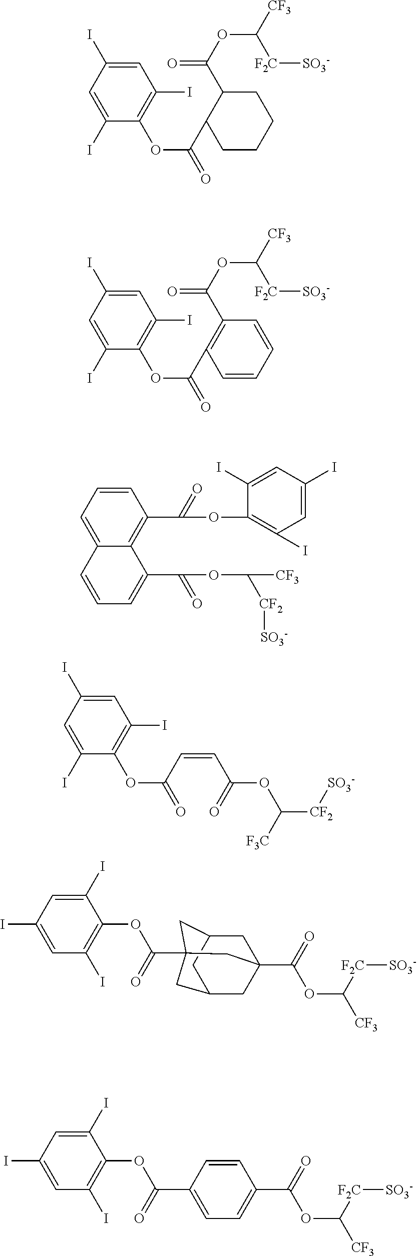

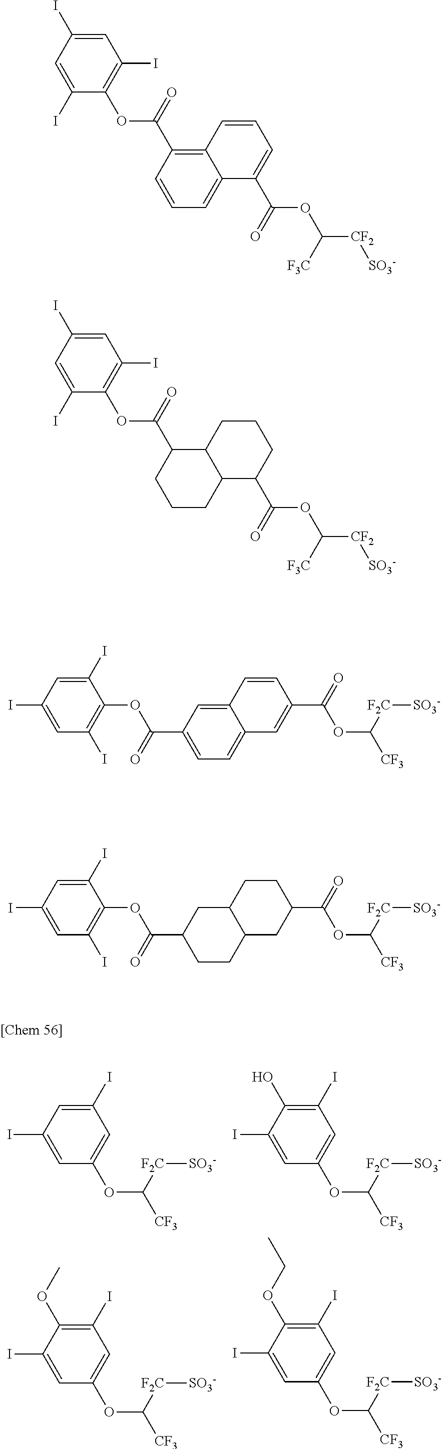

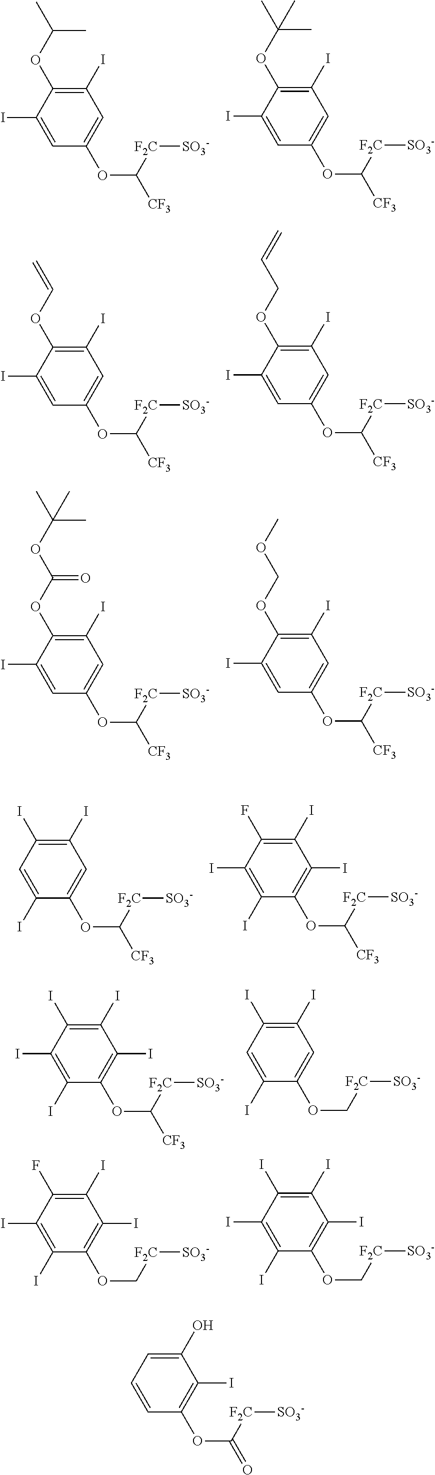

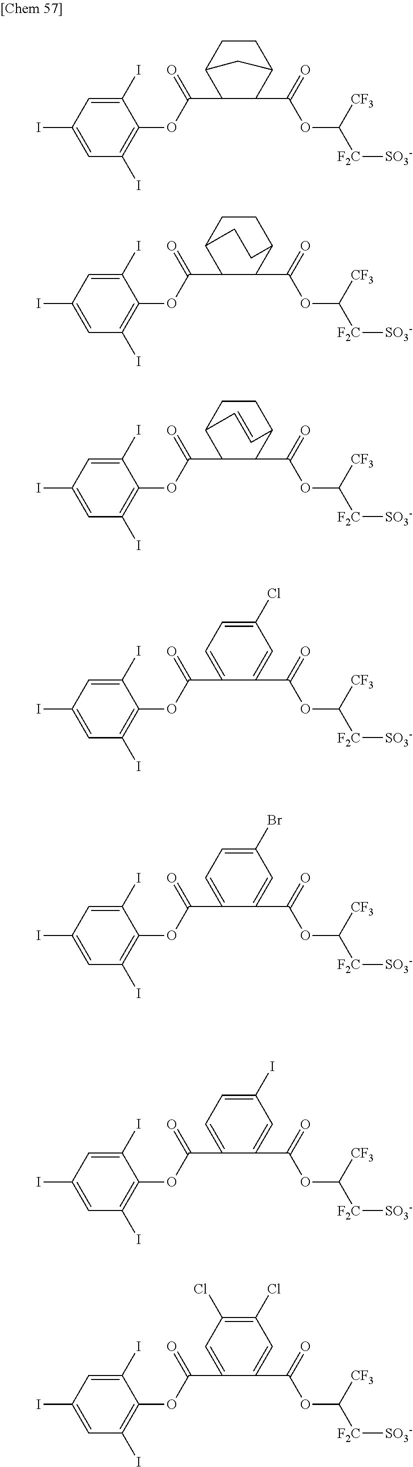

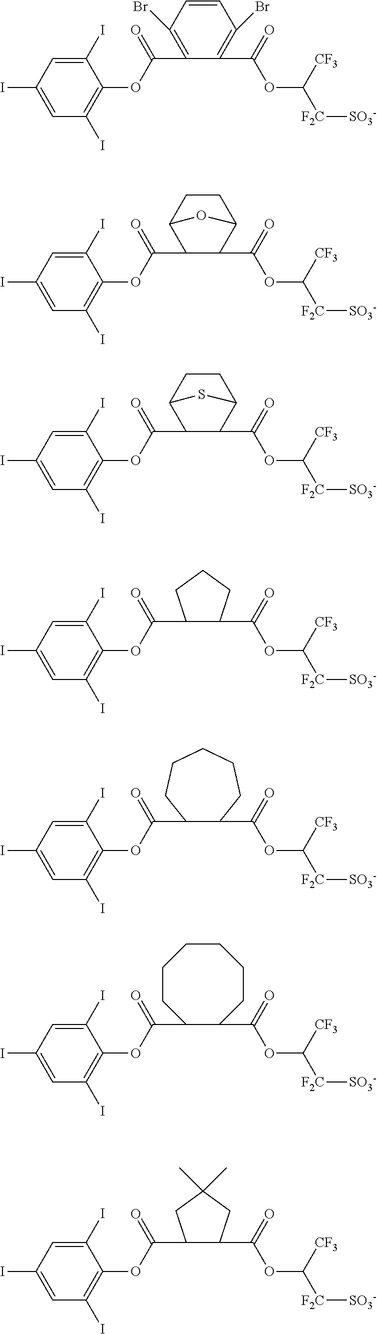

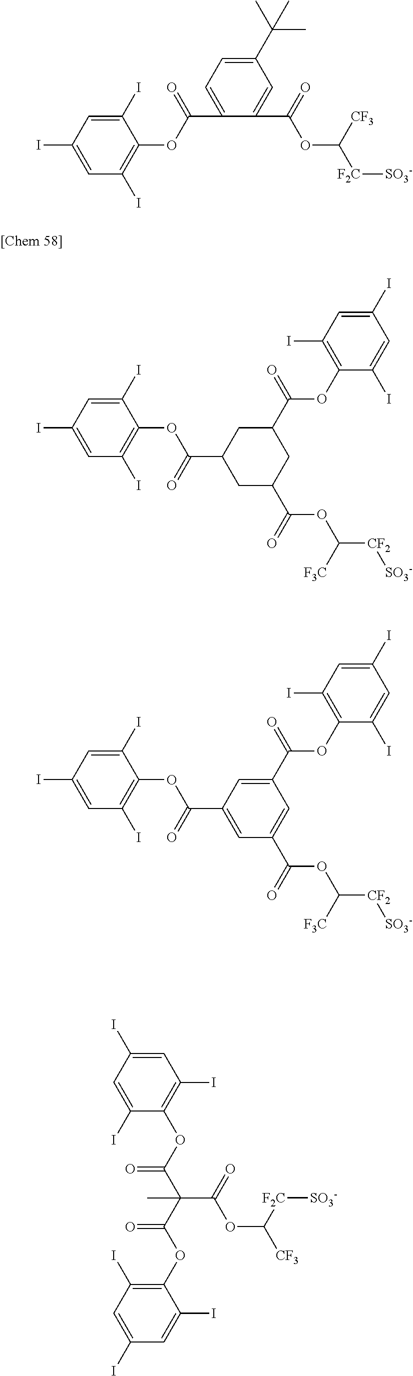

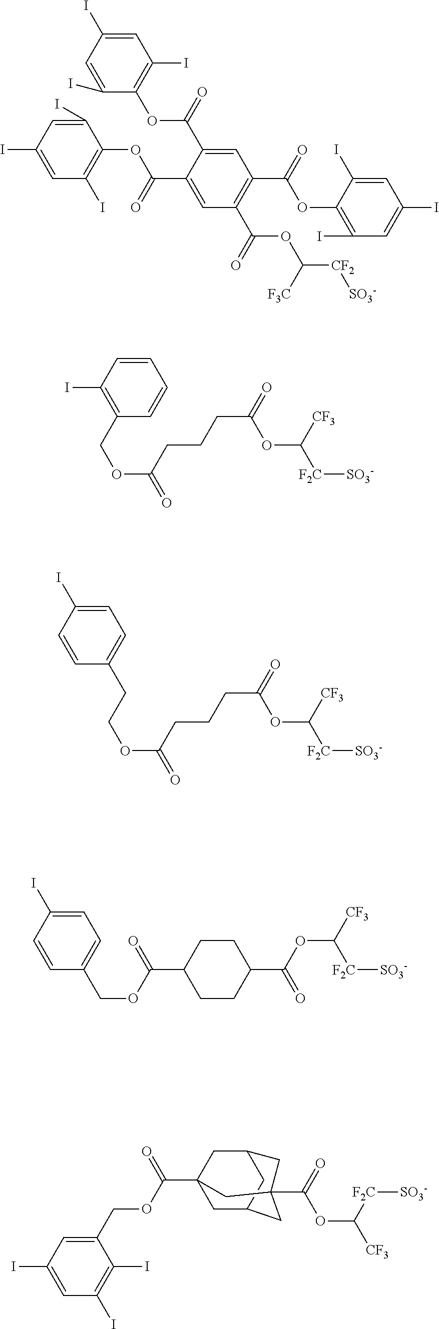

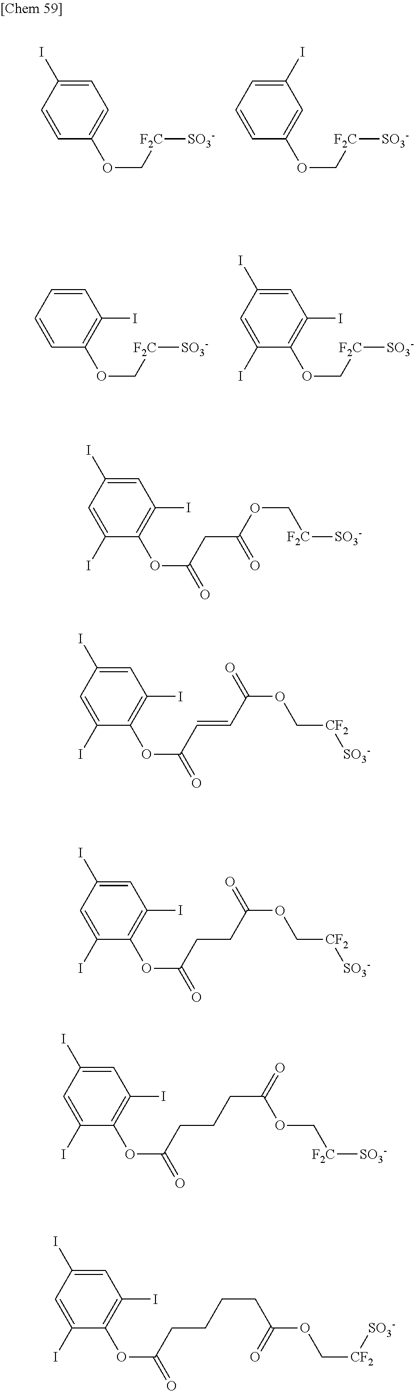

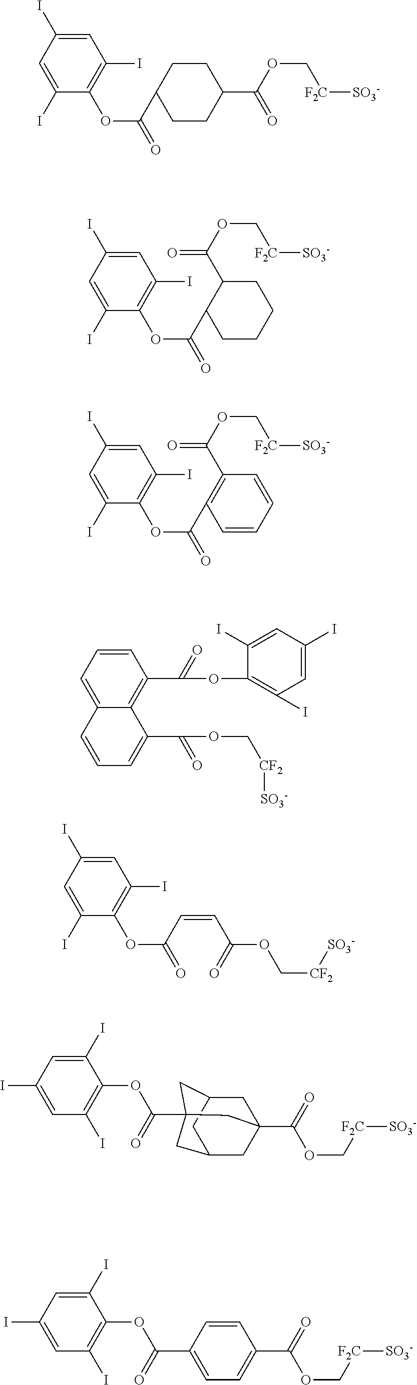

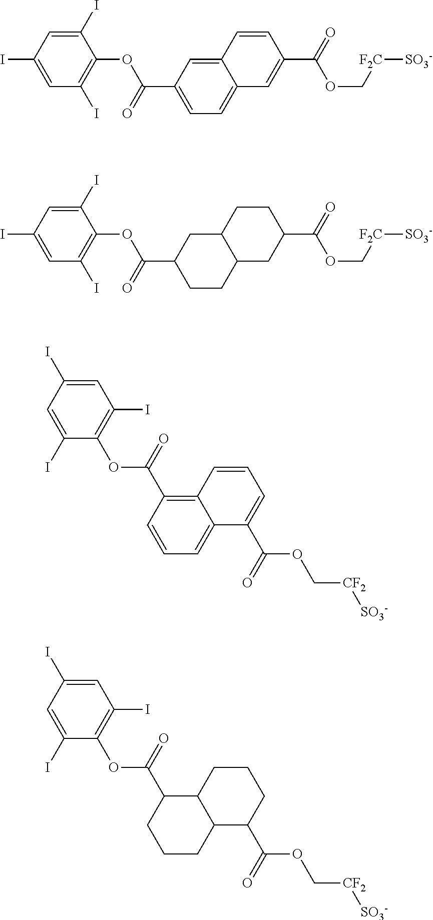

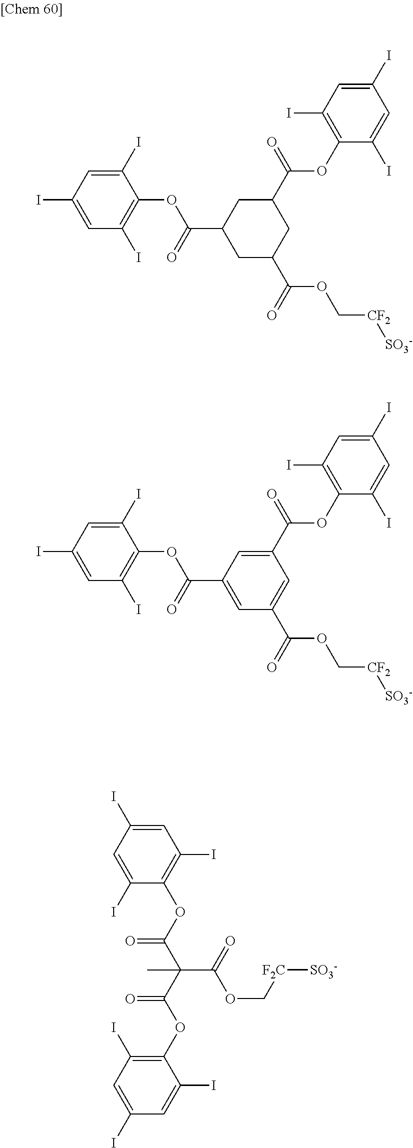

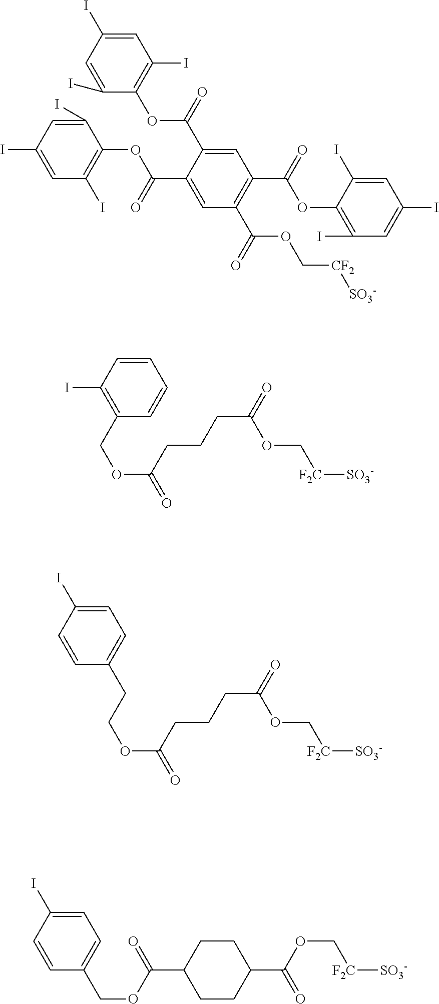

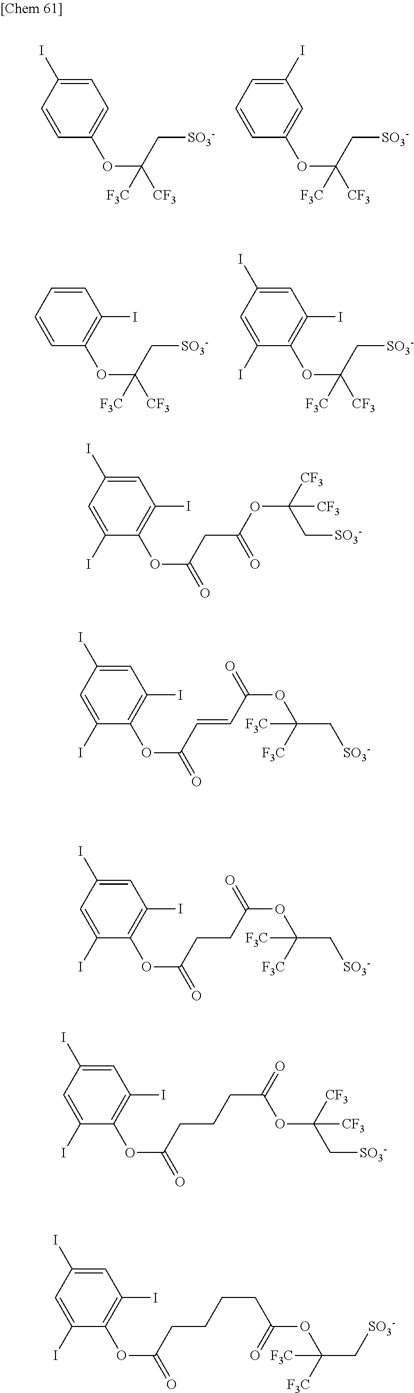

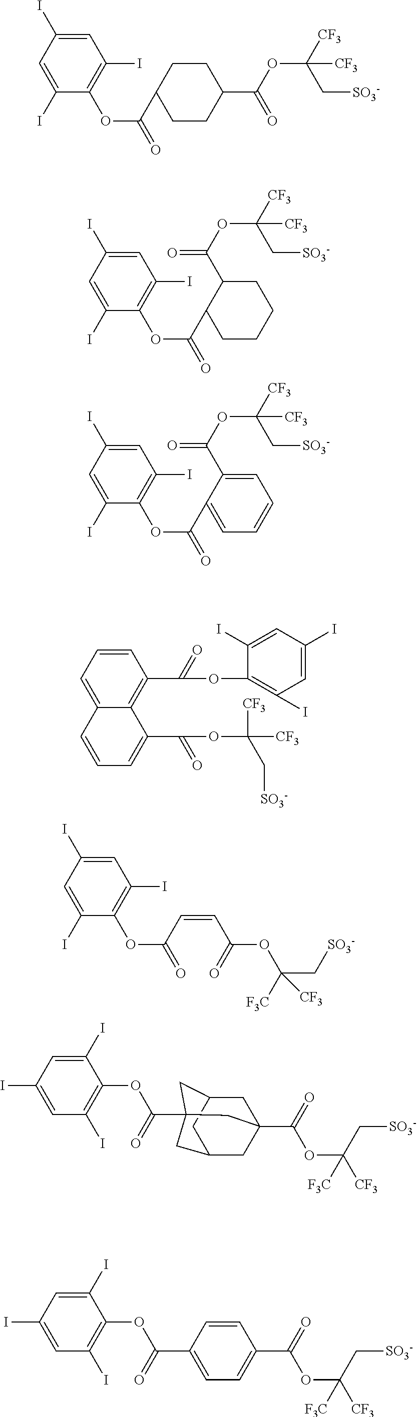

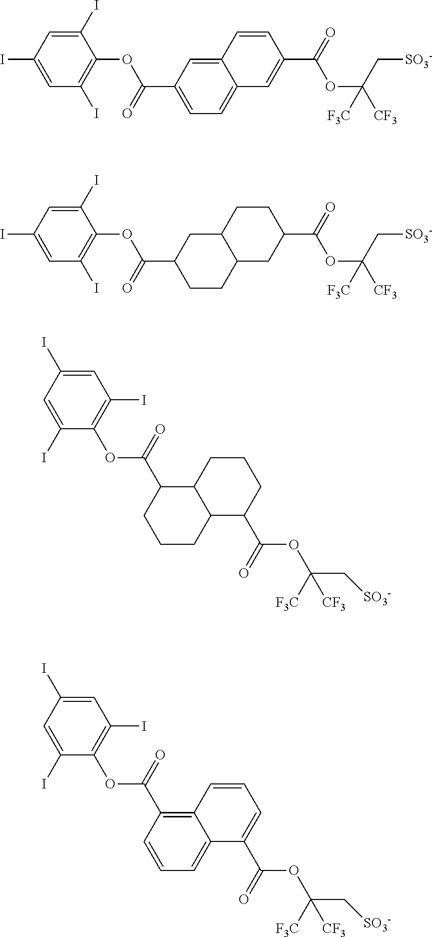

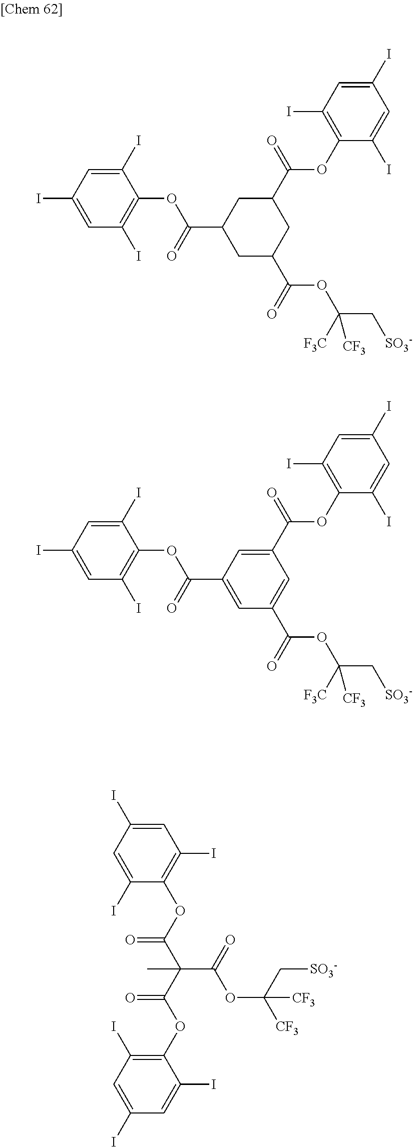

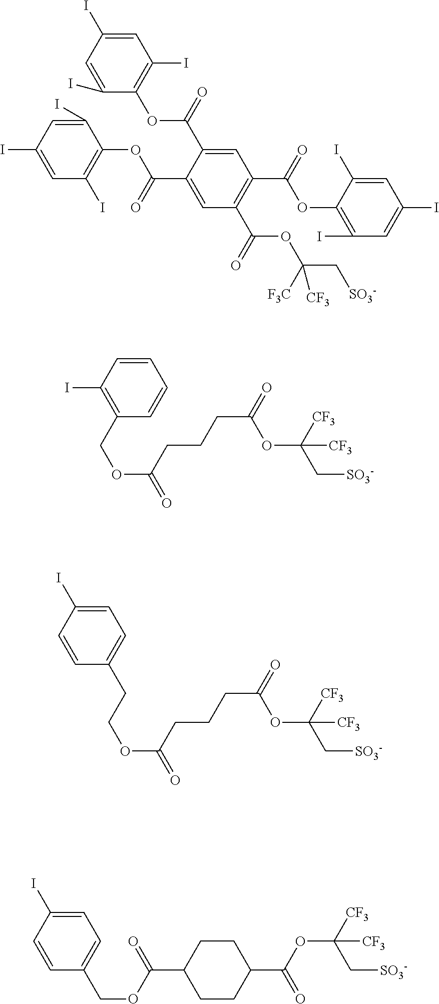

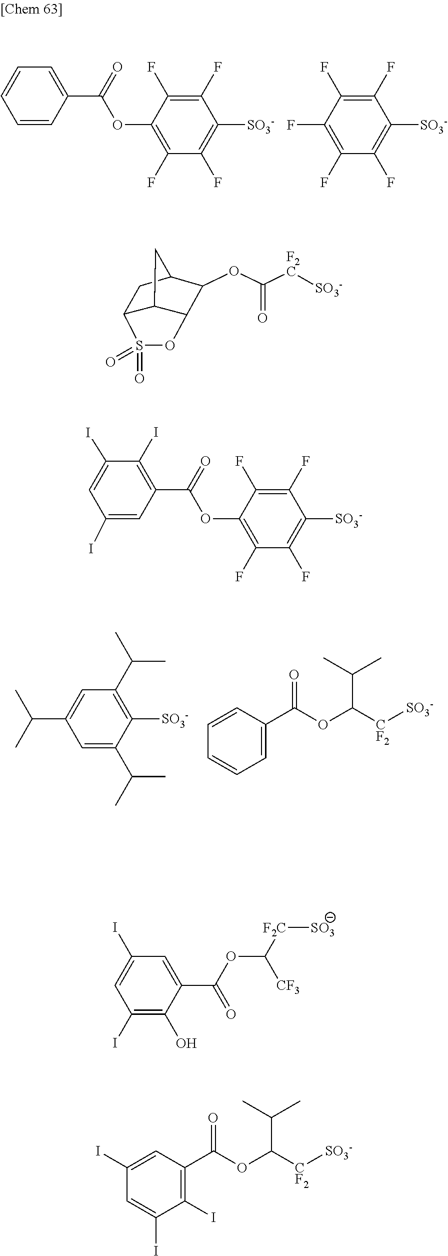

As the onium cation moiety in the radiation-sensitive acid generator represented by formula (A-1), the structure disclosed as the onium cation moieties represented by the above (Q-1) and (Q-2) in the structural unit (VII) that can be contained in the resin can be suitably employed.

### (Structure (1) of Other Organic Acid Anion Moieties)

The radiation-sensitive acid generator may contain, as the organic acid anion moiety, a structure represented by formula (bd1) together with or in place of the organic acid anion moieties of the radiation-sensitive acid generators represented by formulas (A-1) and (A-2).

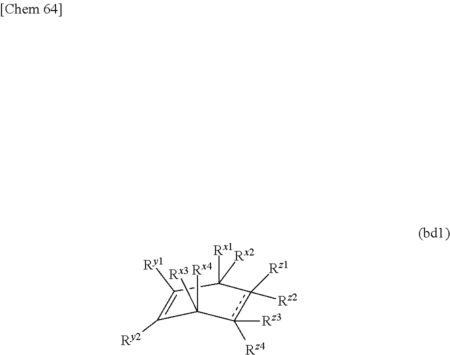

In formula (bd1),
R^{x1} to R^{x4} each independently represent a hydrogen atom, a substituted or unsubstituted hydrocarbon group, or a ring structure formed by combining two or more of them with each other.
R^{y1} to R^{y2} each independently represent a hydrogen atom, a substituted or unsubstituted hydrocarbon group, or a ring structure formed by combining these with each other.

### [Chem 65]

[symbol]

is a double bond or a single bond.
R^{z1} to R^{z4} each independently represent a hydrogen atom, a substituted or unsubstituted hydrocarbon group, or a ring structure formed by combining two or more of them with each other. It is noted that at least one of R^{x1} to R^{x4}, R^{y1} to R^{y2}, and R^{z1} to R^{z4} has a sulfonate anion structure.

Each of the hydrocarbon groups in R^{x1} to R^{x4}, R^{y1} to R^{y2}, and R^{z1} to R^{z4} may be either an aliphatic hydrocarbon group or an aromatic hydrocarbon group, and may be either a cyclic hydrocarbon group or a chain hydrocarbon group.

Examples of the hydrocarbon group which may have a substituent in R^{x1} to R^{x4}, R^{y1} to R^{y2}, and R^{z1} to R^{z4} include a cyclic group optionally having a substituent, a chain alkyl group optionally having a substituent, and a chain alkenyl group optionally having a substituent.

As the hydrocarbon groups in R^{x1} to R^{x4}, R^{y1} to R^{y2}, and R^{z1} to R^{z4}, a cyclic group optionally having a substituent and a chain alkyl group optionally having a substituent are preferable among the above-mentioned hydrocarbon groups.

In formula (bd1), R^{y1} to R^{y2} may be bonded to each other to form a ring structure. The ring structure formed by R^{y1} to R^{y2} shares one side of the six-membered ring in formula (bd1) (the bond between the carbon atoms to which R^{y1} and R^{y2} are bonded), and this ring structure may be either an alicyclic hydrocarbon or an aromatic hydrocarbon. In addition, this ring structure may be a polycyclic structure formed together with a ring structure other than this ring structure.

Among the ring structures formed by R^{y1} to R^{y2}, an aromatic hydrocarbon optionally having a substituent is more preferable from the viewpoint of shortened diffusion of an acid generated by exposure and diffusion controllability of the acid.

In formula (bd1), two or more of R^{z1} to R^{z4} may be bonded to each other to form a ring structure. For example, R^{z1} may form a ring structure with any of R^{z2} to R^{z4}. Specifically, examples thereof include a ring structure sharing one side of the six-membered ring in formula (bd1) (the bond between the carbon atom to which R^{z1} and R^{z2} are bonded and the carbon atom to which R^{z3} and R^{z4} are bonded), a ring structure formed by bonding R^{z1} and R^{z2}, and a ring structure formed by bonding R^{z3} and R^{z4}. The ring structure formed by two or more of R^{z1} to R^{z4} may be either an alicyclic hydrocarbon or an aromatic hydrocarbon, and is particularly preferably an aromatic hydrocarbon. In addition, this ring structure may be a polycyclic structure formed together with a ring structure other than this ring structure.

Among the ring structures formed by two or more of R^{z1} to R^{z4}, a ring structure sharing one side of the six-membered ring in formula (bd1) (the bond between the carbon atom to which R^{z1} and R^{z2} are bonded and the carbon atom to which R^{z3} and R^{z4} are bonded) is preferable from the viewpoint of the diffusion controllability of an acid generated by exposure, and an aromatic ring structure is more preferable.

In formula (bd1), two or more of R^{x1} to R^{x4} may be bonded to each other to form a ring structure. For example, R^{x1} may form a ring structure with any of R^{x2} to R^{x4}. The ring structure formed by two or more of R^{x1} to R^{x4} may be either an alicyclic hydrocarbon or an aromatic hydrocarbon. In addition, this ring structure may be a polycyclic structure formed together with a ring structure other than this ring structure.

Among the ring structures formed by two or more of R^{x1} to R^{x4}, an alicyclic hydrocarbon is preferable from the viewpoint of acid diffusion controllability. Among the ring structures formed by two or more of R^{x1} to R^{x4}, a ring structure in which at least one of R^{x1} to R^{x2} and at least one of R^{x3} to R^{x4} are bonded to each other to form a bridged ring structure is preferable from the viewpoint of acid diffusion controllability, and a ring structure in which this ring structure is an alicyclic hydrocarbon is more preferable.

In formula (bd1), at least one of R^{x1} to R^{x4}, R^{y1} to R^{y2}, and R^{z1} to R^{z4} has a sulfonate anion structure, and when the number of sulfonate anion structure is n, the entire organic acid anion moiety is an n-valent anion. n is an integer of 1 or more.

In the organic anion moiety represented by the above formula (bd1), R^{x1} to R^{x4}, R^{y1} to R^{y2}, and R^{z1} to R^{z4} each may have a sulfonate anion structure. When two or more of R^{x1} to R^{x4} are bonded to each other to form a ring structure, a carbon atom forming the ring structure or a hydrogen atom bonded to the carbon atom may be substituted with a sulfonate anion structure. When two or more of R^{y1} to R^{y2} are bonded to each other to form a ring structure, a carbon atom forming the ring structure or a hydrogen atom bonded to the carbon atom may be substituted with a sulfonate anion structure. When two or more of R^{z1} to R^{z4} are bonded to each other to form a ring structure, a carbon atom forming the ring structure or a hydrogen atom bonded to the carbon atom may be substituted with a sulfonate anion structure.

Examples of the organic anion moiety represented by formula (bd1) include, but are not limited to, those shown below.

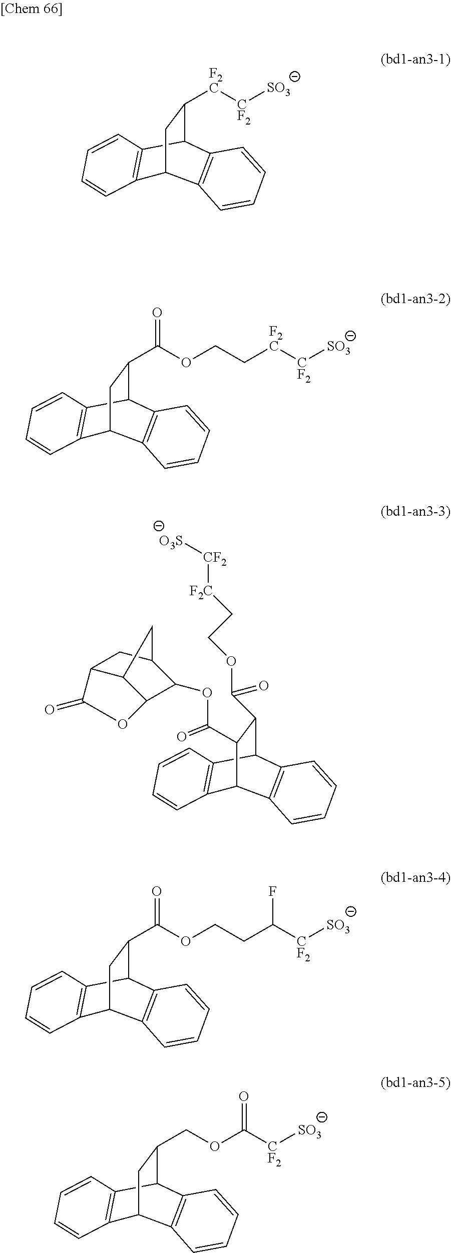

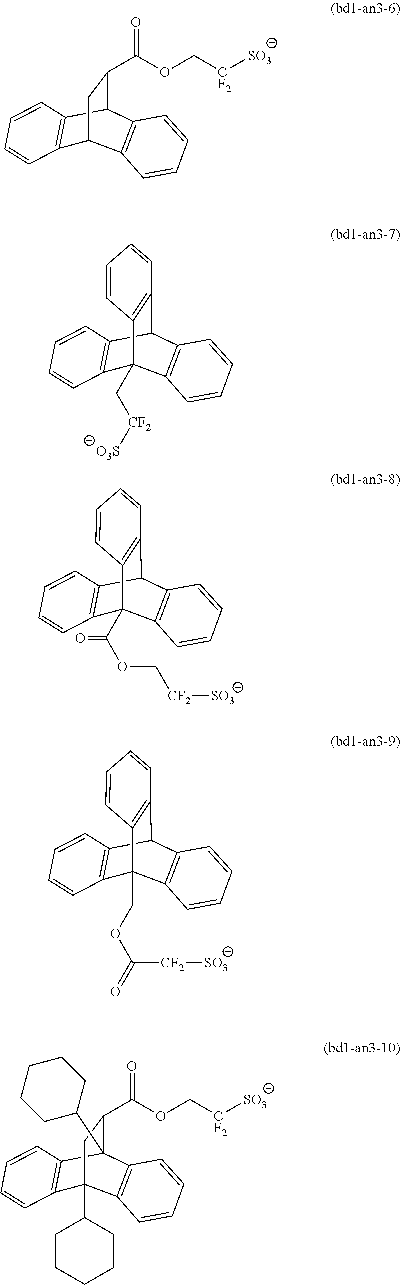

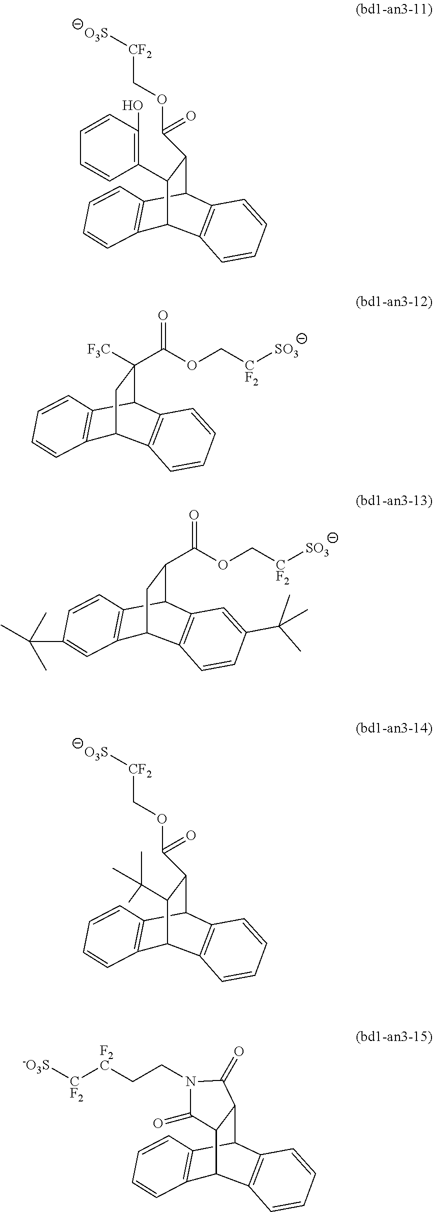

These radiation-sensitive acid generators may be used alone or in combination of two or more thereof. The lower limit of the content of the radiation-sensitive acid generator is preferably 0.5 parts by mass, more preferably 1 part by mass, still more preferably 1.5 parts by mass, and particularly preferably 2 parts by mass per 100 parts by mass of the base resin. The upper limit of the content is preferably 20 parts by mass or less, more preferably 18 parts by mass or less, still more preferably 15 parts by mass or less, and particularly preferably 12 parts by mass or less based on 100 parts by mass of the resin. This makes it possible to exhibit superior sensitivity or CDU performance when forming a resist pattern.

### <Solvent>

The radiation-sensitive resin composition according to the present embodiment contains a solvent. The solvent is not particularly limited as long as it can dissolve or disperse at least the base resin and the acid diffusion controlling agent, and additives or the like contained, as necessary.

Examples of the solvent include an alcohol-based solvent, an ether-based solvent, a ketone-based solvent, an amide-based solvent, an ester-based solvent, and a hydrocarbon-based solvent.

Examples of the alcohol-based solvent include:
a monoalcohol-based solvent having a carbon number of 1 to 18, including iso-propanol, 4-methyl-2-pentanol, 3-methoxybutanol, n-hexanol, 2-ethylhexanol, furfuryl alcohol, cyclohexanol, 3,3,5-trimethylcyclohexanol, and diacetone alcohol;
a polyhydric alcohol having a carbon number of 2 to 18, including ethylene glycol, 1,2-propylene glycol, 2-methyl-2,4-pentanediol, 2,5-hexanediol, diethylene glycol, dipropylene glycol, triethylene glycol, and tripropylene glycol; and
a partially etherized polyhydric alcohol-based solvent in which a part of hydroxy groups in the polyhydric alcohol-based solvent is etherized.

Examples of the ether-based solvent include:
a dialkyl ether-based solvent, including diethyl ether, dipropyl ether, and dibutyl ether;
a cyclic ether-based solvent, including tetrahydrofuran and tetrahydropyran;
an ether-based solvent having an aromatic ring, including diphenylether and anisole (methyl phenyl ether); and
an etherized polyhydric alcohol-based solvent in which a hydroxy group in the polyhydric alcohol-based solvent is etherized.

Examples of the ketone-based solvent include:
a chain ketone-based solvent, including acetone, butanone, and methyl-iso-butyl ketone;
a cyclic ketone-based solvent, including cyclopentanone, cyclohexanone, and methylcyclohexanone; and
2,4-pentanedione, acetonylacetone, and acetophenone.

Examples of the amide-based solvent include:
a cyclic amide-based solvent, including N,N′-dimethyl imidazolidinone and N-methylpyrrolidone; and
a chain amide-based solvent, including N-methylformamide, N,N-dimethylformamide, N,N-diethylformamide, acetamide, N-methylacetamide, N,N-dimethylacetamide, and N-methylpropionamide.

Examples of the ester-based solvent include:
a monocarboxylate ester-based solvent, including n-butyl acetate and ethyl lactate;
a partially etherized polyhydric alcohol acetate-based solvent, including diethylene glycol mono-n-butyl ether acetate, propylene glycol monomethyl ether acetate, and dipropylene glycol monomethyl ether acetate;
a lactone-based solvent, including γ-butyrolactone and valerolactone;
a carbonate-based solvent, including diethyl carbonate, ethylene carbonate, and propylene carbonate; and
a polyhydric carboxylic acid diester-based solvent, including propylene glycol diacetate, methoxy triglycol acetate, diethyl oxalate, ethyl acetoacetate, ethyl lactate, and diethyl phthalate.

Examples of the hydrocarbon-based solvent include:
an aliphatic hydrocarbon-based solvent, including n-hexane, cyclohexane, and methylcyclohexane;
an aromatic hydrocarbon-based solvent, including benzene, toluene, di-iso-propylbenzene, and n-amylnaphthalene.

Among them, the ester-based solvent or the ketone-based solvent is preferred. The partially etherized polyhydric alcohol acetate-based solvent, the cyclic ketone-based solvent, or the lactone-based solvent is more preferred. Propylene glycol monomethyl ether acetate, propylene glycol monomethyl ether, cyclohexanone, γ-butyrolactone or ethyl lactate is still more preferred. The radiation-sensitive resin composition may include one type of the solvent, or two or more types of the solvents in combination.

### <Other Optional Components>

The radiation-sensitive resin composition may contain other optional components other than the above-descried components. Examples of other optional components include a cross-linking agent, a localization enhancing agent, a surfactant, an alicyclic backbone-containing compound, and a sensitizer. These other optional components may be used singly or in combination of two or more of them.

### <Method for Preparing Radiation-Sensitive Resin Composition>

The radiation-sensitive resin composition can be prepared by, for example, mixing the resin, the acid diffusion controlling agent and the solvent, as well as other optional components contained if necessary, in a predetermined ratio. The radiation-sensitive resin composition is preferably filtered through, for example, a filter having a pore diameter of about 0.05 μm to 0.20 μm after mixing. The solid matter concentration of the radiation-sensitive resin composition is usually 0.1 mass % to 50 mass %, preferably 0.5 mass % to 30 mass %, more preferably 1 mass % to 20 mass %.

### <<Method for Forming Pattern>>

A pattern forming method according to an embodiment of the present invention includes:
(1) applying the radiation-sensitive resin composition directly or indirectly on a substrate to form a resist film (hereinafter, also referred to as a “resist film forming step”);
(2) exposing the resist film (hereinafter, also referred to as an “exposure step”); and
(3) developing the exposed resist film (hereinafter, also referred to as a “developing step”).

The method for forming a pattern uses the above-described radiation-sensitive resin composition excellent in sensitivity in the exposure step, LWR performance, and CDU performance, and therefore a high-quality resist pattern can be formed. Hereinbelow, each of the steps will be described.

### [Resist Film Forming Step]

In this step (the above mentioned step (1)), a resist film is formed with the radiation-sensitive resin composition. Examples of the substrate on which the resist film is formed include one traditionally known in the art, including a silicon wafer, silicon dioxide, and a wafer coated with aluminum. An organic or inorganic antireflection film may be formed on the substrate, as disclosed in JP-B-06-12452 and JP-A-59-93448. Examples of the applicating method include a rotary coating (spin coating), flow casting, and roll coating. After applicating, a prebake (PB) may be carried out in order to evaporate the solvent in the film, if needed. The temperature of PB is typically from 60° C. to 150° C., and preferably from 80° C. to 140° C. The duration of PB is typically from 5 seconds to 600 seconds, and preferably from 10 seconds to 300 seconds. The thickness of the resist film formed is preferably from 10 nm to 1,000 nm, and more preferably from 10 nm to 500 nm.

When the immersion exposure is carried out, irrespective of presence of a water repellent polymer additive such as the high fluorine-content resin in the radiation-sensitive resin composition, the formed resist film may have a protective film for the immersion which is not soluble into the immersion liquid on the film in order to prevent a direct contact between the immersion liquid and the resist film. As the protective film for the immersion, a solvent-removable protective film that is removed with a solvent before the developing step (for example, see JP-A-2006-227632); or a developer-removable protective film that is removed during the development of the developing step (for example, see WO2005-069076 and WO2006-035790) may be used. In terms of the throughput, the developer-removable protective film is preferably used.

### [Exposing Step]

In this step (the above mentioned step (2)), the resist film formed in the resist film forming step as the step (1) is exposed by irradiating with a radioactive ray through a photomask (optionally through an immersion medium such as water). Examples of the radioactive ray used for the exposure include visible ray, ultraviolet ray, far ultraviolet ray, extreme ultraviolet ray (EUV); an electromagnetic wave including X ray and y ray; an electron beam; and a charged particle radiation such as a ray. Among them, far ultraviolet ray, an electron beam, or EUV is preferred. ArF excimer laser light (wavelength is 193 nm), KrF excimer laser light (wavelength is 248 nm), an electron beam, or EUV is more preferred. An electron beam or EUV having a wavelength of 50 nm or less which is identified as the next generation exposing technology is further preferred.

When the exposure is carried out by immersion exposure, examples of the immersion liquid include water and fluorine-based inert liquid. The immersion liquid is preferably a liquid which is transparent with respect to the exposing wavelength, and has a minimum temperature factor of the refractive index so that the distortion of the light image reflected on the film becomes minimum. However, when the exposing light source is ArF excimer laser light (wavelength is 193 nm), water is preferably used because of the ease of availability and ease of handling in addition to the above considerations. When water is used, a small proportion of an additive that decreases the surface tension of water and increases the surface activity may be added. Preferably, the additive cannot dissolve the resist film on the wafer and can neglect an influence on an optical coating at an under surface of a lens. The water used is preferably distilled water.

After the exposure, post exposure bake (PEB) is preferably carried out to promote the dissociation of the acid-dissociable group in the resin by the acid generated from the radiation-sensitive acid generator with the exposure in the exposed part of the resist film. The difference of solubility into the developer between the exposed part and the non-exposed part is generated by the PEB. The temperature of PEB is typically from 50° C. to 180° C., and preferably from 80° C. to 130° C. The duration of PEB is typically from 5 seconds to 600 seconds, and preferably from 10 seconds to 300 seconds.

### [Developing Step]

In this step (the above mentioned step (3)), the resist film exposed in the exposing step as the step (2) is developed. By this step, the predetermined resist pattern can be formed. After the development, the resist pattern is washed with a rinse solution such as water or alcohol, and the dried, in general.

Examples of the developer used for the development include, in the alkaline development, an alkaline aqueous solution obtained by dissolving at least one alkaline compound such as sodium hydroxide, potassium hydroxide, sodium carbonate, sodium silicate, sodium metasilicate, ammonia water, ethylamine, n-propylamine, diethylamine, di-n-propylamine, triethylamine, methyldiethylamine, ethyldimethylamine, triethanolamine, tetramethyl ammonium hydroxide (TMAH), pyrrole, piperidine, choline, 1,8-diazabicyclo-[5.4.0]-7-undecene, 1,5-diazabicyclo-[4.3.0]-5-nonene. Among them, an aqueous TMAH solution is preferred, and 2.38% by mass of aqueous TMAH solution is more preferred.

In the case of the development with organic solvent, examples of the solvent include an organic solvent, including a hydrocarbon-based solvent, an ether-based solvent, an ester-based solvent, a ketone-based solvent, and an alcohol-based solvent; and a solvent containing an organic solvent. Examples of the organic solvent include one, two or more solvents listed as the solvent for the radiation-sensitive resin composition. Among them, an ester-based solvent or a ketone-based solvent is preferred. The ester-based solvent is preferably an acetate ester-based solvent, and more preferably n-butyl acetate or amyl acetate. The ketone-based solvent is preferably a chain ketone, and more preferably 2-heptanone. The content of the organic solvent in the developer is preferably not less than 80% by mass, more preferably not less than 90% by mass, further preferably not less than 95% by mass, and particularly preferably not less than 99% by mass. Examples of the ingredient other than the organic solvent in the developer include water and silicone oil.

Examples of the developing method include a method of dipping the substrate in a tank filled with the developer for a given time (dip method); a method of developing by putting and leaving the developer on the surface of the substrate with the surface tension for a given time (paddle method); a method of spraying the developer on the surface of the substrate (spray method); and a method of injecting the developer while scanning an injection nozzle for the developer at a constant rate on the substrate rolling at a constant rate (dynamic dispense method).

### Examples

Hereinafter, the present invention will specifically be described with reference to synthesis examples, examples, and comparative examples, but is not limited to the following examples. Methods for measuring various physical property values are shown below.

### [Mw and Mn]

The Mw and the Mn of polymers were measured by gel permeation chromatography (GPC) using GPC columns manufactured by Tosoh Corporation (“G2000HXL”×2, “G3000HXL”×1, “G4000HXL”×1) under the following conditions.
Eluant: tetrahydrofuran (manufactured by Wako Pure Chemical Industries, Ltd.)
Flow rate: 1.0 mL/min
Sample concentration: 1.0% by mass
Amount of sample injected: 100 μL
Column temperature: 40° C.
Detector: differential refractometer
Standard substance: monodisperse polystyrene

The structures of the radiation-sensitive acid generators PAG1 to PAG12 of the sulfonium salts or iodonium salts used in the radiation-sensitive resin compositions of Examples are shown below.

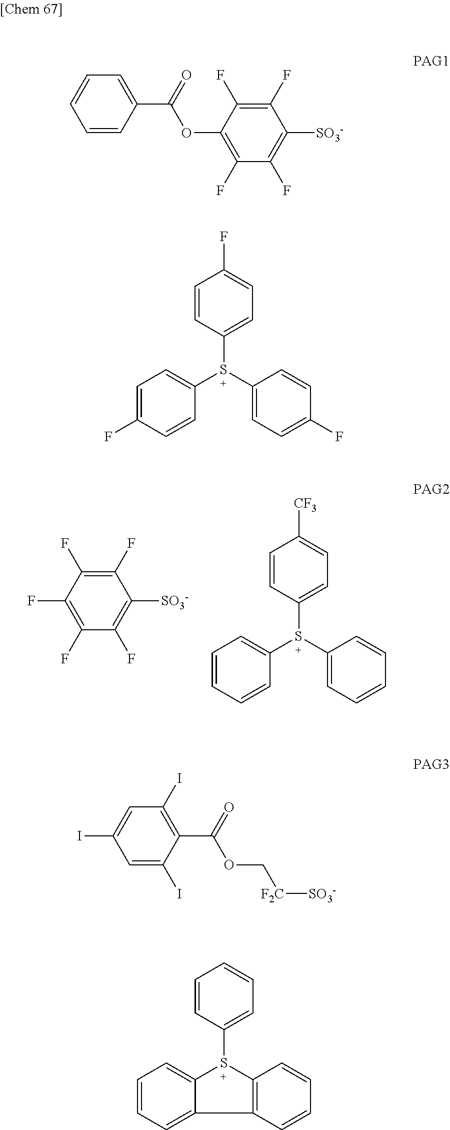

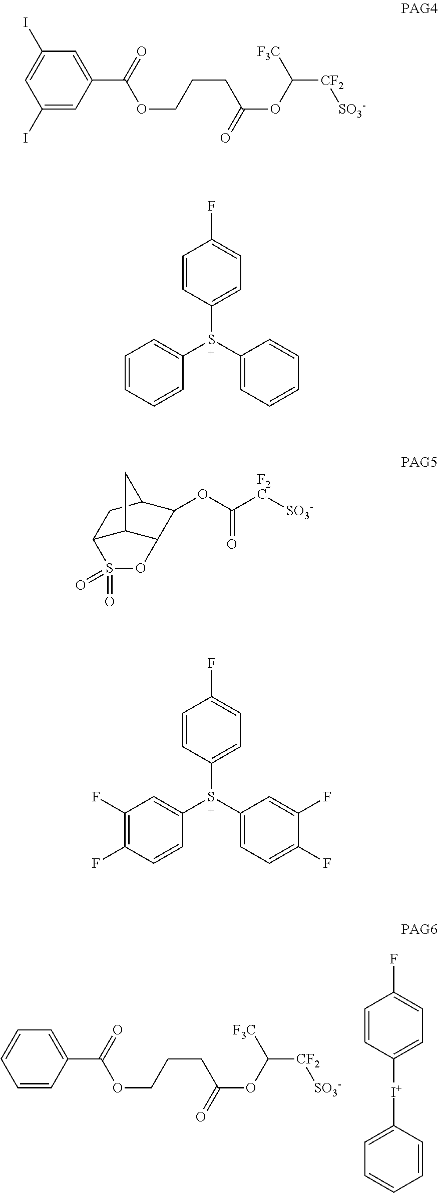

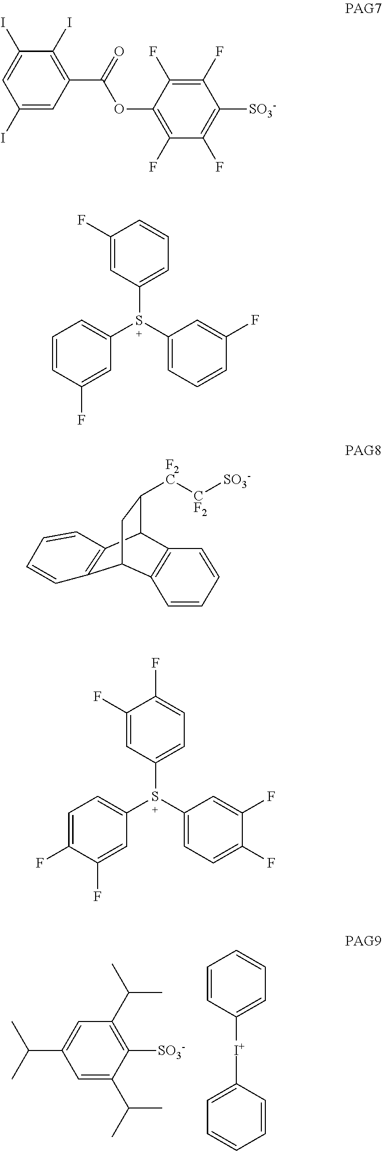

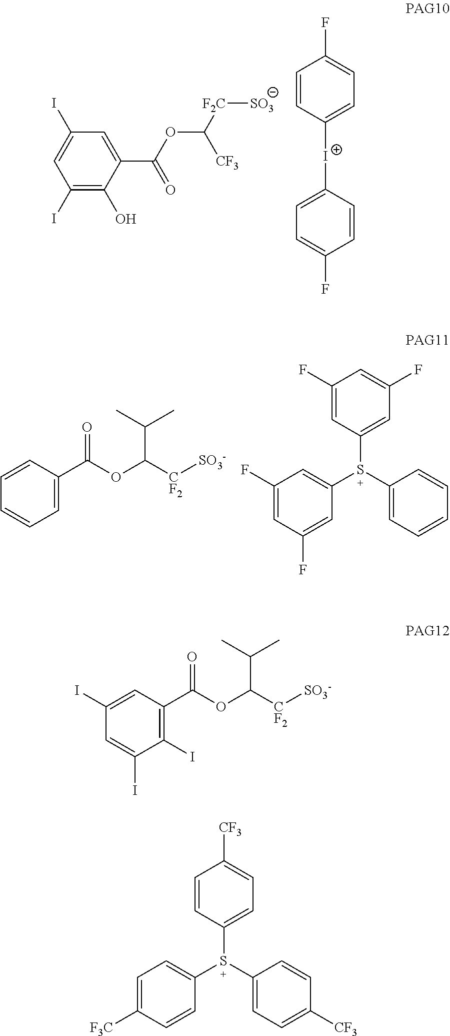

### [Synthesis Examples] Synthesis of Base Resins (P-1) to (P-15) and (Pc-1)

The respective monomers were combined and subjected to a copolymerization reaction in a tetrahydrofuran (THF) solvent, and the reaction products were crystallized in methanol, and washed repeatedly with hexane, then isolated, and dried. Thus, base resins (P-1) to (P-15) and (Pc-1) having the compositions shown below were obtained. The values attached to the structural units are the contents (the total thereof is 1) of the respective structural units. The composition of the obtained base polymers was confirmed by ¹H-NMR, and the Mw and the dispersion degree (Mw/Mn) were confirmed by the above-described GPC (solvent:THF, standard:polystyrene).
P-1: Mw=7,800, Mw/Mn=1.8
P-2: Mw=8,500, Mw/Mn=1.7
P-3: Mw=10,100, Mw/Mn=1.6
P-4: Mw=8,300, Mw/Mn=1.7
P-5: Mw=9,400, Mw/Mn=1.7
P-6: Mw=7,200, Mw/Mn=1.8
P-7: Mw=8,000, Mw/Mn=1.7
P-8: Mw=9,800, Mw/Mn=1.7
P-9: Mw=9,200, Mw/Mn=1.7
P-10: Mw=8,900, Mw/Mn=1.6
P-11: Mw=7,500, Mw/Mn=1.7
P-12: Mw=8,700, Mw/Mn=1.7
P-13: Mw=8,200, Mw/Mn=1.7
P-14: Mw=9,500, Mw/Mn=1.7
P-15: Mw=8,800, Mw/Mn=1.7
Pc-1: Mw=9,300, Mw/Mn=1.7

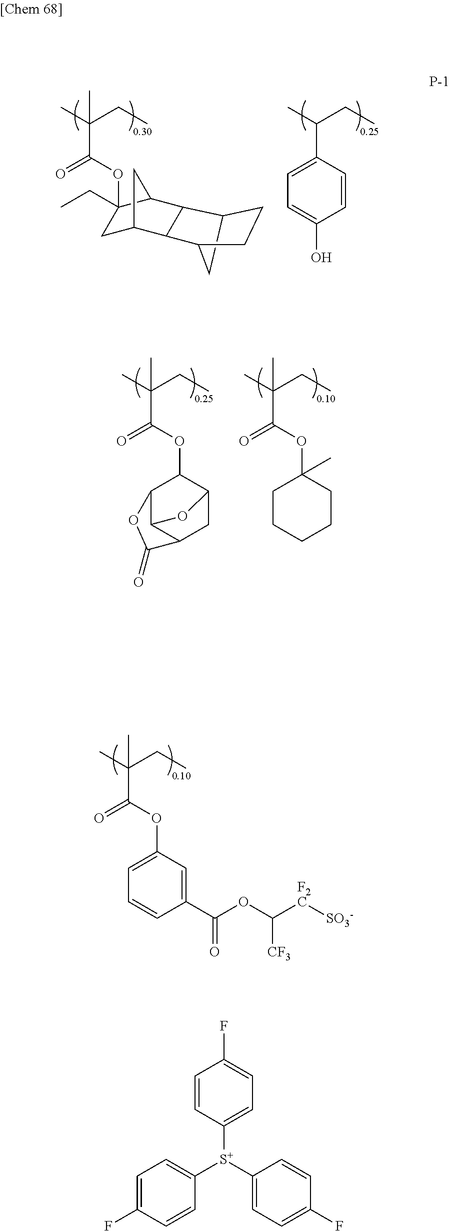

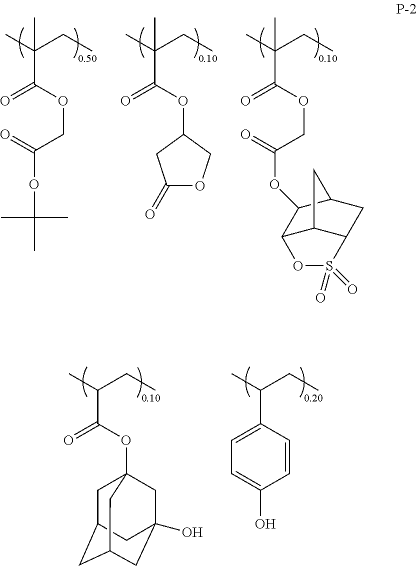

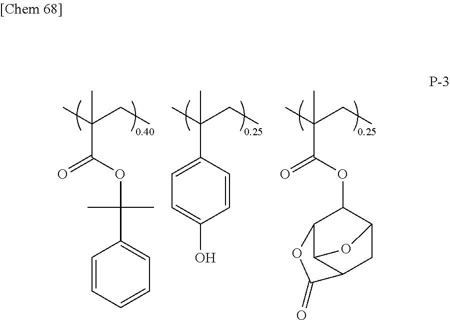

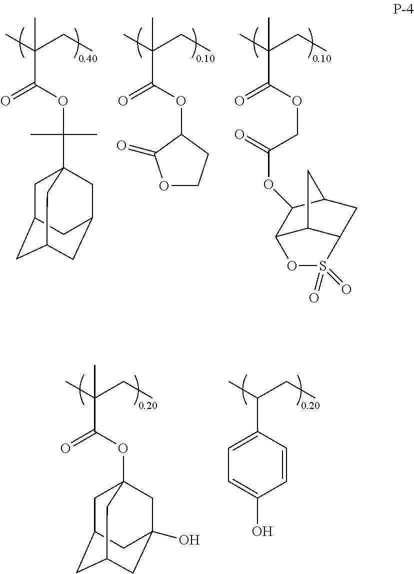

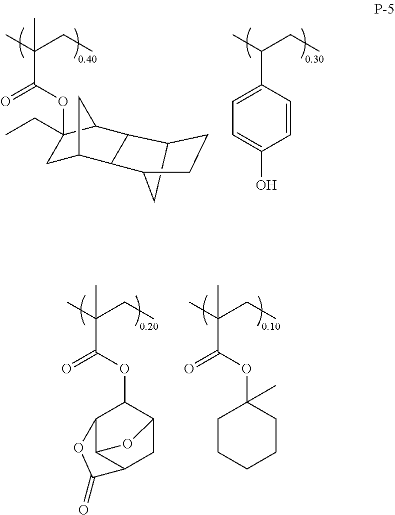

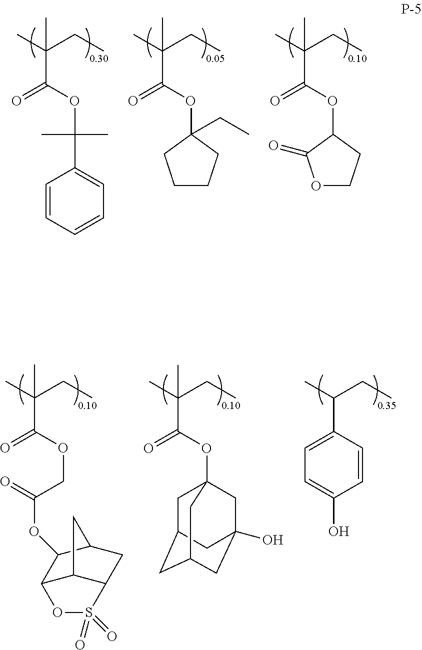

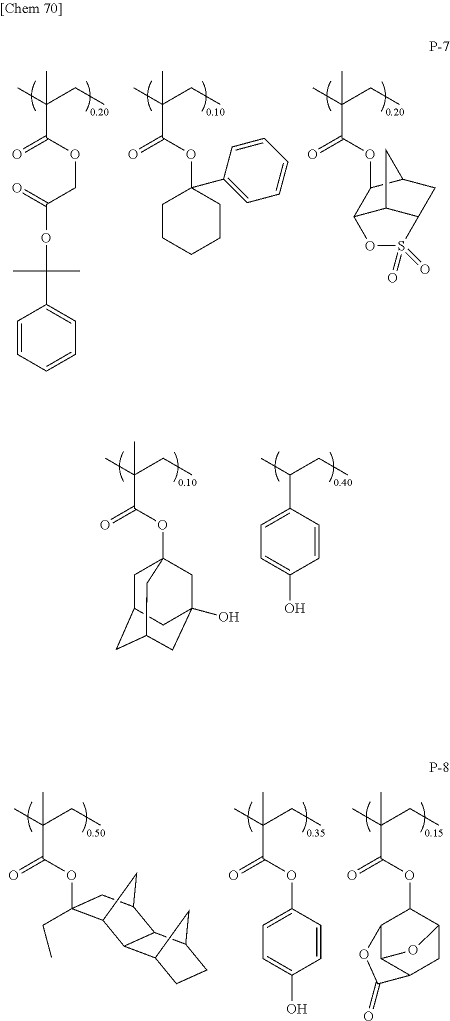

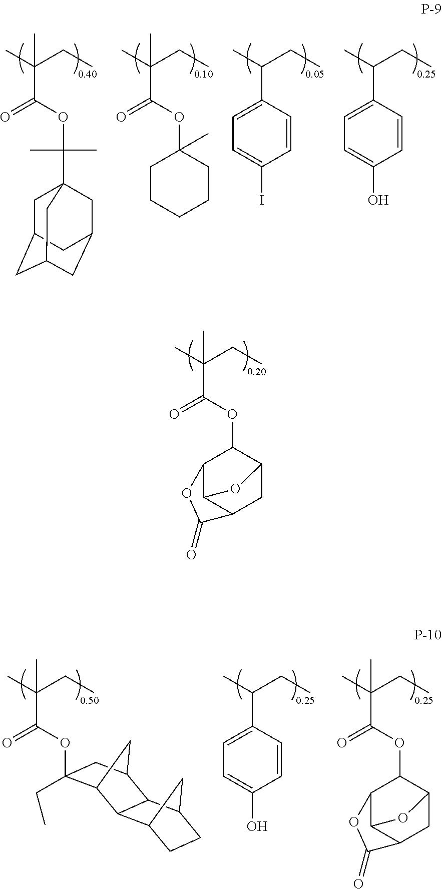

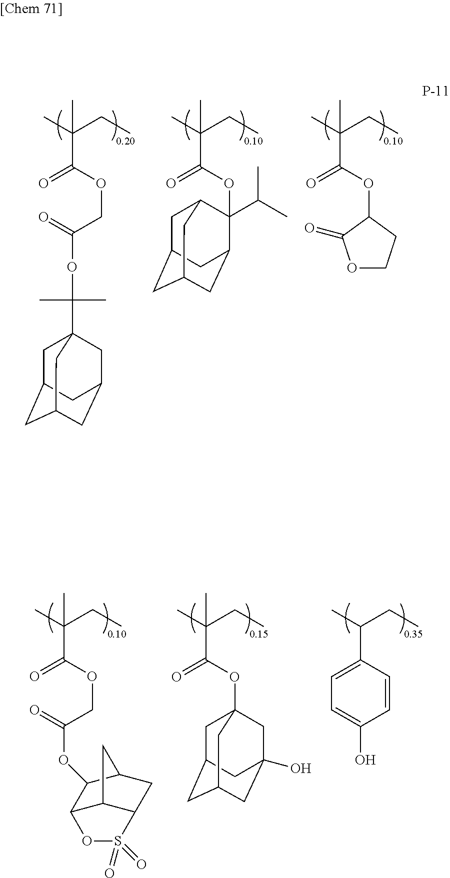

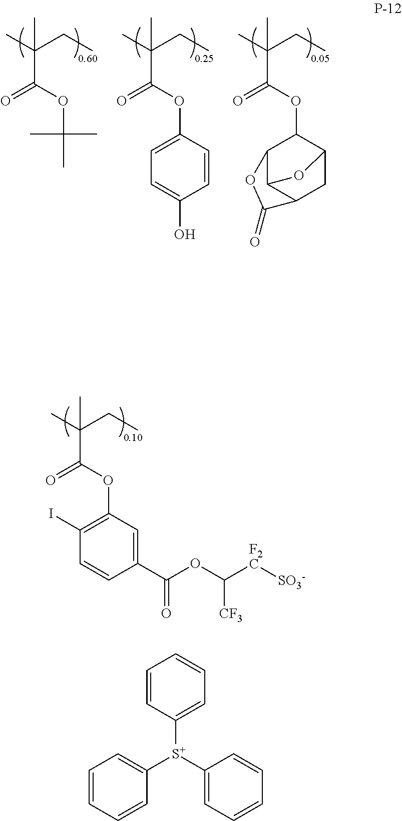

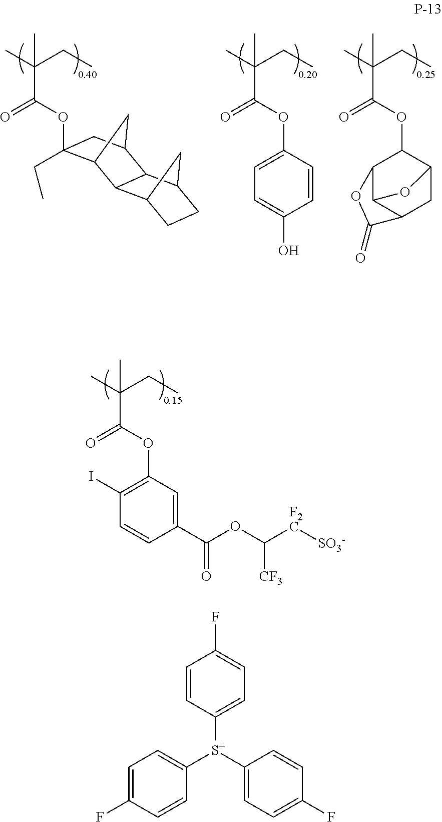

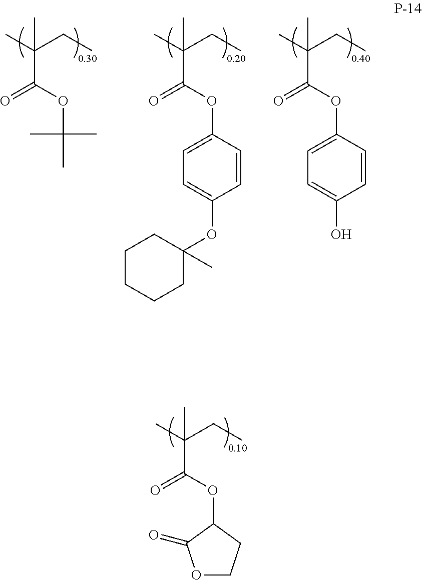

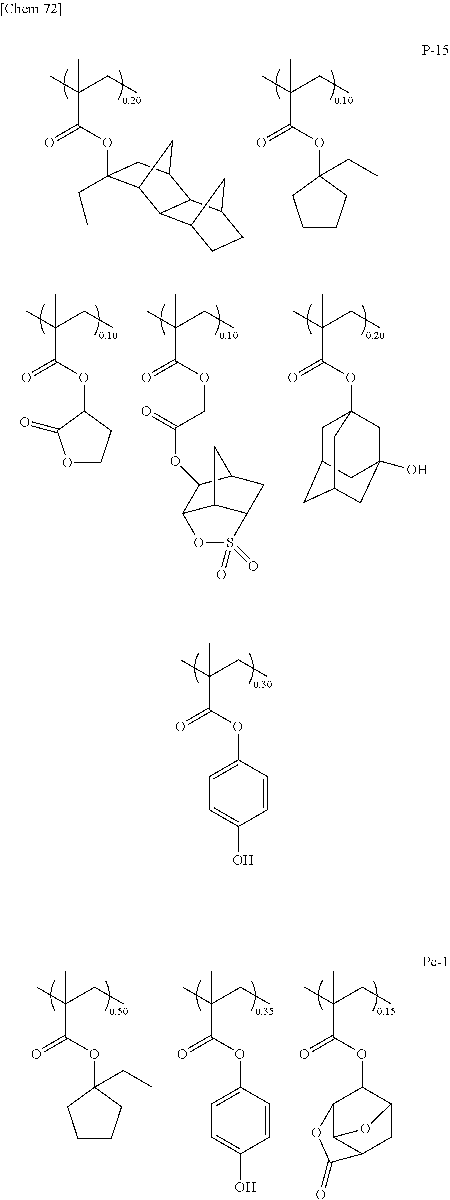

### Examples and Comparative Examples

A radiation-sensitive resin composition was prepared by filtering, through a 0.2 μm-sized filter, a solution obtained by dissolving components in the composition given in Table 1 in a solvent obtained by dissolving 100 ppm of FC-4430 manufactured by 3M as a surfactant.

In Table 1, the components are as follows.

Acid diffusion controlling agents (Q-1) to (Q-18) and (Qc-1) to (Qc-2)

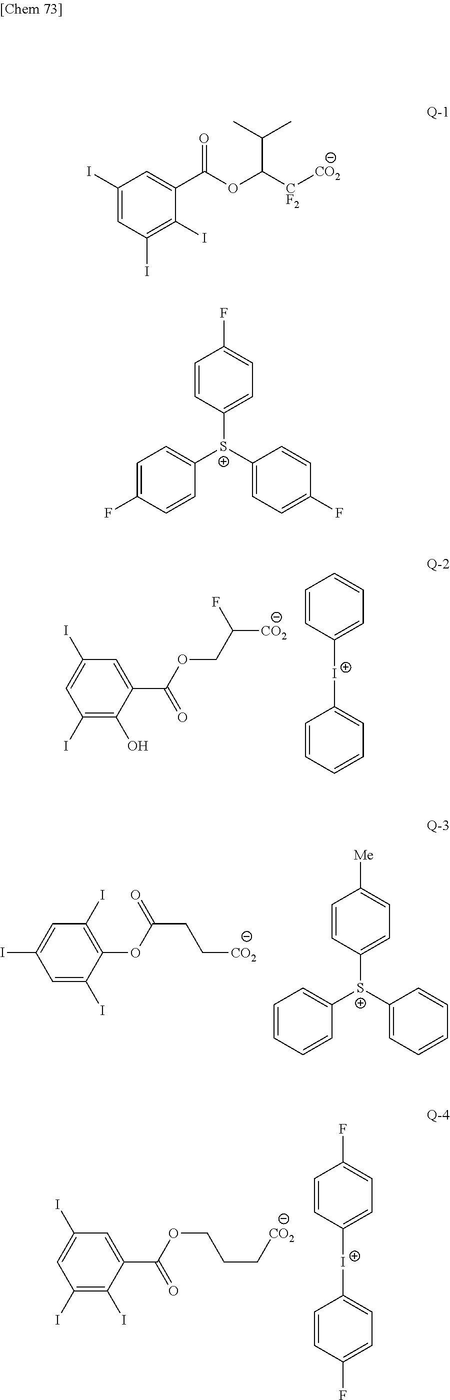

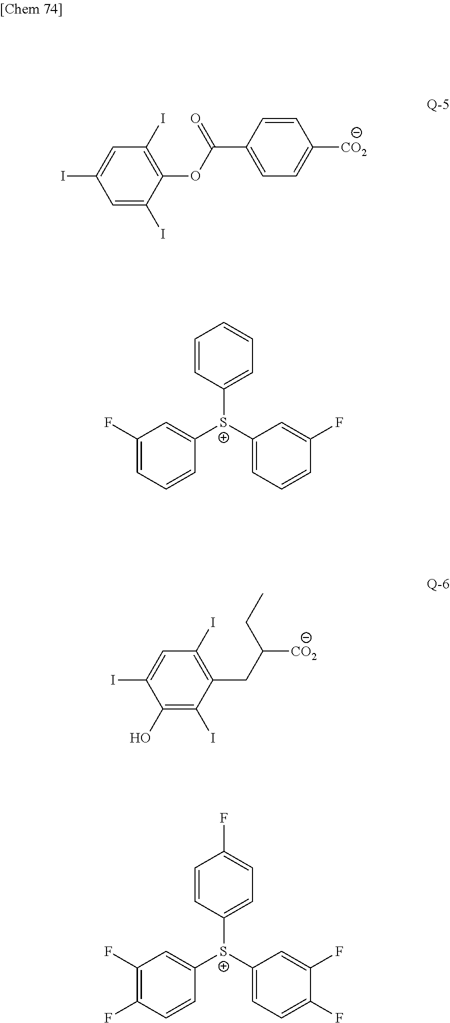

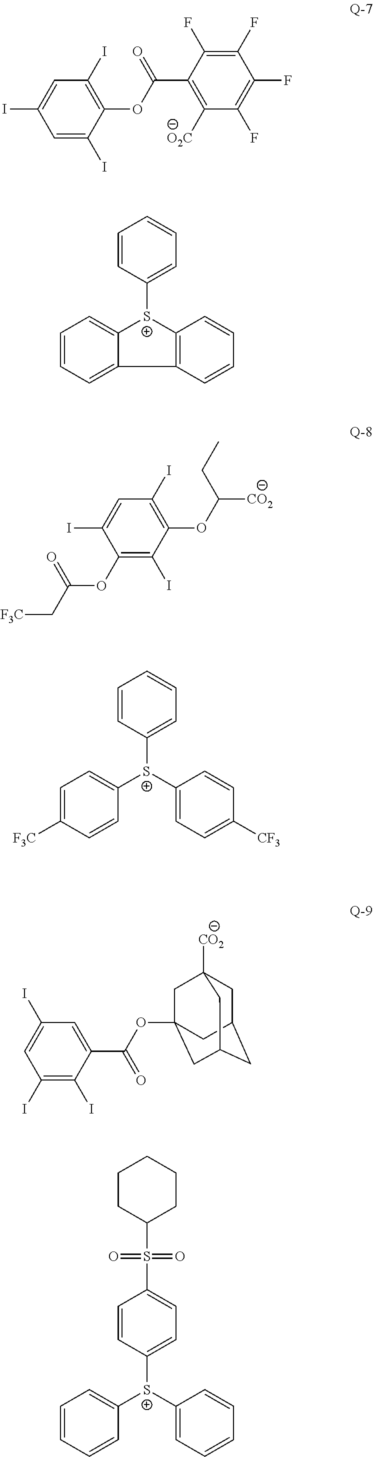

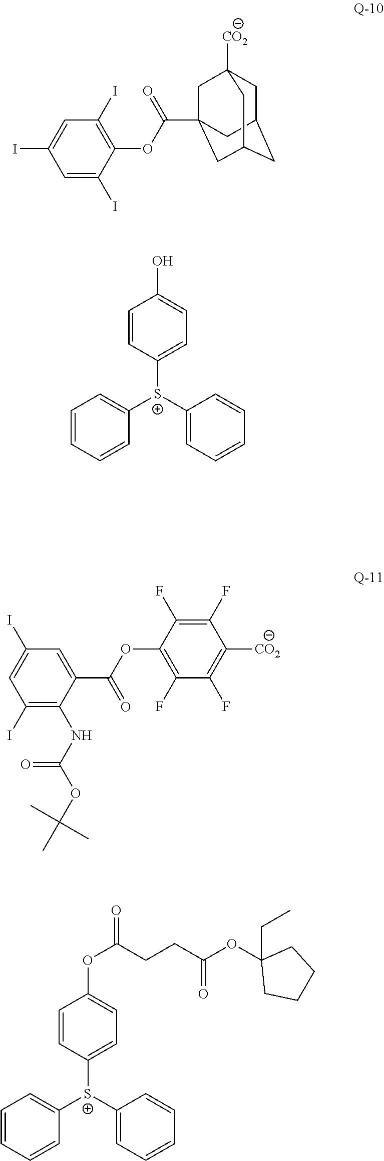

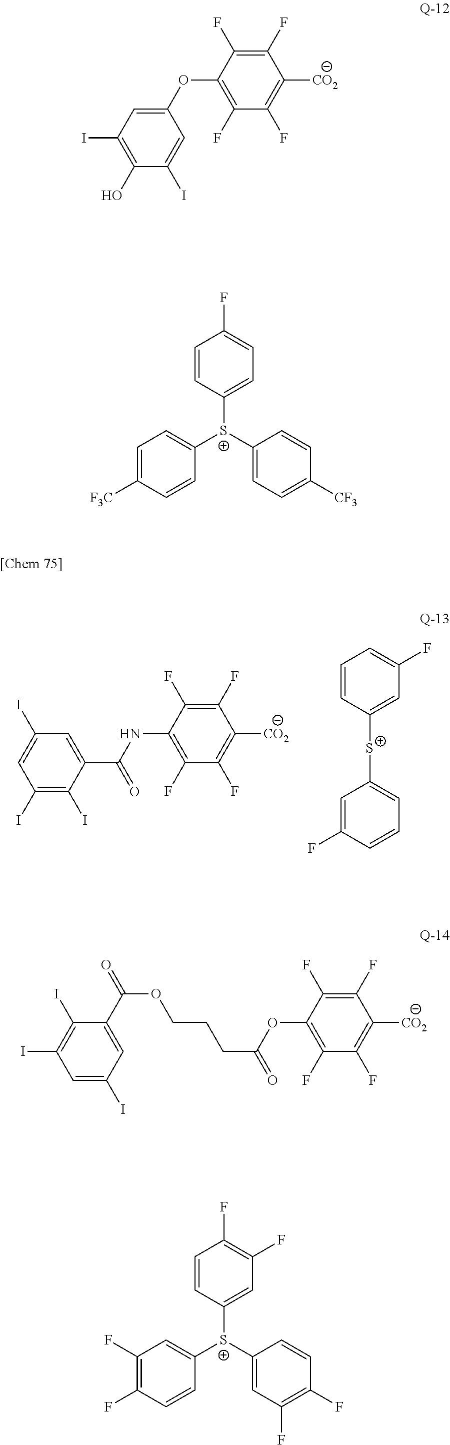

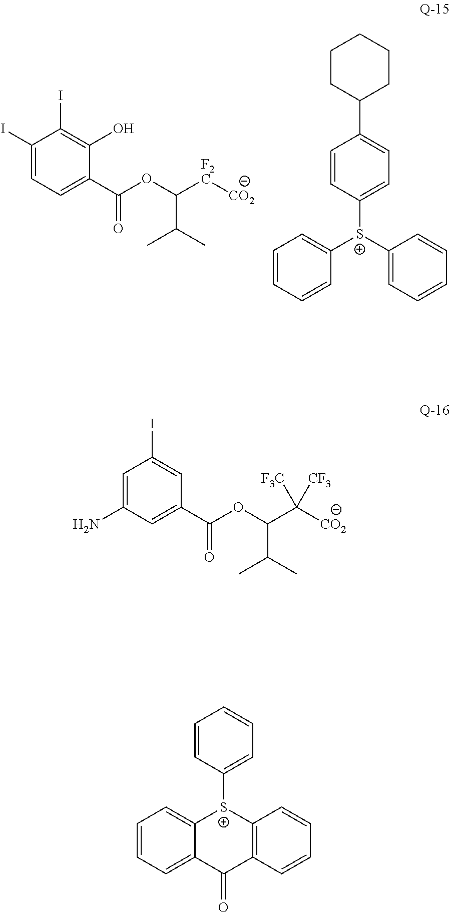

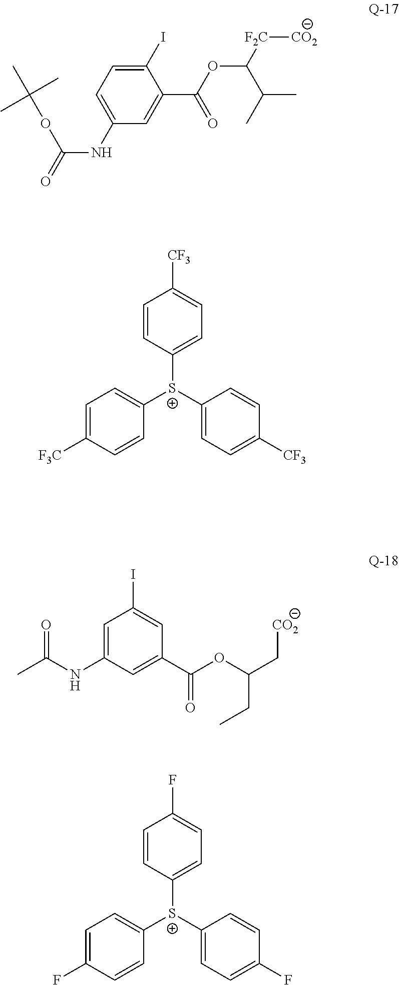

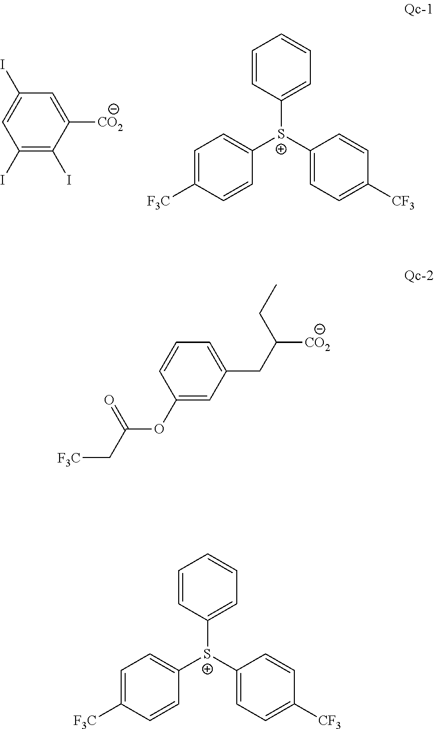

### Solvent:

PGMEA (propylene glycol monomethyl ether acetate)
GBL (γ-butyrolactone)
CHN (cyclohexanone)
PGME (propylene glycol monomethyl ether)
DAA (diacetone alcohol)
EL (ethyl lactate)

High fluorine-containing resin F-1: Mw=8,900, Mw/Mn=2.0

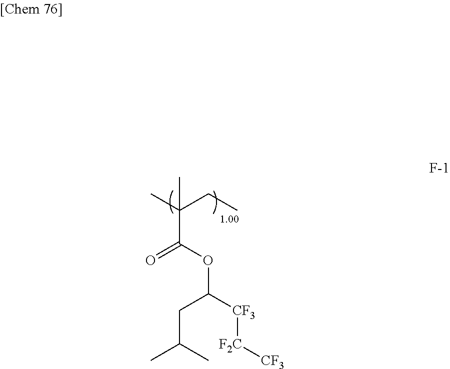

### [Evaluation of Sensitivity by EUV Exposure]

A composition for forming an underlayer antireflective film (“ARC66” manufactured by Brewer Science, Inc.) was applied onto a 12 inch silicon wafer using a spin coater (“CLEAN TRACK ACT12” manufactured by Tokyo Electron Limited), and then heated at 205° C. for 60 seconds to form an underlayer antireflective film having an average thickness of 105 nm. Each radiation-sensitive resin composition shown in Table 1 was applied onto the underlayer antireflection film using the spin coater, followed by performing PB at 130° C. for 60 seconds. Thereafter, cooling was performed at 23° C. for 30 seconds to form a resist film having an average thickness of 55 nm. This resist film was exposed to light using an EUV scanner (“NXE3300” (NA 0.33, σ 0.9/0.6, quadrupole illumination, hole pattern mask with a pitch of 46 nm on wafer and a bias of +20%) manufactured by ASML). PEB was performed on a hot plate at 120° C. for 60 seconds, and development was performed with a 2.38 mass % aqueous tetramethylammonium hydroxide (TMAH) solution for 30 seconds to form a resist pattern with a 23 nm hole and a 46 nm pitch. The exposure dose at which the resist pattern with a 23 nm hole and a 46 nm pitch was formed was defined as an optimum exposure dose (Eop), and the optimum exposure dose was defined as sensitivity (mJ/cm²).

### [Evaluation of CDU]

A resist pattern with a 23 nm hole and a 46 nm pitch was formed through the same operation as that described above by applying the exposure dose Eop determined above. The resist pattern formed was observed from the top of the pattern using a scanning electron microscope (“CG-5000” manufactured by Hitachi High-Technologies Corporation). The hole diameter was measured at 16 points in a range of 500 nm and the average value thereof was determined. In addition, the average value was measured at arbitrary 500 points in total. The 3 sigma value was determined from the distribution of the measurement values, and the 3 sigma value determined was taken as an evaluation value (nm) of CDU performance. The smaller an evaluation value of CDU performance is, the smaller the dispersion of hole diameter in a long period is and the better the CDU performance is. The results are shown in Table 1.

### [Evaluation of Residual Film of Exposed Area]

A resist film having an average thickness of 55 nm was formed in the same manner as described above. Thereafter, exposure was performed at the optimum exposure dose Eop. Each of the wafers before and after the exposure was cut, and the cross section thereof was observed using a scanning electron microscope (“S-5500” manufactured by Hitachi High-Technologies Corporation) to measure the thickness of the resist film. The ratio of the film thickness after the exposure to the film thickness before the exposure was determined and taken as a residual film ratio (%). The case where the residual film ratio is 70% or more is determined as “A”, the case where the residual film ratio is 60% or more and less than 70% is determined as “B”, and the case where the residual film ratio is less than 50% is determined as “C”.

Residual film ratio (%)=(film thickness after exposure at optimum exposure dose(nm)/film thickness before exposure(nm))×100

### [Referential Evaluation of Storage Stability]

Measurement samples resulting from one-month storage at 35° C. and measurement samples resulting from one-month storage at −15° C. were prepared regarding the radiation-sensitive resin compositions obtained in the above-described Examples and Comparative Examples. The sensitivity was evaluated in the same manner as described above using these measurement samples. The sensitivity in the case of storage at −15° C. for 1 month and the sensitivity in the case of storage at 35° C. for 1 month were measured, and the case where the difference therebetween is 1.0% or less is determined as “A”, the case where the difference therebetween is more than 1.0% and 1.5% or less is determined as “B”, and the case where the difference therebetween is more than 1.5% is determined as “C”.

TABLE 1

| | Base resin | PAG | Acid diffusion | Solvent | High fluorine- | | | Residual | |
|---|---|---|---|---|---|---|---|---|---|
| | (parts | (parts | controlling agent | (parts by | containing resin | Sensitivity | CDU | film | Storage |
| | by mass) | by mass) | (parts by mass) | mass) | (parts by mass) | [mJ/cm²] | [nm] | ratio | stability |
| Example 1 | P-1 | PAG1 | Q-1 | PGME/EL | F-1 | 13 | 2.2 | A | A |
| | (100) | (4.0) | (2.0) | (2,000/500) | (3.0) | | | | |
| Example 2 | P-2 | PAG2 | Q-2 | PGMEA/PGME/EL | F-1 | 14 | 2.2 | A | B |
| | (100) | (5.5) | (2.0) | (1,500/500/500) | (3.0) | | | | |
| Example 3 | P-3 | PAG3 | Q-3 | PGMEA/EL | F-1 | 15 | 2.2 | A | A |
| | (100) | (7.5) | (3.0) | (2,000/500) | (3.0) | | | | |
| Example 4 | P-4 | PAG4 | Q-4 | PGMEA/EL | F-1 | 15 | 2.2 | A | B |
| | (100) | (7.0) | (3.0) | (2,000/500) | (3.0) | | | | |
| Example 5 | P-5 | PAG5 | Q-5 | PGMEA/EL | F-1 | 13 | 2.2 | A | A |
| | (100) | (7.5) | (3.0) | (2,000/500) | (3.0) | | | | |
| Example 6 | P-6 | PAG6 | Q-6 | PGMEA/EL | F-1 | 13 | 2.2 | A | B |
| | (100) | (8.0) | (3.0) | (2,000/500) | (3.0) | | | | |
| Example 7 | P-7 | PAG1 | Q-7 | PGMEA/GBL | F-1 | 14 | 2.2 | A | A |
| | (100) | (7.5) | (3.5) | (2,200/300) | (3.0) | | | | |
| Example 8 | P-8 | PAG7 | Q-8 | PGMEA/DAA | F-1 | 14 | 2.2 | A | A |
| | (100) | (7.5) | (3.0) | (2,000/500) | (3.0) | | | | |
| Example 9 | P-9 | PAG3 | Q-9 | PGMEA/PGME | F-1 | 15 | 2.2 | A | A |
| | (100) | (7.0) | (3.5) | (2,000/500) | (3.0) | | | | |
| Example 10 | P-10 | PAG8 | Q-10 | PGMEA/PGME | F-1 | 12 | 2.2 | A | A |
| | (100) | (7.0) | (3.0) | (2,000/500) | (3.0) | | | | |
| Example 11 | P-1 | PAG9 | Q-11 | PGMEA/CHN/PGME | F-1 | 15 | 2.2 | A | B |
| | (100) | (2.5) | (2.5) | (400/2,000/100) | (3.0) | | | | |
| Example 12 | P-5 | PAG9 | Q-12 | PGMEA/PGME | F-1 | 14 | 2.2 | A | B |
| | (100) | (7.5) | (3.0) | (2,000/500) | (3.0) | | | | |
| Example 13 | P-11 | PAG10 | Q-13 | PGMEA/GBL/PGME | F-1 | 15 | 2.2 | A | B |
| | (100) | (9.0) | (3.5) | (2,200/200/100) | (3.0) | | | | |
| Example 14 | P-12 | PAG3 | Q-14 | PGMEA/GBL | F-1 | 12 | 2.2 | A | A |
| | (100) | (4.0) | (3.5) | (2,200/300) | (3.0) | | | | |
| Example 15 | P-13 | PAG11 | Q-15 | PGMEA/DAA | F-1 | 13 | 2.2 | A | A |
| | (100) | (3.5) | (3.0) | (2,000/500) | (3.0) | | | | |
| Example 16 | P-4 | PAG12 | Q-16 | PGMEA/DAA | F-1 | 14 | 2.2 | A | A |
| | (100) | (7.5) | (3.0) | (2,000/500) | (3.0) | | | | |
| Example 17 | P-14 | PAG9 | Q-17 | PGMEA/DAA | F-1 | 14 | 2.2 | A | B |
| | (100) | (7.5) | (2.5) | (2,000/500) | (3.0) | | | | |
| Example 18 | P-15 | PAG8 | Q-18 | PGMEA/EL | F-1 | 12 | 2.2 | A | A |
| | (100) | (7.5) | (2.5) | (2,000/500) | (3.0) | | | | |
| Comparative | P-8 | PAG7 | Qc-1 | PGMEA/DAA | F-1 | 14 | 2.2 | B | A |
| Example 1 | (100) | (7.5) | (3.0) | (2,000/500) | (3.0) | | | | |
| Comparative | P-8 | PAG7 | Qc-2 | PGMEA/DAA | F-1 | 14 | 2.4 | C | A |
| Example 2 | (100) | (7.5) | (3.0) | (2,000/500) | (3.0) | | | | |
| Comparative | Pc-1 | PAG7 | Q-8 | PGMEA/DAA | F-1 | 16 | 2.2 | A | A |
| Example 3 | (100) | (7.5) | (3.0) | (2,000/500) | (3.0) | | | | |

The evaluation conducted for the resist patterns formed through the EUV exposure revealed that all the radiation-sensitive resin compositions of Examples had good sensitivity, CDU performance, and residual film ratio. With respect to the storage stability, the compositions using sulfonium cation were better than those using iodonium cation.

### INDUSTRIAL APPLICABILITY

According to the radiation-sensitive resin composition and the pattern forming method described above, a resist pattern that is superior in sensitivity to exposure light and superior in CDU performance and residual film ratio can be formed. Therefore, these can be suitably used for a machining process and the like of a semiconductor device in which micronization is expected to further progress in the future.

1. A radiation-sensitive resin composition comprising:
a resin comprising;
at least one structural unit selected from the group consisting of a structural unit represented by formula (1) and a structural unit represented by formula (2); and
a structural unit comprising a phenolic hydroxy group;
an acid diffusion controlling agent represented by formula (α); and
a solvent, 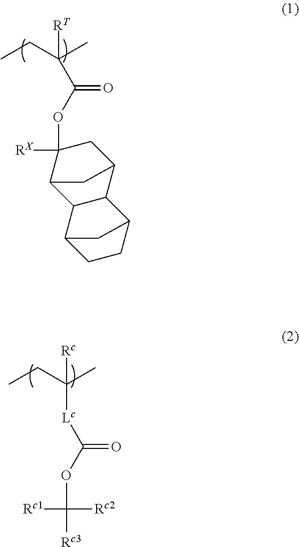
wherein, in formula (1), R^{T} is a hydrogen atom, a fluorine atom, a methyl group, or a trifluoromethyl group, and R^{X} is a monovalent hydrocarbon group having 1 to 20 carbon atoms;
in formula (2), R^{c} is a hydrogen atom, a fluorine atom, a methyl group, or a trifluoromethyl group, L^{c} is a single bond or a divalent linking group, and R^{c1}, R^{c2} and R^{c3} are each independently a monovalent hydrocarbon group having 1 to 20 carbon atoms, 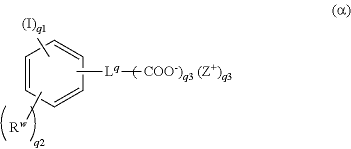
wherein, in formula (α), R^{w} is a monovalent organic group having 1 to 20 carbon atoms, a hydroxy group, or an amino group; when there are a plurality of R^{w}'s, the plurality of R^{w}'s are same or different from each other; L^{q} is a divalent linking group; when there are a plurality of L^{q}'s, the plurality of L^{q}'s are same or different from each other; Z⁺ is a monovalent radiation-sensitive onium cation; q₁ is an integer of 1 to 4; q₂ is an integer of 0 to 3; q₃ is an integer of 1 to 3; and an upper limit of q₁+q₂+q₃ is 6.

2. The radiation-sensitive resin composition according to claim 1, wherein in formula (1), R^{X} is a monovalent chain hydrocarbon group having 1 to 10 carbon atoms.

3. The radiation-sensitive resin composition according to claim 1, wherein in formula (2), R^{c1} and R^{c2} are each independently a monovalent chain hydrocarbon group having 1 to 10 carbon atoms, and R^{c3} is a monovalent alicyclic or aromatic hydrocarbon group having 6 to 12 carbon atoms.

4. The radiation-sensitive resin composition according to claim 1, wherein in formula (α), q₁ is 2 or 3, q₂ is 0 or 1, and q₃ is 1.

5. The radiation-sensitive resin composition according to claim 1, wherein in formula (α), Z⁺ comprises an aromatic ring structure comprising a fluorine atom.

6. The radiation-sensitive resin composition according to claim 1, further comprising a radiation-sensitive acid generator that generates an acid having a pKa lower than a pKa of an acid generated from the acid diffusion controlling agent by irradiation with radiation.

7. The radiation-sensitive resin composition according to claim 1, wherein the resin further comprises a structural unit comprising at least one structure selected from the group consisting of a lactone structure, a cyclic carbonate structure, and a sultone structure.

8. The radiation-sensitive resin composition according to claim 1, wherein the resin further comprises a structural unit comprising an organic acid anion moiety and an onium cation moiety.

9. The radiation-sensitive resin composition according to claim 1, further comprising a high fluorine-containing resin that is higher in mass content of fluorine atoms than the resin.

10. A method for forming a pattern, the method comprising:
applying the radiation-sensitive resin composition according to claim 1 directly or indirectly to a substrate to form a resist film;
exposing the resist film; and
developing the exposed resist film with a developer.

11. The method for forming a pattern according to claim 10, wherein exposing the resist film comprises exposing the resist film to an extreme-ultraviolet ray or an electron beam.
